(19) United States
(12) Patent Application Publication
(10) Pub. No.: US 2008/0316071 A1
(43) Pub. Date: Dec. 25, 2008

(54) Modulation Coding with Rll (1,K) and Mtr (2) Constraints

(75) Inventors: Willem Marie Julia Marcel Coene, Eindhoven (NL); Alexander Padiy, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/575,078

(22) PCT Filed: Sep. 9, 2005
(86) PCT No.: PCT/IB05/52956

§ 371 Date: Mar. 12, 2007

(30) Foreign Application Priority Data
Sep. 15, 2004 (EP) 04104463.7

(51) Int. Cl. H03M 7/46

(52) U.S. Cl. 341/59

(57) ABSTRACT

This invention relates to a method of converting a user bitstream into a coded bitstream by means of a runlengh limited (d, k) channel code where the channel code has a constraint of d=1. In order to ensure an improvement in bit detection performance an additional RMTR constraint of r=2 is imposed limiting to two the maximum number of minimum runs allowed by the d=1 constraint. An additional advantage of such a code is a limitation of the back-tracking depth of a Viterbi bit-detector Based on two different k constraints the construction of such d=1 and r=2 codes is disclosed.

This invention relates to a method of converting a user bitstream into a coded bitstream by means of a channel code where the channel code has a constraint of d=1, to a coder for converting a user bitstream into a coded bitstream by means of a channel code where the coder comprises processing device for applying a channel code with the constraint of d=1, to a recording device comprising such a coder, to a record carrier comprising a track comprising a signal comprising a user bitstream coded in a coded bitstream by means of a channel code where the channel code has the constraint of d=1, to a bit detector for performing bit detection on a code bitstream comprising a user bitstream coded in a coded bitstream by means of a channel code where the channel code has the constraint of d=1, and to a playback device comprising such a bit detector.

At very high densities for a d=1 constrained storage system (e.g. capacities on a 12 cm disc of 33-37 GB, well beyond the 25 GB of Blu-ray Disc), consecutive 2T runs are the Achilles' heel for the bit-detection. Such sequences of 2T runs bounded by larger runlengths at both sides, are called 2T-trains. Therefore, it turns out to be advantageous to limit the length of such 2T-trains. This is a general observation, and is not new as such. Currently, the 17PP code of BD as disclosed by T. Narahara, S. Kobayashi, M. Hattori, Y. Shimpuku, G. van den Enden, J. A. H. M. Kahlman, M. van Dijk and R. van Woudenberg, in “Optical Disc System for Digital Video Recording”, Jpn. J. Appl. Phys., Vol. 39 (2000) Part 1, No. 2B, pp. 912-919. has a so-called RMTR constraint (Repeated Minimum Transition Runlength) of r=6, which means that the number of consecutive minimum runlengths is limited to 6 or, stated differently, the maximum length of the 2T-train is 12 channel bits. The 17PP code is based on the parity-preserve principle as disclosed in U.S. Pat. No. 5,477,222.

In the literature, the RMTR constraint is often referred to as the MTR constraint. Originally, the maximum transition-run (MTR) constraint as introduced by J. Moon and B. Brickner, in “Maximum transition run codes for data storage systems”, IEEE Transactions on Magnetics, Vol. 32, No. 5, pp. 3992-3994, 1996, for a d=0 case, specifies the maximum number of consecutive “1”-bits in the NRZ bitstream where a “1” indicates a transition in the bi-polar channel bitstream. Equivalently, in the NRZI bitstream, the MTR constraint limits the number of successive 1T runs. As argued above, the MTR constraint can also be combined with a d-constraint, in which case the MTR constraint limits the number of consecutive minimum runlengths as is the case for the 17PP code. The basic idea behind the use of MTR codes is to eliminate the so-called dominant error patterns, that is, those patterns that would cause most of the errors in the partial response maximum likelihood (PRML) sequence detectors used for high density recording. A highly efficient rate 16→17 MTR code limiting the number of consecutive transitions to at most two for d=0 has been described in T. Nishiya, K. Tsukano, T. Hirai, T. Nara, S. Mita, “Turbo-EEPRML: An EEPRML channel with an error correcting post-processor designed for 16/17 rate quasi MTR code”, Proceedings Globecom '98, Sydney, pp. 2706-2711, 1998.

It is an objective of the present invention to provide a method of converting a user bitstream into a coded bitstream by means of a channel code that improves the performance of the bit-detector.

To achieve this object the method of converting a user bitstream into a coded bitstream by means of a channel code is characterized in that the channel code has an additional constraint of r=2.

Within the scope of a code-rate of R=⅔ for d=1 the minimum RMTR constraint that is still possible is r=2. It turned out that r=2 results in a improved bit-detection performance. Thus, for exactly the same rate as the 17PP code, a maximally improved RMTR constraint and correspondingly improved bit-detection performance is obtained.

In addition another advantage is achieved by applying the RMTR constraint, which is a limitation of the back-tracking depth (or trace-back depth) of a Viterbi (PRML) bit-detector when such a detector is used on the receiving/retrieving side.

Performance gain due to the RMTR constraint has been studied experimentally for high-density optical recording channels derived from the Blu-ray Disc (BD) system. Experiments have been performed using the increased-density BD rewritable system with the disc capacity increased from the standard 23.3-25-27 GB to 37 GB. This particular experimental platform has been chosen because of the plans for standardization of an increased-density system derived from the current Blu-ray Disc standard. PRML (Viterbi) bit detection has been employed. Moreover, next-generation high-numerical-aperture near-field optical recording systems will likewise profit from the improved bit-detection performance that is offered by channel codes that have the r=2 constraint.

Performance of the Viterbi bit detector has been measured based on the sequenced amplitude margin (SAM) analysis. SAM analysis allows computing the error probability (SAMEP) at the output of the Viterbi detector as well as calculation of the SAM-based pre-detection signal-to-noise ratio (SAMSNR) defined as

SAMSNR=20*log₁₀(\sqrt{2}*erfinv(1−2*SAMEP)) [dB].

SAMSNR proved to be a useful performance measure since it can be related to the potential capacity gain. Namely, in the relevant range of capacities around 35 GB, 1 dB gain in SAMSNR means almost 6% disc capacity increase.

Channel codes with different RMTR constraints (r=1, r=2, r=3 and r=6) have been compared to each other. (Note that the r=1 constraint is the only one that cannot be realized with a rate R=⅔ code; a rate R= 16/25 is assumed instead.) In order to separate read-channel performance gain due to the imposed RMTR constraint from the corresponding write-channel gain, two different Viterbi bit detectors have been used: one which is aware of the RMTR constraint, and the other which is not. In the second case the performance gain can be attributed solely to the improved spectral content of the data written on the disc (such that it is better matched to the characteristics of the write channel used).

When the 17PP channel code with the RMTR constraint r=6 (as used in the BD system) is employed, SAMSNR of 11.66 dB is achieved for both RMTR-aware and RMTR-unaware bit detectors, i.e. no RMTR-related performance gain is observed in the read channel. When the channel code with r=3 is used, SAMSNR of 11.87 dB and 11.72 dB are achieved for the RMTR-aware and RMTR-unaware bit detectors correspondingly. As one can see, in both write and read channels, RMTR-related SAMSNR increase of about 0.15 dB is gained with respect to the case of r=6, leading to a total SAMSNR gain of about 0.3 dB. The channel code with r=2 leads to an even greater SAMSNR improvement with respect to r=6: SAMSNR of 12.07 dB and 12.55 dB are achieved for the RMTR-aware and RMTR-unaware bit detectors correspondingly, which means a total SAMSNR gain of about 0.9 dB. Decreasing the RMTR further from r=2 to r=1 does not lead to any significant SAMSNR gain. To the contrary, the overall system performance is deteriorated because of the increased code rate loss for the case of r=1 as is discussed in the following discussion.

For d=1 and RMTR r=2, the theoretical capacity amounts to:

C(d=1,k=∞,r=2)=0.679289. (1)

So, a code with rate ⅔ is still feasible. For an even more aggressive RMTR constraint r=1, the theoretical capacity amounts to:

C(d=1,k=∞,r=1)=0.650902. (2)

Clearly, a practical code with rate ⅔ for r=1 is thus not possible. As shown by the experimental results, no performance gain is observed by going from r=2 to r=1, since 2T trains of length 1 and 2 are clearly distinguishable by the Viterbi bit-detector (intuitively by looking at the polarity at the longer runlengths at both sides of the short 2T-train). Therefore, the following derivation focuses on the case r=2, for which we can achieve the same code rate as the 17PP code of BD, with RMTR r=6.

It is thus shown that a code with constraints d=1 and r=2 provides improved performance which can be used to obtain an increase in disc capacity or an increase in the reliability of the bit detection by allowing a gain of almost 1 dB (in fact 0.9 dB), i.e. about 5% disc capacity increase.

Detailed description of a code with d=1 and an RMTR Constraint r=2.

A new d=1 parity-preserving RLL code with identical code-rate as 17PP (R=⅔) and with the minimum RMTR constraint possible (r=2) is proposed so that the bit-detection performance can be improved: the improvement can be quantified as 0.9 dB of (SAM) SNR, or, equivalently, about 5% of capacity in the capacity range of 35 GB for a BD system.

The following additional properties of the channel code can also to be realized, based on the ACH algorithm as disclosed by R. L. Adler, D. Coppersmith, and M. Hassner, in “Algorithms for Sliding Block Codes. An Application of Symbolic Dynamics to Information Theory”, IEEE Transaction on Information Theory, Vol. IT-29, 1983, pp. 5-22., a well-known technique for the construction of a sliding block code with look-ahead decoding:
a byte-based mapping (of 8 user bits onto 12 channel bits), identical to that of the ETM code as disclosed by K. Kayanuma, C. Noda and T. Iwanaga, in “Eight to Twelve Modulation Code for High Density Optical Disk”, Technical Digest ISOM-2003, Nov. 3-7 2003, Nara, Japan, paper We-F-45, pp. 160-161;
DC-control via the parity-preserve principle as used in the 17PP code. This means that the parity of user words and channel words is identical as disclosed by U.S. Pat. No. 5,477,222 or, equivalently, always opposite. Therefore, 128 even-parity and 128 odd-parity channel words are needed for each of the encoding states of the Finite-State Machine (FSM) of the RLL code;
state-independent decoding must preferably apply for the FSM to limit error-propagation: it is not needed for the decoder to know the FSM state for which a given channel word was encoded.

First, the mathematical procedure for the ACH-based code-construction will be outlined for the specific case of codes with the parity-preserve property. Subsequently, two particular codes will be discussed, that have been designed according to this construction method: one code has runlength constraints d=1, k=12 and r=2, the other has runlength constraints d=1, k=10 and r=2. Both codes have an 8-to-12 mapping, meaning that bytes of user information are encoded onto 12-bit channel words. Because of the larger k-constraint of the first code, the required amount of so-called state-splitting in the ACH algorithm will be less than for the second code with the more tight k=10 constraint: this is reflected by the fact that the maximum component of the approximate eigenvector equals 5 and 8 for the first and the second code, respectively. It should be noted that, for the same 8-to-12 mapping, an even lower value for the k-constraint, k−9, is possible within the assumed boundary conditions (8-to-12 mapping, PP-property), but would require a 28-fold state-splitting in the ACH-algorithm, which leads to increased error propagation for such a code.

In order to explain the ACH-based code-construction of parity-preserving codes, the construction of a code using a combi-code construction is outlined.

In US-patent U.S. Pat. No. 6,469,645-B2, the concept of combi-codes has been disclosed. Additional information can be found in “Combi-Codes for DC-Free Runlength-Limited Coding”, Wim M. J. Coene, IEEE Transactions on Consumer Electronics, Vol. 46, No. 4, pp. 1082-1087, November 2000.

A combi-code for a given constraint consists of a set of at least two codes for that constraint, possibly with different rates, where the encoders of the various codes share a common set of encoder states. As a consequence, after each encoding step the encoder of the current code may be replaced by the encoder of any other code in the set, where the new encoder has to start in the ending state of the current encoder. Typically, one of the codes, called the standard code or main code, is an efficient code for standard use; the other codes serve to realise certain additional properties of the channel bitstream. Sets of sliding-block decodable codes for a combi-code can be constructed via the ACH-algorithm; here the codes are jointly constructed starting with suitable presentations derived from the basic presentation for the constraint and using the same approximate eigenvector. The construction of a Combi-Code satisfying the (dk) constraints is guided by an approximate eigenvector, see K. A. S. Immink, “Codes for Mass Data Storage Systems”, 1999, Shannon Foundation Publishers, The Netherlands and A. Lempel and M. Cohn, “Look-Ahead Coding for Input-Constrained Channels”, IEEE Trans. Inform. Theory, Vol. 28, 1982, pp. 933-937, and H. D. L. Hollmann, “On the Construction of Bounded-Delay Encodable Codes for Constrained Systems”, IEEE Trans. Inform. Theory, Vol. 41, 1995, pp. 1354-1378. The components of this vector indicate the amount of state-splitting needed in the ACH-algorithm as disclosed by R. L. Adler, D. Coppersmith, M. Hassner, in “Algorithms for Sliding Block Codes. An Application of Symbolic Dynamics to Information Theory”, IEEE Trans. Inform. Theory, Vol. 29, 1983, pp. 5-22. This algorithm has to be applied to the construction of the main code and the substitution code simultaneously.

The main code is denoted C₁; it maps n-bit data words into m₁-bit channel words, and can be constructed on the basis of an approximate eigenvector vᵢ, i=1, . . . ,k+1 that satisfies the inequality:

Σⱼ₌₁^{k+1}Dᵢⱼ^{m}^{₁}vⱼ≧2ⁿvᵢ, i=1, . . . , k+1, (3)

where the matrix D is a (k+1)×(k+1) matrix, known as the adjacency matrix or connection matrix for the state-transition diagram (STD) that describes (dk)-sequences.

For the substitution code, denoted C₂, we derive a similar approximate eigenvector inequality, that takes the two properties of the substitution code into account: for each branch (or transition between coding states), there are two channel words with opposite parity and the same next-state. We enumerate separately the number of channel words of length m₂ (leaving from state σᵢ and arriving at state σⱼ of the STD) that have even parity and the number of those words that have odd parity. We represent these numbers by D_{E}[m₂]ᵢⱼ and D_{O}[m₂]ᵢⱼ, respectively. For the substitution code, the enumeration does not involve single channel words, but word-pairs, where the two channel words of each word-pair have opposite parity and arrive at the same next-state σⱼ of the STD. For this purpose, we define a new connection matrix for sequences of length m denoted by D_{EO}[m] with the matrix elements:

D_{EO}[m]ᵢⱼ=Min[D_{E}[m]ᵢⱼ, D_{O}[m]ᵢⱼ]. (4)

A substitution code that maps n-bit data words into a set of two m₂-bit channel words with the same next-state and with opposite parity, can be constructed on the basis of an approximate eigenvector vᵢ, i=1, . . . , k+1 that satisfies the inequality:

Σⱼ₌₁^{k+1}D_{EO}[m₂]ᵢⱼvⱼ≧2ⁿvᵢ, i=1, . . . , k+1. (5)

For the construction of a Combi-Code, an approximate eigenvector must satisfy the inequalities (3) and (5) simultaneously. The requirement of a single approximate eigenvector for the main code and the substitution code enables a seamless transition from the main code to the substitution code and vice versa. Moreover, the same operation of merging-of-states (as needed in the ACH-algorithm) can be carried out for both codes.

Design Rules for a Parity-Preserving RLL Code by means of Relaxation of Design Rules for a Substitution Code for the case that the latter is only to be used as Parity-Preserve Code

The substitution code used alone, that is without standard code, is a parity-preserve code (which by definition maintains the parity between user words and channel words). This can be seen as follows. For each n-bit input word, the substitution code has two channel words with opposite parity, and the same next-state. The possible choice between the two channel words with opposite parity represents in fact one bit of information: hence, we could consider this as a n+1-to-m₂ mapping (with m₂ the length of the channel words). Precisely 2ⁿ input words and the corresponding channel words have even parity, and precisely 2ⁿ input words and the corresponding channel words have odd parity: thus the code as such is parity-preserving. Now, in the special case that we only use the substitution code (and thus no concatenation with a main code is required), the “same-next-state” property is not required at all, and can therefore be omitted. Therefore the joint design rule of Eq. (5) as required for a substitution code, can be relaxed for a parity-preserving code into the two independent design rules that have to be satisfied simultaneously by the aimed approximate eigenvector:

Σⱼ₌₁^{k+1}D_{E}[m₂]ᵢⱼvⱼ≧2ⁿvᵢ, i=1, . . . , k+1. (6)

and

Σⱼ₌₁^{k+1}D_{O}[m₂]ᵢⱼvⱼ≧2ⁿvᵢ, i=1, . . . , k+1. (7)

The above formulas Eq. (6) and Eq. (7) are crucial since they describe the recipe for the code-construction of parity-preserving codes on the basis of the ACH-algorithm. This is a quite unique code-construction method, since the latest review on d,k constrained channel codes by K. A. S. Immink (“Codes for Mass Data Storage Systems”, Second Edition, 2004, Shannon Foundation Publishers, Eindhoven) claims on page 290 that “ . . . it is not yet clear how we can efficiently design parity preserving codes with the ACH algorithm.” Obviously, the above code-construction has clarified the pending issue.

For the practical case considered here with the 8-to-12 parity-preserving RLL code, the parameters (with the definitions of above as used for the substitution code) are: d=1, r=2, k=12, n+1=8 and m₂=12. Note that these parameters should not lead to any confusion here: the actual mapping of the code as a parity-preserve code is 8-to-12; the corresponding substitution code (if it would exist), would have a 7-to-12 mapping (with two channel words along the branches).

The invention will now be discussed based on FIGURES.

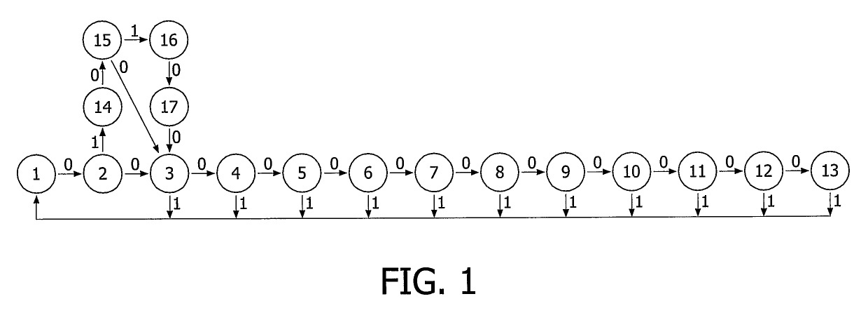

FIG. 1 shows a state transition diagram for the RLL constraints d=1, k=12 and r=2.

As a first example, an RLL code is disclosed with constraints: d=1, k=12 and r=2. The state-transition diagram (STD) for these RLL constraints is shown in FIG. 1. The RMTR constraint becomes obvious from STD-states 1, 2, 14, 15, 16, 17 and 3 at the upper-left corner of the FIGURE. An even lower k-constraint is possible as will be outlined in the second example, but this requires an 8-fold state-splitting and more states in the FSM of the code, leading to a larger complexity.

The approximate eigenvector for ACH-based construction of a sliding-block code with the parity-preserving property, and mapping 8-bit symbols onto 12-bit channel words, satisfying Eqs. (6-7) of the above code-construction, has been chosen as:

{3,5,5,5,5,5,5,4,4,4,3,3,0,2,4,2,3}. (8)

State-splitting according to the above approximate eigenvector, and subsequent state-merging leads to a final Finite-State Machine comprising 10 states. The code-tables are shown in the table III. The states are numbered from S0 to S 9. The code-words are listed by their decimal representation, with the MSB first (at left side of code-word). Channel words entering a given state are characterized by their specific word endings as indicated in Table I.

TABLE I
Characteristics of Word-Ending and States

| Word Ending | States |
|---|---|
| -001\| | S0, S1, S2 |
| -00101\| | S0, S1 |
| -0010101\| | S0, S1 |
| -0010\| | S0, S1, S2, S3, S4 |
| -001010\| | S0, S1, S2, S3 |
| -00101010\| | S0, S1, S2 |
| -10^{m}\| | S5, S6, S7, S8, S9 |
| (2 ≦ m ≦ 6) | |
| -10^{m}\| | S5, S6, S7, S8 |
| (7 ≦ m ≦ 9) | |
| -10^{m}\| | S5, S6, S7 |
| (10 ≦ m ≦ 11) | |

Note that the state-merging resulting into S0, S1 and S2 for all of the six first lines in the above table has made it possible to arrive at a 10-state FSM.

A sliding block code needs to decode the next-state of a given channel word in order to be able to uniquely decode said channel word. The next-state depends on the characteristics of the considered channel word (in particular the bits at the end of the word, as indicated in Table I), and a number of leading bits of the next channel word. The combination of a given channel word and its next state is sufficient to uniquely decode the corresponding source symbol. The “next-state” function for the latter discrimination has been realized in the coding tables according to a specific grouping (see Table II) with respect to the decimal representation.

Note that for a given channel word, at maximum 5 states (the maximum amount of state-splitting applied) can be possible “next-states” for that word. There are two sets, each of 5 states, that represent the maximum number of next-states (the 1 st set comprising S0, S1, . . . , S4, the 2nd set comprising S5, S6, . . . , S9). Note that the fan-out of all states in each of both sets is clearly separated into contiguous subsets of output words. Each subset is based on a range of decimal representations. Such a grouping of words in the fan-out of the states of the FSM limits error propagation. A similar ordering could of course be obtained based on a lexicographic ordering instead of the decimal ordering (which has some ‘gaps’ or missing words because of the RLL constraints).

TABLE II
Characteristics of Fan-Out of States
(decimal representation)

| State | Even Words | Odd Words |
|---|---|---|
| S0 | 1-66 | 1-63 |
| S1 | 70-133 | 64-123 |
| S2 | 134-198 | 126-192 |
| S3 | 199-261 | 194-259 |
| S4 | 262-319 | 263-334 |
| S5 | 219-281 | 218-284 |
| S6 | 137-199 | 136-202 |
| S7 | 200-215 | 206-217 |
| | 282-321 | 288-343 |
| S8 | 54-118 | 53-111 |
| S9 | 14-52 | 13-51 |
| | 122-134 | 114-135 |
| | ≧325 | ≧345 |

DC control aspects.
Note that other measures for reducing the error-propagation that is caused by the insertion of DC-control bits into the source bitstream, prior to encoding, can also be combined with the currently proposed channel code. Such a measure is described by U.S. Pat. No. 6,265,994.

As a second example, an RLL code is disclosed with constraints d=1, k=10 and r=2. Compared relative to the state-transition diagram (STD) of FIG. 1 for k=12, it is obvious that states 12 and 13 are not valid states for the k=10 constraint that is considered in this second code. The approximate eigenvector for ACH-based construction of a sliding-block code with the parity-preserving property, and mapping 8-bit symbols onto 12-bit channel words, satisfying Eqs. (6-7) of the above code-construction, has been chosen as:

{5,8,8,8,8,8,7,7,6,5,3,4,7,3,5}. (9)

State-splitting according to the above approximate eigenvector, and subsequent state-merging leads to a final Finite-State Machine comprising 16 states. The code-tables are shown in the table IV. The states are numbered from S0 to S15. A sliding block code needs to decode the next-state of a given channel word in order to be able to uniquely decode said channel word. The next-state depends on the characteristics of the considered channel word, and a number of leading bits of the next channel word. The combination of a given channel word and its next state is sufficient to uniquely decode the corresponding user (or source) symbol.

TABLE III

| | S0 | | | | S1 | | | | S2 | | | | S3 | | | | S4 | | | |
|---|---|---|---|---|---|---|---|---|---|---|---|---|---|---|---|---|---|---|---|---|
| | Even | | Odd | | Even | | Odd | | Even | | Odd | | Even | | Odd | | Even | | Odd | |
| 0 | 5 | 0 | 1 | 0 | 293 | 0 | 276 | 5 | 676 | 5 | 656 | 5 | 1298 | 0 | 1288 | 5 | 2196 | 5 | 2197 | 0 |
| 1 | 5 | 1 | 1 | 1 | 293 | 1 | 276 | 6 | 676 | 6 | 656 | 6 | 1298 | 1 | 1288 | 6 | 2196 | 6 | 2197 | 1 |
| 2 | 9 | 0 | 1 | 2 | 297 | 0 | 276 | 7 | 676 | 7 | 656 | 7 | 1298 | 2 | 1288 | 7 | 2196 | 7 | 2208 | 5 |
| 3 | 9 | 1 | 2 | 0 | 297 | 1 | 276 | 8 | 676 | 8 | 656 | 8 | 1298 | 3 | 1288 | 8 | 2196 | 8 | 2208 | 6 |
| 4 | 9 | 2 | 2 | 1 | 297 | 2 | 276 | 9 | 676 | 9 | 656 | 9 | 1298 | 4 | 1288 | 9 | 2196 | 9 | 2208 | 7 |
| 5 | 10 | 0 | 2 | 2 | 298 | 0 | 289 | 0 | 1025 | 0 | 661 | 0 | 1300 | 5 | 1296 | 5 | 2209 | 0 | 2208 | 8 |
| 6 | 10 | 1 | 2 | 3 | 298 | 1 | 289 | 1 | 1025 | 1 | 661 | 1 | 1300 | 6 | 1296 | 6 | 2209 | 1 | 2208 | 9 |
| 7 | 10 | 2 | 2 | 4 | 298 | 2 | 289 | 2 | 1025 | 2 | 672 | 5 | 1300 | 7 | 1296 | 7 | 2209 | 2 | 2213 | 0 |
| 8 | 10 | 3 | 4 | 5 | 320 | 5 | 290 | 0 | 1026 | 0 | 672 | 6 | 1300 | 8 | 1296 | 8 | 2210 | 0 | 2213 | 1 |
| 9 | 17 | 0 | 4 | 6 | 320 | 6 | 290 | 1 | 1026 | 1 | 672 | 7 | 1300 | 9 | 1296 | 9 | 2210 | 1 | 2217 | 0 |
| 10 | 17 | 1 | 4 | 7 | 320 | 7 | 290 | 2 | 1026 | 2 | 672 | 8 | 1313 | 0 | 1301 | 0 | 2210 | 2 | 2217 | 1 |
| 11 | 17 | 2 | 4 | 8 | 320 | 8 | 290 | 3 | 1026 | 3 | 672 | 9 | 1313 | 1 | 1301 | 1 | 2210 | 3 | 2217 | 2 |
| 12 | 18 | 0 | 4 | 9 | 320 | 9 | 290 | 4 | 1026 | 4 | 677 | 0 | 1313 | 2 | 1312 | 5 | 2210 | 4 | 2305 | 0 |
| 13 | 18 | 1 | 8 | 5 | 325 | 0 | 292 | 5 | 1028 | 5 | 677 | 1 | 1314 | 0 | 1312 | 6 | 2212 | 5 | 2305 | 1 |
| 14 | 18 | 2 | 8 | 6 | 325 | 1 | 292 | 6 | 1028 | 6 | 1024 | 5 | 1314 | 1 | 1312 | 7 | 2212 | 6 | 2305 | 2 |
| 15 | 18 | 3 | 8 | 7 | 329 | 0 | 292 | 7 | 1028 | 7 | 1024 | 6 | 1314 | 2 | 1312 | 8 | 2212 | 7 | 2306 | 0 |
| 16 | 18 | 4 | 8 | 8 | 329 | 1 | 292 | 8 | 1028 | 8 | 1024 | 7 | 1314 | 3 | 1312 | 9 | 2212 | 8 | 2306 | 1 |
| 17 | 20 | 5 | 8 | 9 | 329 | 2 | 292 | 9 | 1028 | 9 | 1029 | 0 | 1314 | 4 | 1317 | 0 | 2212 | 9 | 2306 | 2 |
| 18 | 20 | 6 | 16 | 5 | 330 | 0 | 296 | 5 | 1032 | 5 | 1029 | 1 | 1316 | 5 | 1317 | 1 | 2216 | 5 | 2306 | 3 |
| 19 | 20 | 7 | 16 | 6 | 330 | 1 | 296 | 6 | 1032 | 6 | 1033 | 0 | 1316 | 6 | 1321 | 0 | 2216 | 6 | 2306 | 4 |
| 20 | 20 | 8 | 16 | 7 | 330 | 2 | 296 | 7 | 1032 | 7 | 1033 | 1 | 1316 | 7 | 1321 | 1 | 2216 | 7 | 2308 | 5 |
| 21 | 20 | 9 | 16 | 8 | 330 | 3 | 296 | 8 | 1032 | 8 | 1033 | 2 | 1316 | 8 | 1321 | 2 | 2216 | 8 | 2308 | 6 |
| 22 | 33 | 0 | 16 | 9 | 337 | 0 | 296 | 9 | 1032 | 9 | 1034 | 0 | 1316 | 9 | 1322 | 0 | 2216 | 9 | 2308 | 7 |
| 23 | 33 | 1 | 21 | 0 | 337 | 1 | 321 | 0 | 1040 | 5 | 1034 | 1 | 1320 | 5 | 1322 | 1 | 2304 | 5 | 2308 | 8 |
| 24 | 33 | 2 | 21 | 1 | 337 | 2 | 321 | 1 | 1040 | 6 | 1034 | 2 | 1320 | 6 | 1322 | 2 | 2304 | 6 | 2308 | 9 |
| 25 | 34 | 0 | 32 | 5 | 338 | 0 | 321 | 2 | 1040 | 7 | 1034 | 3 | 1320 | 7 | 1344 | 5 | 2304 | 7 | 2312 | 5 |
| 26 | 34 | 1 | 32 | 6 | 338 | 1 | 322 | 0 | 1040 | 8 | 1041 | 0 | 1320 | 8 | 1344 | 6 | 2304 | 8 | 2312 | 6 |
| 27 | 34 | 2 | 32 | 7 | 338 | 2 | 322 | 1 | 1040 | 9 | 1041 | 1 | 1320 | 9 | 1344 | 7 | 2309 | 0 | 2312 | 7 |
| 28 | 34 | 3 | 32 | 8 | 338 | 3 | 322 | 2 | 1045 | 0 | 1041 | 2 | 1345 | 0 | 1344 | 8 | 2309 | 1 | 2312 | 8 |
| 29 | 34 | 4 | 32 | 9 | 338 | 4 | 322 | 3 | 1045 | 1 | 1042 | 0 | 1345 | 1 | 1344 | 9 | 2313 | 0 | 2312 | 9 |
| 30 | 36 | 5 | 37 | 0 | 513 | 0 | 322 | 4 | 1056 | 5 | 1042 | 1 | 1345 | 2 | 1349 | 0 | 2313 | 1 | 2320 | 5 |
| 31 | 36 | 6 | 37 | 1 | 513 | 1 | 324 | 5 | 1056 | 6 | 1042 | 2 | 1346 | 0 | 1349 | 1 | 2313 | 2 | 2320 | 6 |
| 32 | 36 | 7 | 41 | 0 | 513 | 2 | 324 | 6 | 1056 | 7 | 1042 | 3 | 1346 | 1 | 1353 | 0 | 2314 | 0 | 2320 | 7 |
| 33 | 36 | 8 | 41 | 1 | 514 | 0 | 324 | 7 | 1056 | 8 | 1042 | 4 | 1346 | 2 | 1353 | 1 | 2314 | 1 | 2320 | 8 |
| 34 | 36 | 9 | 41 | 2 | 514 | 1 | 324 | 8 | 1056 | 9 | 1044 | 5 | 1346 | 3 | 1353 | 2 | 2314 | 2 | 2320 | 9 |
| 35 | 40 | 5 | 42 | 0 | 514 | 2 | 324 | 9 | 1061 | 0 | 1044 | 6 | 1346 | 4 | 1354 | 0 | 2314 | 3 | 2325 | 0 |
| 36 | 40 | 6 | 42 | 1 | 514 | 3 | 328 | 5 | 1061 | 1 | 1044 | 7 | 1348 | 5 | 1354 | 1 | 2321 | 0 | 2325 | 1 |
| 37 | 40 | 7 | 42 | 2 | 514 | 4 | 328 | 6 | 1065 | 0 | 1044 | 8 | 1348 | 6 | 1354 | 2 | 2321 | 1 | 2336 | 5 |
| 38 | 40 | 8 | 64 | 5 | 516 | 5 | 328 | 7 | 1065 | 1 | 1044 | 9 | 1348 | 7 | 1354 | 3 | 2321 | 2 | 2336 | 6 |
| 39 | 40 | 9 | 64 | 6 | 516 | 6 | 328 | 8 | 1065 | 2 | 1057 | 0 | 1348 | 8 | 2048 | 5 | 2322 | 0 | 2336 | 7 |
| 40 | 65 | 0 | 64 | 7 | 516 | 7 | 328 | 9 | 1066 | 0 | 1057 | 1 | 1348 | 9 | 2048 | 6 | 2322 | 1 | 2336 | 8 |
| 41 | 65 | 1 | 64 | 8 | 516 | 8 | 336 | 5 | 1066 | 1 | 1057 | 2 | 1352 | 5 | 2048 | 7 | 2322 | 2 | 2336 | 9 |
| 42 | 65 | 2 | 64 | 9 | 516 | 9 | 336 | 6 | 1066 | 2 | 1058 | 0 | 1352 | 6 | 2053 | 0 | 2322 | 3 | 2341 | 0 |
| 43 | 66 | 0 | 69 | 0 | 520 | 5 | 336 | 7 | 1088 | 5 | 1058 | 1 | 1352 | 7 | 2053 | 1 | 2322 | 4 | 2341 | 1 |
| 44 | 66 | 1 | 69 | 1 | 520 | 6 | 336 | 8 | 1088 | 6 | 1058 | 2 | 1352 | 8 | 2057 | 0 | 2324 | 5 | 2345 | 0 |
| 45 | 66 | 2 | 73 | 0 | 520 | 7 | 336 | 9 | 1088 | 7 | 1058 | 3 | 1352 | 9 | 2057 | 1 | 2324 | 6 | 2345 | 1 |
| 46 | 66 | 3 | 73 | 1 | 520 | 8 | 512 | 5 | 1088 | 8 | 1058 | 4 | 2049 | 0 | 2057 | 2 | 2324 | 7 | 2345 | 2 |
| 47 | 66 | 4 | 73 | 2 | 520 | 9 | 512 | 6 | 1088 | 9 | 1060 | 5 | 2049 | 1 | 2058 | 0 | 2324 | 8 | 2346 | 0 |
| 48 | 68 | 5 | 74 | 0 | 528 | 5 | 512 | 7 | 1093 | 0 | 1060 | 6 | 2049 | 2 | 2058 | 1 | 2324 | 9 | 2346 | 1 |
| 49 | 68 | 6 | 74 | 1 | 528 | 6 | 512 | 8 | 1093 | 1 | 1060 | 7 | 2050 | 0 | 2058 | 2 | 2337 | 0 | 2346 | 2 |
| 50 | 68 | 7 | 74 | 2 | 528 | 7 | 517 | 0 | 1097 | 0 | 1060 | 8 | 2050 | 1 | 2058 | 3 | 2337 | 1 | 2368 | 5 |
| 51 | 68 | 8 | 74 | 3 | 528 | 8 | 517 | 1 | 1097 | 1 | 1060 | 9 | 2050 | 2 | 2065 | 0 | 2337 | 2 | 2368 | 6 |
| 52 | 68 | 9 | 81 | 0 | 528 | 9 | 521 | 0 | 1097 | 2 | 1064 | 5 | 2050 | 3 | 2065 | 1 | 2338 | 0 | 2368 | 7 |
| 53 | 72 | 5 | 81 | 1 | 533 | 0 | 521 | 1 | 1098 | 0 | 1064 | 6 | 2050 | 4 | 2065 | 2 | 2338 | 1 | 2368 | 8 |
| 54 | 72 | 6 | 81 | 2 | 533 | 1 | 521 | 2 | 1098 | 1 | 1064 | 7 | 2052 | 5 | 2066 | 0 | 2338 | 2 | 2368 | 9 |
| 55 | 72 | 7 | 82 | 0 | 544 | 5 | 522 | 0 | 1098 | 2 | 1064 | 8 | 2052 | 6 | 2066 | 1 | 2338 | 3 | 2373 | 0 |
| 56 | 72 | 8 | 82 | 1 | 544 | 6 | 522 | 1 | 1098 | 3 | 1064 | 9 | 2052 | 7 | 2066 | 2 | 2338 | 4 | 2373 | 1 |
| 57 | 72 | 9 | 82 | 2 | 544 | 7 | 522 | 2 | 1105 | 0 | 1089 | 0 | 2052 | 8 | 2066 | 3 | 2340 | 5 | 2377 | 0 |
| 58 | 80 | 5 | 82 | 3 | 544 | 8 | 522 | 3 | 1105 | 1 | 1089 | 1 | 2052 | 9 | 2066 | 4 | 2340 | 6 | 2377 | 1 |
| 59 | 80 | 6 | 82 | 4 | 544 | 9 | 529 | 0 | 1105 | 2 | 1089 | 2 | 2056 | 5 | 2068 | 5 | 2340 | 7 | 2377 | 2 |
| 60 | 80 | 7 | 84 | 5 | 549 | 0 | 529 | 1 | 1106 | 0 | 1090 | 0 | 2056 | 6 | 2068 | 6 | 2340 | 8 | 2378 | 0 |
| 61 | 80 | 8 | 84 | 6 | 549 | 1 | 529 | 2 | 1106 | 1 | 1090 | 1 | 2056 | 7 | 2068 | 7 | 2340 | 9 | 2378 | 1 |
| 62 | 80 | 9 | 84 | 7 | 553 | 0 | 530 | 0 | 1106 | 2 | 1090 | 2 | 2056 | 8 | 2068 | 8 | 2344 | 5 | 2378 | 2 |
| 63 | 129 | 0 | 84 | 8 | 553 | 1 | 530 | 1 | 1106 | 3 | 1090 | 3 | 2056 | 9 | 2068 | 9 | 2344 | 6 | 2378 | 3 |
| 64 | 129 | 1 | 84 | 9 | 553 | 2 | 530 | 2 | 1106 | 4 | 1090 | 4 | 2064 | 5 | 2081 | 0 | 2344 | 7 | 2385 | 0 |
| 65 | 129 | 2 | 128 | 5 | 554 | 0 | 530 | 3 | 1108 | 5 | 1092 | 5 | 2064 | 6 | 2081 | 1 | 2344 | 8 | 2385 | 1 |
| 66 | 130 | 0 | 128 | 6 | 554 | 1 | 530 | 4 | 1108 | 6 | 1092 | 6 | 2064 | 7 | 2081 | 2 | 2344 | 9 | 2385 | 2 |
| 67 | 130 | 1 | 128 | 7 | 554 | 2 | 532 | 5 | 1108 | 7 | 1092 | 7 | 2064 | 8 | 2082 | 0 | 2369 | 0 | 2386 | 0 |
| 68 | 130 | 2 | 128 | 8 | 576 | 5 | 532 | 6 | 1108 | 8 | 1092 | 8 | 2064 | 9 | 2082 | 1 | 2369 | 1 | 2386 | 1 |
| 69 | 130 | 3 | 133 | 0 | 576 | 6 | 532 | 7 | 1108 | 9 | 1092 | 9 | 2069 | 0 | 2082 | 2 | 2369 | 2 | 2386 | 2 |
| 70 | 130 | 4 | 133 | 1 | 576 | 7 | 532 | 8 | 1152 | 5 | 1096 | 5 | 2069 | 1 | 2082 | 3 | 2370 | 0 | 2386 | 3 |
| 71 | 132 | 5 | 137 | 0 | 576 | 8 | 532 | 9 | 1152 | 6 | 1096 | 6 | 2080 | 5 | 2082 | 4 | 2370 | 1 | 2386 | 4 |
| 72 | 132 | 6 | 137 | 1 | 576 | 9 | 545 | 0 | 1152 | 7 | 1096 | 7 | 2080 | 6 | 2084 | 5 | 2370 | 2 | 2561 | 0 |
| 73 | 132 | 7 | 137 | 2 | 581 | 0 | 545 | 1 | 1152 | 8 | 1096 | 8 | 2080 | 7 | 2084 | 6 | 2370 | 3 | 2561 | 1 |
| 74 | 132 | 8 | 138 | 0 | 581 | 1 | 545 | 2 | 1157 | 0 | 1096 | 9 | 2080 | 8 | 2084 | 7 | 2370 | 4 | 2561 | 2 |
| 75 | 132 | 9 | 138 | 1 | 585 | 0 | 546 | 0 | 1157 | 1 | 1104 | 5 | 2080 | 9 | 2084 | 8 | 2372 | 5 | 2562 | 0 |
| 76 | 136 | 5 | 138 | 2 | 585 | 1 | 546 | 1 | 1161 | 0 | 1104 | 6 | 2085 | 0 | 2084 | 9 | 2372 | 6 | 2562 | 1 |
| 77 | 136 | 6 | 138 | 3 | 585 | 2 | 546 | 2 | 1161 | 1 | 1104 | 7 | 2085 | 1 | 2088 | 5 | 2372 | 7 | 2562 | 2 |
| 78 | 136 | 7 | 145 | 0 | 586 | 0 | 546 | 3 | 1161 | 2 | 1104 | 8 | 2089 | 0 | 2088 | 6 | 2372 | 8 | 2562 | 3 |
| 79 | 136 | 8 | 145 | 1 | 586 | 1 | 546 | 4 | 1162 | 0 | 1104 | 9 | 2089 | 1 | 2088 | 7 | 2372 | 9 | 2562 | 4 |
| 80 | 136 | 9 | 145 | 2 | 586 | 2 | 548 | 5 | 1162 | 1 | 1153 | 0 | 2089 | 2 | 2088 | 8 | 2376 | 5 | 2564 | 5 |
| 81 | 144 | 5 | 146 | 0 | 586 | 3 | 548 | 6 | 1162 | 2 | 1153 | 1 | 2090 | 0 | 2088 | 9 | 2376 | 6 | 2564 | 6 |
| 82 | 144 | 6 | 146 | 1 | 593 | 0 | 548 | 7 | 1162 | 3 | 1153 | 2 | 2090 | 1 | 2113 | 0 | 2376 | 7 | 2564 | 7 |
| 83 | 144 | 7 | 146 | 2 | 593 | 1 | 548 | 8 | 1169 | 0 | 1154 | 0 | 2090 | 2 | 2113 | 1 | 2376 | 8 | 2564 | 8 |
| 84 | 144 | 8 | 146 | 3 | 593 | 2 | 548 | 9 | 1169 | 1 | 1154 | 1 | 2112 | 5 | 2113 | 2 | 2376 | 9 | 2564 | 9 |
| 85 | 144 | 9 | 146 | 4 | 594 | 0 | 552 | 5 | 1169 | 2 | 1154 | 2 | 2112 | 6 | 2114 | 0 | 2384 | 5 | 2568 | 5 |
| 86 | 149 | 0 | 148 | 5 | 594 | 1 | 552 | 6 | 1170 | 0 | 1154 | 3 | 2112 | 7 | 2114 | 1 | 2384 | 6 | 2568 | 6 |
| 87 | 149 | 1 | 148 | 6 | 594 | 2 | 552 | 7 | 1170 | 1 | 1154 | 4 | 2112 | 8 | 2114 | 2 | 2384 | 7 | 2568 | 7 |
| 88 | 160 | 5 | 148 | 7 | 594 | 3 | 552 | 8 | 1170 | 2 | 1156 | 5 | 2112 | 9 | 2114 | 3 | 2384 | 8 | 2568 | 8 |
| 89 | 160 | 6 | 148 | 8 | 594 | 4 | 552 | 9 | 1170 | 3 | 1156 | 6 | 2117 | 0 | 2114 | 4 | 2384 | 9 | 2568 | 9 |
| 90 | 160 | 7 | 148 | 9 | 596 | 5 | 577 | 0 | 1170 | 4 | 1156 | 7 | 2117 | 1 | 2116 | 5 | 2560 | 5 | 2576 | 5 |
| 91 | 160 | 8 | 161 | 0 | 596 | 6 | 577 | 1 | 1172 | 5 | 1156 | 8 | 2121 | 0 | 2116 | 6 | 2560 | 6 | 2576 | 6 |
| 92 | 160 | 9 | 161 | 1 | 596 | 7 | 577 | 2 | 1172 | 6 | 1156 | 9 | 2121 | 1 | 2116 | 7 | 2560 | 7 | 2576 | 7 |
| 93 | 165 | 0 | 161 | 2 | 596 | 8 | 578 | 0 | 1172 | 7 | 1160 | 5 | 2121 | 2 | 2116 | 8 | 2560 | 8 | 2576 | 8 |
| 94 | 165 | 1 | 162 | 0 | 596 | 9 | 578 | 1 | 1172 | 8 | 1160 | 6 | 2122 | 0 | 2116 | 9 | 2565 | 0 | 2576 | 9 |
| 95 | 169 | 0 | 162 | 1 | 640 | 5 | 578 | 2 | 1172 | 9 | 1160 | 7 | 2122 | 1 | 2120 | 5 | 2565 | 1 | 2581 | 0 |
| 96 | 169 | 1 | 162 | 2 | 640 | 6 | 578 | 3 | 1185 | 0 | 1160 | 8 | 2122 | 2 | 2120 | 6 | 2569 | 0 | 2581 | 1 |
| 97 | 169 | 2 | 162 | 3 | 640 | 7 | 578 | 4 | 1185 | 1 | 1160 | 9 | 2122 | 3 | 2120 | 7 | 2569 | 1 | 2592 | 5 |
| 98 | 257 | 0 | 162 | 4 | 640 | 8 | 580 | 5 | 1185 | 2 | 1168 | 5 | 2129 | 0 | 2120 | 8 | 2569 | 2 | 2592 | 6 |
| 99 | 257 | 1 | 164 | 5 | 645 | 0 | 580 | 6 | 1186 | 0 | 1168 | 6 | 2129 | 1 | 2120 | 9 | 2570 | 0 | 2592 | 7 |
| 100 | 257 | 2 | 164 | 6 | 645 | 1 | 580 | 7 | 1186 | 1 | 1168 | 7 | 2129 | 2 | 2128 | 5 | 2570 | 1 | 2592 | 8 |
| 101 | 258 | 0 | 164 | 7 | 649 | 0 | 580 | 8 | 1186 | 2 | 1168 | 8 | 2130 | 0 | 2128 | 6 | 2570 | 2 | 2592 | 9 |
| 102 | 258 | 1 | 164 | 8 | 649 | 1 | 580 | 9 | 1186 | 3 | 1168 | 9 | 2130 | 1 | 2128 | 7 | 2570 | 3 | 2597 | 0 |
| 103 | 258 | 2 | 164 | 9 | 649 | 2 | 584 | 5 | 1186 | 4 | 1173 | 0 | 2130 | 2 | 2128 | 8 | 2577 | 0 | 2597 | 1 |
| 104 | 258 | 3 | 168 | 5 | 650 | 0 | 584 | 6 | 1188 | 5 | 1173 | 1 | 2130 | 3 | 2128 | 9 | 2577 | 1 | 2601 | 0 |
| 105 | 258 | 4 | 168 | 6 | 650 | 1 | 584 | 7 | 1188 | 6 | 1184 | 5 | 2130 | 4 | 2177 | 0 | 2577 | 2 | 2601 | 1 |
| 106 | 260 | 5 | 168 | 7 | 650 | 2 | 584 | 8 | 1188 | 7 | 1184 | 6 | 2132 | 5 | 2177 | 1 | 2578 | 0 | 2601 | 2 |
| 107 | 260 | 6 | 168 | 8 | 650 | 3 | 584 | 9 | 1188 | 8 | 1184 | 7 | 2132 | 6 | 2177 | 2 | 2578 | 1 | 2602 | 0 |
| 108 | 260 | 7 | 168 | 9 | 657 | 0 | 592 | 5 | 1188 | 9 | 1184 | 8 | 2132 | 7 | 2178 | 0 | 2578 | 2 | 2602 | 1 |
| 109 | 260 | 8 | 256 | 5 | 657 | 1 | 592 | 6 | 1192 | 5 | 1184 | 9 | 2132 | 8 | 2178 | 1 | 2578 | 3 | 2602 | 2 |
| 110 | 260 | 9 | 256 | 6 | 657 | 2 | 592 | 7 | 1192 | 6 | 1189 | 0 | 2132 | 9 | 2178 | 2 | 2578 | 4 | 2624 | 5 |
| 111 | 264 | 5 | 256 | 7 | 658 | 0 | 592 | 8 | 1192 | 7 | 1189 | 1 | 2176 | 5 | 2178 | 3 | 2580 | 5 | 2624 | 6 |
| 112 | 264 | 6 | 256 | 8 | 658 | 1 | 592 | 9 | 1192 | 8 | 1193 | 0 | 2176 | 6 | 2178 | 4 | 2580 | 6 | 2624 | 7 |
| 113 | 264 | 7 | 261 | 0 | 658 | 2 | 641 | 0 | 1192 | 9 | 1193 | 1 | 2176 | 7 | 2180 | 5 | 2580 | 7 | 2624 | 8 |
| 114 | 264 | 8 | 261 | 1 | 658 | 3 | 641 | 1 | 1280 | 5 | 1193 | 2 | 2176 | 8 | 2180 | 6 | 2580 | 8 | 2624 | 9 |
| 115 | 264 | 9 | 265 | 0 | 658 | 4 | 641 | 2 | 1280 | 6 | 1281 | 0 | 2181 | 0 | 2180 | 7 | 2580 | 9 | 2629 | 0 |
| 116 | 272 | 5 | 265 | 1 | 660 | 5 | 642 | 0 | 1280 | 7 | 1281 | 1 | 2181 | 1 | 2180 | 8 | 2593 | 0 | 2629 | 1 |
| 117 | 272 | 6 | 265 | 2 | 660 | 6 | 642 | 1 | 1280 | 8 | 1281 | 2 | 2185 | 0 | 2180 | 9 | 2593 | 1 | 2633 | 0 |
| 118 | 272 | 7 | 266 | 0 | 660 | 7 | 642 | 2 | 1285 | 0 | 1282 | 0 | 2185 | 1 | 2184 | 5 | 2593 | 2 | 2633 | 1 |
| 119 | 272 | 8 | 266 | 1 | 660 | 8 | 642 | 3 | 1285 | 1 | 1282 | 1 | 2185 | 2 | 2184 | 6 | 2594 | 0 | 2633 | 2 |
| 120 | 272 | 9 | 266 | 2 | 660 | 9 | 642 | 4 | 1289 | 0 | 1282 | 2 | 2186 | 0 | 2184 | 7 | 2594 | 1 | 2634 | 0 |
| 121 | 277 | 0 | 266 | 3 | 673 | 0 | 644 | 5 | 1289 | 1 | 1282 | 3 | 2186 | 1 | 2184 | 8 | 2594 | 2 | 2634 | 1 |
| 122 | 277 | 1 | 273 | 0 | 673 | 1 | 644 | 6 | 1289 | 2 | 1282 | 4 | 2186 | 2 | 2184 | 9 | 2594 | 3 | 2634 | 2 |
| 123 | 288 | 5 | 273 | 1 | 673 | 2 | 644 | 7 | 1290 | 0 | 1284 | 5 | 2186 | 3 | 2192 | 5 | 2594 | 4 | 2634 | 3 |
| 124 | 288 | 6 | 273 | 2 | 674 | 0 | 644 | 8 | 1290 | 1 | 1284 | 6 | 2193 | 0 | 2192 | 6 | 2596 | 5 | 2641 | 0 |
| 125 | 288 | 7 | 274 | 0 | 674 | 1 | 644 | 9 | 1290 | 2 | 1284 | 7 | 2193 | 1 | 2192 | 7 | 2596 | 6 | 2641 | 1 |
| 126 | 288 | 8 | 274 | 1 | 674 | 2 | 648 | 5 | 1290 | 3 | 1284 | 8 | 2193 | 2 | 2192 | 8 | 2596 | 7 | 2641 | 2 |
| 127 | 288 | 9 | 274 | 2 | 674 | 3 | 648 | 6 | 1297 | 0 | 1284 | 9 | 2194 | 0 | 2192 | 9 | 2596 | 8 | 2642 | 0 |
| | S5 | | | | S6 | | | | S7 | | | | S8 | | | | S9 | | | |
| | Even | | Odd | | Even | | Odd | | Even | | Odd | | Even | | Odd | | Even | | Odd | |
| 0 | 2196 | 5 | 2197 | 0 | 1298 | 0 | 1288 | 5 | 2600 | 9 | 2644 | 7 | 293 | 0 | 276 | 5 | 676 | 5 | 656 | 5 |
| 1 | 2196 | 6 | 2197 | 1 | 1298 | 1 | 1288 | 6 | 2596 | 9 | 2644 | 8 | 293 | 1 | 276 | 6 | 676 | 6 | 656 | 6 |
| 2 | 2196 | 7 | 2208 | 5 | 1298 | 2 | 1288 | 7 | 2600 | 5 | 2644 | 9 | 297 | 0 | 276 | 7 | 676 | 7 | 656 | 7 |
| 3 | 2196 | 8 | 2208 | 6 | 1297 | 1 | 1288 | 8 | 2600 | 6 | 2688 | 5 | 297 | 1 | 276 | 8 | 676 | 8 | 656 | 8 |
| 4 | 2196 | 9 | 2208 | 7 | 1297 | 2 | 1288 | 9 | 2600 | 8 | 2688 | 6 | 297 | 2 | 276 | 9 | 676 | 9 | 656 | 9 |
| 5 | 2209 | 0 | 2208 | 8 | 1025 | 0 | 1296 | 5 | 1300 | 5 | 2693 | 1 | 298 | 0 | 289 | 0 | 2626 | 2 | 661 | 0 |
| 6 | 2209 | 1 | 2208 | 9 | 1025 | 1 | 1296 | 6 | 1300 | 6 | 2697 | 0 | 298 | 1 | 289 | 1 | 2626 | 3 | 661 | 1 |
| 7 | 2209 | 2 | 2213 | 0 | 1025 | 2 | 1296 | 7 | 1300 | 7 | 2697 | 1 | 298 | 2 | 289 | 2 | 2626 | 4 | 672 | 5 |
| 8 | 2210 | 0 | 2213 | 1 | 1026 | 0 | 1296 | 8 | 1300 | 8 | 2697 | 2 | 320 | 5 | 290 | 0 | 2628 | 5 | 672 | 6 |
| 9 | 2210 | 1 | 2217 | 0 | 1026 | 1 | 1296 | 9 | 1300 | 9 | 2698 | 0 | 320 | 6 | 290 | 1 | 2628 | 6 | 672 | 7 |
| 10 | 2210 | 2 | 2217 | 1 | 1026 | 2 | 1301 | 0 | 1313 | 0 | 2698 | 1 | 320 | 7 | 290 | 2 | 2628 | 8 | 672 | 8 |
| 11 | 2210 | 3 | 2217 | 2 | 1026 | 3 | 1301 | 1 | 1313 | 1 | 2642 | 1 | 320 | 8 | 290 | 3 | 2628 | 9 | 672 | 9 |
| 12 | 2210 | 4 | 2305 | 0 | 1026 | 4 | 1312 | 5 | 1313 | 2 | 2642 | 2 | 320 | 9 | 290 | 4 | 2632 | 5 | 677 | 0 |
| 13 | 2212 | 5 | 2305 | 1 | 1028 | 5 | 1312 | 6 | 1314 | 0 | 2642 | 3 | 325 | 0 | 292 | 5 | 2632 | 6 | 677 | 1 |
| 14 | 2212 | 6 | 2305 | 2 | 1028 | 6 | 1024 | 5 | 1314 | 1 | 2642 | 4 | 325 | 1 | 292 | 6 | 2632 | 7 | 648 | 9 |
| 15 | 2212 | 7 | 2306 | 0 | 1028 | 7 | 1024 | 6 | 1314 | 2 | 2644 | 5 | 329 | 0 | 292 | 7 | 2632 | 8 | 2706 | 0 |
| 16 | 2212 | 8 | 2306 | 1 | 1028 | 8 | 1024 | 7 | 1314 | 3 | 2644 | 6 | 329 | 1 | 292 | 8 | 674 | 4 | 2706 | 4 |
| 17 | 2212 | 9 | 2306 | 2 | 1028 | 9 | 1029 | 0 | 1314 | 4 | 1317 | 0 | 329 | 2 | 292 | 9 | 2625 | 0 | 2706 | 1 |
| 18 | 2216 | 5 | 2306 | 3 | 1032 | 5 | 1029 | 1 | 1316 | 5 | 1317 | 1 | 330 | 0 | 296 | 5 | 2625 | 1 | 2706 | 2 |
| 19 | 2216 | 6 | 2306 | 4 | 1032 | 6 | 1033 | 0 | 1316 | 6 | 1321 | 0 | 330 | 1 | 296 | 6 | 2625 | 2 | 2706 | 3 |
| 20 | 2216 | 7 | 2308 | 5 | 1032 | 7 | 1033 | 1 | 1316 | 7 | 1321 | 1 | 330 | 2 | 296 | 7 | 2626 | 0 | 648 | 7 |
| 21 | 2216 | 8 | 2308 | 6 | 1032 | 8 | 1033 | 2 | 1316 | 8 | 1321 | 2 | 330 | 3 | 296 | 8 | 2626 | 1 | 648 | 8 |
| 22 | 2216 | 9 | 2308 | 7 | 1032 | 9 | 1034 | 0 | 1316 | 9 | 1322 | 0 | 337 | 0 | 296 | 9 | 33 | 0 | 2705 | 0 |
| 23 | 2304 | 5 | 2308 | 8 | 1040 | 5 | 1034 | 1 | 1320 | 5 | 1322 | 1 | 337 | 1 | 321 | 0 | 33 | 1 | 2705 | 1 |
| 24 | 2304 | 6 | 2308 | 9 | 1040 | 6 | 1034 | 2 | 1320 | 6 | 1322 | 2 | 337 | 2 | 321 | 1 | 33 | 2 | 2705 | 2 |
| 25 | 2304 | 7 | 2312 | 5 | 1040 | 7 | 1034 | 3 | 1320 | 7 | 1344 | 5 | 338 | 0 | 321 | 2 | 34 | 0 | 32 | 5 |
| 26 | 2304 | 8 | 2312 | 6 | 1040 | 8 | 1041 | 0 | 1320 | 8 | 1344 | 6 | 338 | 1 | 322 | 0 | 34 | 1 | 32 | 6 |
| 27 | 2309 | 0 | 2312 | 7 | 1040 | 9 | 1041 | 1 | 1320 | 9 | 1344 | 7 | 338 | 2 | 322 | 1 | 34 | 2 | 32 | 7 |
| 28 | 2309 | 1 | 2312 | 8 | 1045 | 0 | 1041 | 2 | 1345 | 0 | 1344 | 8 | 338 | 3 | 322 | 2 | 34 | 3 | 32 | 8 |
| 29 | 2313 | 0 | 2312 | 9 | 1045 | 1 | 1042 | 0 | 1345 | 1 | 1344 | 9 | 338 | 4 | 322 | 3 | 34 | 4 | 32 | 9 |
| 30 | 2313 | 1 | 2320 | 5 | 1056 | 5 | 1042 | 1 | 1345 | 2 | 1349 | 0 | 513 | 0 | 322 | 4 | 36 | 5 | 37 | 0 |
| 31 | 2313 | 2 | 2320 | 6 | 1056 | 6 | 1042 | 2 | 1346 | 0 | 1349 | 1 | 513 | 1 | 324 | 5 | 36 | 6 | 37 | 1 |
| 32 | 2314 | 0 | 2320 | 7 | 1056 | 7 | 1042 | 3 | 1346 | 1 | 1353 | 0 | 513 | 2 | 324 | 6 | 36 | 7 | 41 | 0 |
| 33 | 2314 | 1 | 2320 | 8 | 1056 | 8 | 1042 | 4 | 1346 | 2 | 1353 | 1 | 514 | 0 | 324 | 7 | 36 | 8 | 41 | 1 |
| 34 | 2314 | 2 | 2320 | 9 | 1056 | 9 | 1044 | 5 | 1346 | 3 | 1353 | 2 | 514 | 1 | 324 | 8 | 36 | 9 | 41 | 2 |
| 35 | 2314 | 3 | 2325 | 0 | 1061 | 0 | 1044 | 6 | 1346 | 4 | 1354 | 0 | 514 | 2 | 324 | 9 | 40 | 5 | 42 | 0 |
| 36 | 2321 | 0 | 2325 | 1 | 1061 | 1 | 1044 | 7 | 1348 | 5 | 1354 | 1 | 514 | 3 | 328 | 5 | 40 | 6 | 42 | 1 |
| 37 | 2321 | 1 | 2336 | 5 | 1065 | 0 | 1044 | 8 | 1348 | 6 | 1354 | 2 | 514 | 4 | 328 | 6 | 40 | 7 | 42 | 2 |
| 38 | 2321 | 2 | 2336 | 6 | 1065 | 1 | 1044 | 9 | 1348 | 7 | 1354 | 3 | 516 | 5 | 328 | 7 | 40 | 8 | 64 | 5 |
| 39 | 2322 | 0 | 2048 | 5 | 1065 | 2 | 1057 | 0 | 1348 | 8 | 2688 | 7 | 516 | 6 | 328 | 8 | 40 | 9 | 64 | 6 |
| 40 | 2322 | 1 | 2048 | 6 | 1066 | 0 | 1057 | 1 | 1348 | 9 | 2688 | 8 | 516 | 7 | 328 | 9 | 65 | 0 | 64 | 7 |
| 41 | 2322 | 2 | 2048 | 7 | 1066 | 1 | 1057 | 2 | 1352 | 5 | 2693 | 0 | 516 | 8 | 336 | 5 | 65 | 1 | 64 | 8 |
| 42 | 2194 | 3 | 2053 | 0 | 1066 | 2 | 1058 | 0 | 1352 | 6 | 2341 | 0 | 516 | 9 | 336 | 6 | 65 | 2 | 64 | 9 |
| 43 | 2194 | 4 | 2053 | 1 | 1088 | 5 | 1058 | 1 | 1352 | 7 | 2341 | 1 | 520 | 5 | 336 | 7 | 66 | 0 | 69 | 0 |
| 44 | 2194 | 1 | 2057 | 0 | 1088 | 6 | 1058 | 2 | 2324 | 5 | 2345 | 0 | 520 | 6 | 336 | 8 | 66 | 1 | 69 | 1 |
| 45 | 2194 | 2 | 2057 | 1 | 1088 | 7 | 1058 | 3 | 2324 | 6 | 2345 | 1 | 520 | 7 | 336 | 9 | 66 | 2 | 73 | 0 |
| 46 | 2049 | 0 | 2057 | 2 | 1088 | 8 | 1058 | 4 | 2324 | 7 | 2345 | 2 | 520 | 8 | 512 | 5 | 66 | 3 | 73 | 1 |
| 47 | 2049 | 1 | 2058 | 0 | 1088 | 9 | 1060 | 5 | 2324 | 8 | 2346 | 0 | 520 | 9 | 512 | 6 | 66 | 4 | 73 | 2 |
| 48 | 2049 | 2 | 2058 | 1 | 1093 | 0 | 1060 | 6 | 2324 | 9 | 2346 | 1 | 528 | 5 | 512 | 7 | 68 | 5 | 74 | 0 |
| 49 | 2050 | 0 | 2058 | 2 | 1093 | 1 | 1060 | 7 | 2337 | 0 | 2346 | 2 | 528 | 6 | 512 | 8 | 68 | 6 | 74 | 1 |
| 50 | 2050 | 1 | 2058 | 3 | 1097 | 0 | 1060 | 8 | 2337 | 1 | 2368 | 5 | 528 | 7 | 517 | 0 | 68 | 7 | 74 | 2 |
| 51 | 2050 | 2 | 2065 | 0 | 1097 | 1 | 1060 | 9 | 2337 | 2 | 2368 | 6 | 528 | 8 | 517 | 1 | 68 | 8 | 74 | 3 |
| 52 | 2050 | 3 | 2065 | 1 | 1097 | 2 | 1064 | 5 | 2338 | 0 | 2368 | 7 | 528 | 9 | 521 | 0 | 68 | 9 | 81 | 0 |
| 53 | 2050 | 4 | 2065 | 2 | 1098 | 0 | 1064 | 6 | 2338 | 1 | 2368 | 8 | 533 | 0 | 521 | 1 | 72 | 5 | 81 | 1 |
| 54 | 2052 | 5 | 2066 | 0 | 1098 | 1 | 1064 | 7 | 2338 | 2 | 2368 | 9 | 533 | 1 | 521 | 2 | 72 | 6 | 81 | 2 |
| 55 | 2052 | 6 | 2066 | 1 | 1098 | 2 | 1064 | 8 | 2338 | 3 | 2373 | 0 | 544 | 5 | 522 | 0 | 72 | 7 | 82 | 0 |
| 56 | 2052 | 7 | 2066 | 2 | 1098 | 3 | 1064 | 9 | 2338 | 4 | 2373 | 1 | 544 | 6 | 522 | 1 | 72 | 8 | 82 | 1 |
| 57 | 2052 | 8 | 2066 | 3 | 1105 | 0 | 1089 | 0 | 2340 | 5 | 2377 | 0 | 544 | 7 | 522 | 2 | 72 | 9 | 82 | 2 |
| 58 | 2052 | 9 | 2066 | 4 | 1105 | 1 | 1089 | 1 | 2340 | 6 | 2377 | 1 | 544 | 8 | 522 | 3 | 80 | 5 | 82 | 3 |
| 59 | 2056 | 5 | 2068 | 5 | 1105 | 2 | 1089 | 2 | 2340 | 7 | 2377 | 2 | 544 | 9 | 529 | 0 | 80 | 6 | 82 | 4 |
| 60 | 2056 | 6 | 2068 | 6 | 1106 | 0 | 1090 | 0 | 2340 | 8 | 2378 | 0 | 549 | 0 | 529 | 1 | 80 | 7 | 84 | 5 |
| 61 | 2056 | 7 | 2068 | 7 | 1106 | 1 | 1090 | 1 | 2340 | 9 | 2378 | 1 | 549 | 1 | 529 | 2 | 80 | 8 | 84 | 6 |
| 62 | 2056 | 8 | 2068 | 8 | 1106 | 2 | 1090 | 2 | 2344 | 5 | 2378 | 2 | 553 | 0 | 530 | 0 | 80 | 9 | 84 | 7 |
| 63 | 2056 | 9 | 2068 | 9 | 1106 | 3 | 1090 | 3 | 2344 | 6 | 2378 | 3 | 553 | 1 | 530 | 1 | 129 | 0 | 84 | 8 |
| 64 | 2064 | 5 | 2081 | 0 | 1106 | 4 | 1090 | 4 | 2344 | 7 | 2385 | 0 | 553 | 2 | 530 | 2 | 129 | 1 | 84 | 9 |
| 65 | 2064 | 6 | 2081 | 1 | 1108 | 5 | 1092 | 5 | 2344 | 8 | 2385 | 1 | 554 | 0 | 530 | 3 | 129 | 2 | 128 | 5 |
| 66 | 2064 | 7 | 2081 | 2 | 1108 | 6 | 1092 | 6 | 2344 | 9 | 2385 | 2 | 554 | 1 | 530 | 4 | 130 | 0 | 128 | 6 |
| 67 | 2064 | 8 | 2082 | 0 | 1108 | 7 | 1092 | 7 | 2369 | 0 | 2386 | 0 | 554 | 2 | 532 | 5 | 130 | 1 | 128 | 7 |
| 68 | 2064 | 9 | 2082 | 1 | 1108 | 8 | 1092 | 8 | 2369 | 1 | 2386 | 1 | 576 | 5 | 532 | 6 | 130 | 2 | 128 | 8 |
| 69 | 2069 | 0 | 2082 | 2 | 1108 | 9 | 1092 | 9 | 2369 | 2 | 2386 | 2 | 576 | 6 | 532 | 7 | 130 | 3 | 133 | 0 |
| 70 | 2069 | 1 | 2082 | 3 | 1152 | 5 | 1096 | 5 | 2370 | 0 | 2386 | 3 | 576 | 7 | 532 | 8 | 130 | 4 | 133 | 1 |
| 71 | 2080 | 5 | 2082 | 4 | 1152 | 6 | 1096 | 6 | 2370 | 1 | 2386 | 4 | 576 | 8 | 532 | 9 | 132 | 5 | 137 | 0 |
| 72 | 2080 | 6 | 2084 | 5 | 1152 | 7 | 1096 | 7 | 2370 | 2 | 2561 | 0 | 576 | 9 | 545 | 0 | 132 | 6 | 137 | 1 |
| 73 | 2080 | 7 | 2084 | 6 | 1152 | 8 | 1096 | 8 | 2370 | 3 | 2561 | 1 | 581 | 0 | 545 | 1 | 132 | 7 | 137 | 2 |
| 74 | 2080 | 8 | 2084 | 7 | 1157 | 0 | 1096 | 9 | 2370 | 4 | 2561 | 2 | 581 | 1 | 545 | 2 | 132 | 8 | 138 | 0 |
| 75 | 2080 | 9 | 2084 | 8 | 1157 | 1 | 1104 | 5 | 2372 | 5 | 2562 | 0 | 585 | 0 | 546 | 0 | 132 | 9 | 138 | 1 |
| 76 | 2085 | 0 | 2084 | 9 | 1161 | 0 | 1104 | 6 | 2372 | 6 | 2562 | 1 | 585 | 1 | 546 | 1 | 136 | 5 | 138 | 2 |
| 77 | 2085 | 1 | 2088 | 5 | 1161 | 1 | 1104 | 7 | 2372 | 7 | 2562 | 2 | 585 | 2 | 546 | 2 | 136 | 6 | 138 | 3 |
| 78 | 2089 | 0 | 2088 | 6 | 1161 | 2 | 1104 | 8 | 2372 | 8 | 2562 | 3 | 586 | 0 | 546 | 3 | 136 | 7 | 145 | 0 |
| 79 | 2089 | 1 | 2088 | 7 | 1162 | 0 | 1104 | 9 | 2372 | 9 | 2562 | 4 | 586 | 1 | 546 | 4 | 136 | 8 | 145 | 1 |
| 80 | 2089 | 2 | 2088 | 8 | 1162 | 1 | 1153 | 0 | 2376 | 5 | 2564 | 5 | 586 | 2 | 548 | 5 | 136 | 9 | 145 | 2 |
| 81 | 2090 | 0 | 2088 | 9 | 1162 | 2 | 1153 | 1 | 2376 | 6 | 2564 | 6 | 586 | 3 | 548 | 6 | 144 | 5 | 146 | 0 |
| 82 | 2090 | 1 | 2113 | 0 | 1162 | 3 | 1153 | 2 | 2376 | 7 | 2564 | 7 | 593 | 0 | 548 | 7 | 144 | 6 | 146 | 1 |
| 83 | 2090 | 2 | 2113 | 1 | 1169 | 0 | 1154 | 0 | 2376 | 8 | 2564 | 8 | 593 | 1 | 548 | 8 | 144 | 7 | 146 | 2 |
| 84 | 2112 | 5 | 2113 | 2 | 1169 | 1 | 1154 | 1 | 2376 | 9 | 2564 | 9 | 593 | 2 | 548 | 9 | 144 | 8 | 146 | 3 |
| 85 | 2112 | 6 | 2114 | 0 | 1169 | 2 | 1154 | 2 | 2384 | 5 | 2568 | 5 | 594 | 0 | 552 | 5 | 144 | 9 | 146 | 4 |
| 86 | 2112 | 7 | 2114 | 1 | 1170 | 0 | 1154 | 3 | 2384 | 6 | 2568 | 6 | 594 | 1 | 552 | 6 | 149 | 0 | 148 | 5 |
| 87 | 2112 | 8 | 2114 | 2 | 1170 | 1 | 1154 | 4 | 2384 | 7 | 2568 | 7 | 594 | 2 | 552 | 7 | 149 | 1 | 148 | 6 |
| 88 | 2112 | 9 | 2114 | 3 | 1170 | 2 | 1156 | 5 | 2384 | 8 | 2568 | 8 | 594 | 3 | 552 | 8 | 160 | 5 | 148 | 7 |
| 89 | 2117 | 0 | 2114 | 4 | 1170 | 3 | 1156 | 6 | 2384 | 9 | 2568 | 9 | 594 | 4 | 552 | 9 | 160 | 6 | 148 | 8 |
| 90 | 2117 | 1 | 2116 | 5 | 1170 | 4 | 1156 | 7 | 2560 | 5 | 2576 | 5 | 596 | 5 | 577 | 0 | 160 | 7 | 148 | 9 |
| 91 | 2121 | 0 | 2116 | 6 | 1172 | 5 | 1156 | 8 | 2560 | 6 | 2576 | 6 | 596 | 6 | 577 | 1 | 160 | 8 | 161 | 0 |
| 92 | 2121 | 1 | 2116 | 7 | 1172 | 6 | 1156 | 9 | 2560 | 7 | 2576 | 7 | 596 | 7 | 577 | 2 | 160 | 9 | 161 | 1 |
| 93 | 2121 | 2 | 2116 | 8 | 1172 | 7 | 1160 | 5 | 2560 | 8 | 2576 | 8 | 596 | 8 | 578 | 0 | 165 | 0 | 161 | 2 |
| 94 | 2122 | 0 | 2116 | 9 | 1172 | 8 | 1160 | 6 | 2565 | 0 | 2576 | 9 | 596 | 9 | 578 | 1 | 165 | 1 | 162 | 0 |
| 95 | 2122 | 1 | 2120 | 5 | 1172 | 9 | 1160 | 7 | 2565 | 1 | 2581 | 0 | 640 | 5 | 578 | 2 | 169 | 0 | 162 | 1 |
| 96 | 2122 | 2 | 2120 | 6 | 1185 | 0 | 1160 | 8 | 2569 | 0 | 2581 | 1 | 640 | 6 | 578 | 3 | 169 | 1 | 162 | 2 |
| 97 | 2122 | 3 | 2120 | 7 | 1185 | 1 | 1160 | 9 | 2569 | 1 | 2592 | 5 | 640 | 7 | 578 | 4 | 169 | 2 | 162 | 3 |
| 98 | 2129 | 0 | 2120 | 8 | 1185 | 2 | 1168 | 5 | 2569 | 2 | 2592 | 6 | 257 | 0 | 580 | 5 | 2628 | 7 | 162 | 4 |
| 99 | 2129 | 1 | 2120 | 9 | 1186 | 0 | 1168 | 6 | 2570 | 0 | 2592 | 7 | 257 | 1 | 580 | 6 | 645 | 0 | 164 | 5 |
| 100 | 2129 | 2 | 2128 | 5 | 1186 | 1 | 1168 | 7 | 2570 | 1 | 2592 | 8 | 257 | 2 | 580 | 7 | 645 | 1 | 164 | 6 |
| 101 | 2130 | 0 | 2128 | 6 | 1186 | 2 | 1168 | 8 | 2570 | 2 | 2592 | 9 | 258 | 0 | 580 | 8 | 649 | 0 | 164 | 7 |
| 102 | 2130 | 1 | 2128 | 7 | 1186 | 3 | 1168 | 9 | 2570 | 3 | 2597 | 0 | 258 | 1 | 580 | 9 | 649 | 1 | 164 | 8 |
| 103 | 2130 | 2 | 2128 | 8 | 1186 | 4 | 1173 | 0 | 2577 | 0 | 2597 | 1 | 258 | 2 | 584 | 5 | 649 | 2 | 164 | 9 |
| 104 | 2130 | 3 | 2128 | 9 | 1188 | 5 | 1173 | 1 | 2577 | 1 | 2601 | 0 | 258 | 3 | 584 | 6 | 650 | 0 | 168 | 5 |
| 105 | 2130 | 4 | 2177 | 0 | 1188 | 6 | 1184 | 5 | 2577 | 2 | 2601 | 1 | 258 | 4 | 584 | 7 | 650 | 1 | 168 | 6 |
| 106 | 2132 | 5 | 2177 | 1 | 1188 | 7 | 1184 | 6 | 2578 | 0 | 2601 | 2 | 260 | 5 | 584 | 8 | 650 | 2 | 168 | 7 |
| 107 | 2132 | 6 | 2177 | 2 | 1188 | 8 | 1184 | 7 | 2578 | 1 | 2602 | 0 | 260 | 6 | 274 | 4 | 650 | 3 | 168 | 8 |
| 108 | 2132 | 7 | 2178 | 0 | 1188 | 9 | 1184 | 8 | 2578 | 2 | 2602 | 1 | 260 | 7 | 274 | 3 | 657 | 0 | 592 | 5 |
| 109 | 2132 | 8 | 2178 | 1 | 1192 | 5 | 1184 | 9 | 2578 | 3 | 2602 | 2 | 260 | 8 | 256 | 5 | 657 | 1 | 592 | 6 |
| 110 | 2132 | 9 | 2178 | 2 | 1192 | 6 | 1189 | 0 | 2578 | 4 | 2624 | 5 | 260 | 9 | 256 | 6 | 657 | 2 | 592 | 7 |
| 111 | 2176 | 5 | 2178 | 3 | 1192 | 7 | 1189 | 1 | 2580 | 5 | 2624 | 6 | 264 | 5 | 256 | 7 | 658 | 0 | 592 | 8 |
| 112 | 2176 | 6 | 2178 | 4 | 1192 | 8 | 1193 | 0 | 2580 | 6 | 2624 | 7 | 264 | 6 | 256 | 8 | 658 | 1 | 592 | 9 |
| 113 | 2176 | 7 | 2180 | 5 | 1192 | 9 | 1193 | 1 | 2580 | 7 | 2624 | 8 | 264 | 7 | 261 | 0 | 658 | 2 | 641 | 0 |
| 114 | 2176 | 8 | 2180 | 6 | 1280 | 5 | 1193 | 2 | 2580 | 8 | 2624 | 9 | 264 | 8 | 261 | 1 | 658 | 3 | 641 | 1 |
| 115 | 2181 | 0 | 2180 | 7 | 1280 | 6 | 1281 | 0 | 2580 | 9 | 2629 | 0 | 264 | 9 | 265 | 0 | 658 | 4 | 641 | 2 |
| 116 | 2181 | 1 | 2180 | 8 | 1280 | 7 | 1281 | 1 | 2593 | 0 | 2629 | 1 | 272 | 5 | 265 | 1 | 660 | 5 | 642 | 0 |
| 117 | 2185 | 0 | 2180 | 9 | 1280 | 8 | 1281 | 2 | 2593 | 1 | 2633 | 0 | 272 | 6 | 265 | 2 | 660 | 6 | 642 | 1 |
| 118 | 2185 | 1 | 2184 | 5 | 1285 | 0 | 1282 | 0 | 2593 | 2 | 2633 | 1 | 272 | 7 | 266 | 0 | 660 | 7 | 642 | 2 |
| 119 | 2185 | 2 | 2184 | 6 | 1285 | 1 | 1282 | 1 | 2594 | 0 | 2633 | 2 | 272 | 8 | 266 | 1 | 660 | 8 | 642 | 3 |
| 120 | 2186 | 0 | 2184 | 7 | 1289 | 0 | 1282 | 2 | 2594 | 1 | 2634 | 0 | 272 | 9 | 266 | 2 | 660 | 9 | 642 | 4 |
| 121 | 2186 | 1 | 2184 | 8 | 1289 | 1 | 1282 | 3 | 2594 | 2 | 2634 | 1 | 277 | 0 | 266 | 3 | 673 | 0 | 644 | 5 |
| 122 | 2186 | 2 | 2184 | 9 | 1289 | 2 | 1282 | 4 | 2594 | 3 | 2634 | 2 | 277 | 1 | 273 | 0 | 673 | 1 | 644 | 6 |
| 123 | 2186 | 3 | 2192 | 5 | 1290 | 0 | 1284 | 5 | 2594 | 4 | 2634 | 3 | 288 | 5 | 273 | 1 | 673 | 2 | 644 | 7 |
| 124 | 2193 | 0 | 2192 | 6 | 1290 | 1 | 1284 | 6 | 2596 | 5 | 2641 | 0 | 288 | 6 | 273 | 2 | 674 | 0 | 644 | 8 |
| 125 | 2193 | 1 | 2192 | 7 | 1290 | 2 | 1284 | 7 | 2596 | 6 | 2641 | 1 | 288 | 7 | 274 | 0 | 674 | 1 | 644 | 9 |
| 126 | 2193 | 2 | 2192 | 8 | 1290 | 3 | 1284 | 8 | 2596 | 7 | 2641 | 2 | 288 | 8 | 274 | 1 | 674 | 2 | 648 | 5 |
| 127 | 2194 | 0 | 2192 | 9 | 1297 | 0 | 1284 | 9 | 2596 | 8 | 2642 | 0 | 288 | 9 | 274 | 2 | 674 | 3 | 648 | 6 |

TABLE IV

| | |
|---|---|
| Even | Odd |

State S00 Part-1: Entries 0-31

| | | | | |
|---|---|---|---|---|
| 0 | 000000000101 | 0 | 000000000100 | 8 |
| 1 | 000000000101 | 1 | 000000000100 | 9 |
| 2 | 000000000101 | 2 | 000000000100 | 10 |
| 3 | 000000000101 | 3 | 000000000100 | 11 |
| 4 | 000000001001 | 0 | 000000000100 | 12 |
| 5 | 000000001001 | 1 | 000000000100 | 13 |
| 6 | 000000001001 | 2 | 000000000100 | 14 |
| 7 | 000000001001 | 3 | 000000000100 | 15 |
| 8 | 000000001001 | 4 | 000000001000 | 8 |
| 9 | 000000001010 | 0 | 000000001000 | 9 |
| 10 | 000000001010 | 1 | 000000001000 | 10 |
| 11 | 000000001010 | 2 | 000000001000 | 11 |
| 12 | 000000001010 | 3 | 000000001000 | 12 |
| 13 | 000000001010 | 4 | 000000001000 | 13 |
| 14 | 000000001010 | 5 | 000000001000 | 14 |
| 15 | 000000001010 | 6 | 000000001000 | 15 |
| 16 | 000000010001 | 0 | 000000010000 | 8 |
| 17 | 000000010001 | 1 | 000000010000 | 9 |
| 18 | 000000010001 | 2 | 000000010000 | 10 |
| 19 | 000000010001 | 3 | 000000010000 | 11 |
| 20 | 000000010001 | 4 | 000000010000 | 12 |
| 21 | 000000010010 | 0 | 000000010000 | 13 |
| 22 | 000000010010 | 1 | 000000010000 | 14 |
| 23 | 000000010010 | 2 | 000000010000 | 15 |
| 24 | 000000010010 | 3 | 000000010101 | 0 |
| 25 | 000000010010 | 4 | 000000010101 | 1 |
| 26 | 000000010010 | 5 | 000000010101 | 2 |
| 27 | 000000010010 | 6 | 000000100000 | 8 |
| 28 | 000000010010 | 7 | 000000100000 | 9 |
| 29 | 000000010100 | 8 | 000000100000 | 10 |
| 30 | 000000010100 | 9 | 000000100000 | 11 |
| 31 | 000000010100 | 10 | 000000100000 | 12 |

State S00 Part-2: Entries 32-63

| | | | | |
|---|---|---|---|---|
| 32 | 000000010100 | 11 | 000000100000 | 13 |
| 33 | 000000010100 | 12 | 000000100000 | 14 |
| 34 | 000000010100 | 13 | 000000100000 | 15 |
| 35 | 000000010100 | 14 | 000000100101 | 0 |
| 36 | 000000010100 | 15 | 000000100101 | 1 |
| 37 | 000000100001 | 0 | 000000100101 | 2 |
| 38 | 000000100001 | 1 | 000000100101 | 3 |
| 39 | 000000100001 | 2 | 000000101001 | 0 |
| 40 | 000000100001 | 3 | 000000101001 | 1 |
| 41 | 000000100001 | 4 | 000000101001 | 2 |
| 42 | 000000100010 | 0 | 000000101001 | 3 |
| 43 | 000000100010 | 1 | 000000101001 | 4 |
| 44 | 000000100010 | 2 | 000000101010 | 0 |
| 45 | 000000100010 | 3 | 000000101010 | 1 |
| 46 | 000000100010 | 4 | 000000101010 | 2 |
| 47 | 000000100010 | 5 | 000000101010 | 3 |
| 48 | 000000100010 | 6 | 000000101010 | 4 |
| 49 | 000000100010 | 7 | 000001000000 | 8 |
| 50 | 000000100100 | 8 | 000001000000 | 9 |
| 51 | 000000100100 | 9 | 000001000000 | 10 |
| 52 | 000000100100 | 10 | 000001000000 | 11 |
| 53 | 000000100100 | 11 | 000001000000 | 12 |
| 54 | 000000100100 | 12 | 000001000000 | 13 |
| 55 | 000000100100 | 13 | 000001000000 | 14 |
| 56 | 000000100100 | 14 | 000001000101 | 0 |
| 57 | 000000100100 | 15 | 000001000101 | 1 |
| 58 | 000000101000 | 8 | 000001000101 | 2 |
| 59 | 000000101000 | 9 | 000001000101 | 3 |
| 60 | 000000101000 | 10 | 000001001001 | 0 |
| 61 | 000000101000 | 11 | 000001001001 | 1 |
| 62 | 000000101000 | 12 | 000001001001 | 2 |
| 63 | 000000101000 | 13 | 000001001001 | 3 |

State S00 Part-3: Entries 64-95

| | | | | |
|---|---|---|---|---|
| 64 | 000000101000 | 14 | 000001001001 | 4 |
| 65 | 000000101000 | 15 | 000001001010 | 0 |
| 66 | 000001000001 | 0 | 000001001010 | 1 |
| 67 | 000001000001 | 1 | 000001001010 | 2 |
| 68 | 000001000001 | 2 | 000001001010 | 3 |
| 69 | 000001000001 | 3 | 000001001010 | 4 |
| 70 | 000001000001 | 4 | 000001001010 | 5 |
| 71 | 000001000010 | 0 | 000001001010 | 6 |
| 72 | 000001000010 | 1 | 000001010001 | 0 |
| 73 | 000001000010 | 2 | 000001010001 | 1 |
| 74 | 000001000010 | 3 | 000001010001 | 2 |
| 75 | 000001000010 | 4 | 000001010001 | 3 |
| 76 | 000001000010 | 5 | 000001010001 | 4 |
| 77 | 000001000010 | 6 | 000001010010 | 0 |
| 78 | 000001000010 | 7 | 000001010010 | 1 |
| 79 | 000001000100 | 8 | 000001010010 | 2 |
| 80 | 000001000100 | 9 | 000001010010 | 3 |
| 81 | 000001000100 | 10 | 000001010010 | 4 |
| 82 | 000001000100 | 11 | 000001010010 | 5 |
| 83 | 000001000100 | 12 | 000001010010 | 6 |
| 84 | 000001000100 | 13 | 000001010010 | 7 |
| 85 | 000001000100 | 14 | 000001010100 | 8 |
| 86 | 000001000100 | 15 | 000001010100 | 9 |
| 87 | 000001001000 | 8 | 000001010100 | 10 |
| 88 | 000001001000 | 9 | 000001010100 | 11 |
| 89 | 000001001000 | 10 | 000001010100 | 12 |
| 90 | 000001001000 | 11 | 000001010100 | 13 |
| 91 | 000001001000 | 12 | 000001010100 | 14 |
| 92 | 000001001000 | 13 | 000001010100 | 15 |
| 93 | 000001001000 | 14 | 000010000000 | 8 |
| 94 | 000001001000 | 15 | 000010000000 | 9 |
| 95 | 000001010000 | 8 | 000010000000 | 10 |

State S00 Part-4: Entries 96-127

| | | | | |
|---|---|---|---|---|
| 96 | 000001010000 | 9 | 000010000000 | 11 |
| 97 | 000001010000 | 10 | 000010000000 | 12 |
| 98 | 000001010000 | 11 | 000010000000 | 13 |
| 99 | 000001010000 | 12 | 000010000000 | 14 |
| 100 | 000001010000 | 13 | 000010000101 | 0 |
| 101 | 000001010000 | 14 | 000010000101 | 1 |
| 102 | 000001010000 | 15 | 000010000101 | 2 |
| 103 | 000010000001 | 0 | 000010000101 | 3 |
| 104 | 000010000001 | 1 | 000010001001 | 0 |
| 105 | 000010000001 | 2 | 000010001001 | 1 |
| 106 | 000010000001 | 3 | 000010001001 | 2 |
| 107 | 000010000001 | 4 | 000010001001 | 3 |
| 108 | 000010000010 | 0 | 000010001001 | 4 |
| 109 | 000010000010 | 1 | 000010001010 | 0 |
| 110 | 000010000010 | 2 | 000010001010 | 1 |
| 111 | 000010000010 | 3 | 000010001010 | 2 |
| 112 | 000010000010 | 4 | 000010001010 | 3 |
| 113 | 000010000010 | 5 | 000010001010 | 4 |
| 114 | 000010000010 | 6 | 000010001010 | 5 |
| 115 | 000010000010 | 7 | 000010001010 | 6 |
| 116 | 000010000100 | 8 | 000010010001 | 0 |
| 117 | 000010000100 | 9 | 000010010001 | 1 |
| 118 | 000010000100 | 10 | 000010010001 | 2 |
| 119 | 000010000100 | 11 | 000010010001 | 3 |
| 120 | 000010000100 | 12 | 000010010001 | 4 |
| 121 | 000010000100 | 13 | 000010010010 | 0 |
| 122 | 000010000100 | 14 | 000010010010 | 1 |
| 123 | 000010000100 | 15 | 000010010010 | 2 |
| 124 | 000010001000 | 8 | 000010010010 | 3 |
| 125 | 000010001000 | 9 | 000010010010 | 4 |
| 126 | 000010001000 | 10 | 000010010010 | 5 |
| 127 | 000010001000 | 11 | 000010010010 | 6 |

State S01 Part-1: Entries 0-31

| | | | | |
|---|---|---|---|---|
| 0 | 000010010000 | 8 | 000010010100 | 8 |
| 1 | 000010010000 | 9 | 000010010100 | 9 |
| 2 | 000010010000 | 10 | 000010010100 | 10 |
| 3 | 000010010000 | 11 | 000010010100 | 11 |
| 4 | 000010010000 | 12 | 000010010100 | 12 |
| 5 | 000010010000 | 13 | 000010010100 | 13 |
| 6 | 000010010000 | 14 | 000010010100 | 14 |
| 7 | 000010010000 | 15 | 000010010100 | 15 |
| 8 | 000010010101 | 0 | 000010100001 | 0 |
| 9 | 000010010101 | 1 | 000010100001 | 1 |
| 10 | 000010010101 | 2 | 000010100001 | 2 |
| 11 | 000010100000 | 8 | 000010100001 | 3 |
| 12 | 000010100000 | 9 | 000010100001 | 4 |
| 13 | 000010100000 | 10 | 000010100010 | 0 |
| 14 | 000010100000 | 11 | 000010100010 | 1 |
| 15 | 000010100000 | 12 | 000010100010 | 2 |
| 16 | 000010100000 | 13 | 000010100010 | 3 |
| 17 | 000010100000 | 14 | 000010100010 | 4 |
| 18 | 000010100000 | 15 | 000010100010 | 5 |
| 19 | 000010100101 | 0 | 000010100010 | 6 |
| 20 | 000010100101 | 1 | 000010100010 | 7 |
| 21 | 000010100101 | 2 | 000010100100 | 8 |
| 22 | 000010100101 | 3 | 000010100100 | 9 |
| 23 | 000010101001 | 0 | 000010100100 | 10 |
| 24 | 000010101001 | 1 | 000010100100 | 11 |
| 25 | 000010101001 | 2 | 000010100100 | 12 |
| 26 | 000010101001 | 3 | 000010100100 | 13 |
| 27 | 000010101001 | 4 | 000010100100 | 14 |
| 28 | 000100000001 | 0 | 000010100100 | 15 |
| 29 | 000100000001 | 1 | 000010101000 | 8 |
| 30 | 000100000001 | 2 | 000010101000 | 9 |
| 31 | 000100000001 | 3 | 000010101000 | 10 |

State S01 Part-2: Entries 32-63

| | | | | |
|---|---|---|---|---|
| 32 | 000100000001 | 4 | 000010101000 | 11 |
| 33 | 000100000010 | 0 | 000010101000 | 12 |
| 34 | 000100000010 | 1 | 000010101000 | 13 |
| 35 | 000100000010 | 2 | 000100000000 | 8 |
| 36 | 000100000010 | 3 | 000100000000 | 9 |
| 37 | 000100000010 | 4 | 000100000000 | 10 |
| 38 | 000100000010 | 5 | 000100000000 | 11 |
| 39 | 000100000010 | 6 | 000100000000 | 12 |
| 40 | 000100000010 | 7 | 000100000000 | 13 |
| 41 | 000100000100 | 8 | 000100000101 | 0 |
| 42 | 000100000100 | 9 | 000100000101 | 1 |
| 43 | 000100000100 | 10 | 000100000101 | 2 |
| 44 | 000100000100 | 11 | 000100000101 | 3 |
| 45 | 000100000100 | 12 | 000100001001 | 0 |
| 46 | 000100000100 | 13 | 000100001001 | 1 |
| 47 | 000100000100 | 14 | 000100001001 | 2 |
| 48 | 000100000100 | 15 | 000100001001 | 3 |
| 49 | 000100001000 | 8 | 000100001001 | 4 |
| 50 | 000100001000 | 9 | 000100001010 | 0 |
| 51 | 000100001000 | 10 | 000100001010 | 1 |
| 52 | 000100001000 | 11 | 000100001010 | 2 |
| 53 | 000100001000 | 12 | 000100001010 | 3 |
| 54 | 000100001000 | 13 | 000100001010 | 4 |
| 55 | 000100001000 | 14 | 000100001010 | 5 |
| 56 | 000100001000 | 15 | 000100001010 | 6 |
| 57 | 000100010000 | 8 | 000100010001 | 0 |
| 58 | 000100010000 | 9 | 000100010001 | 1 |
| 59 | 000100010000 | 10 | 000100010001 | 2 |
| 60 | 000100010000 | 11 | 000100010001 | 3 |
| 61 | 000100010000 | 12 | 000100010001 | 4 |
| 62 | 000100010000 | 13 | 000100010010 | 0 |
| 63 | 000100010000 | 14 | 000100010010 | 1 |

State S01 Part-3: Entries 64-95

| | | | | |
|---|---|---|---|---|
| 64 | 000100010000 | 15 | 000100010010 | 2 |
| 65 | 000100010101 | 0 | 000100010010 | 3 |
| 66 | 000100010101 | 1 | 000100010010 | 4 |
| 67 | 000100010101 | 2 | 000100010010 | 5 |
| 68 | 000100100000 | 8 | 000100010010 | 6 |
| 69 | 000100100000 | 9 | 000100010010 | 7 |
| 70 | 000100100000 | 10 | 000100010100 | 8 |
| 71 | 000100100000 | 11 | 000100010100 | 9 |
| 72 | 000100100000 | 12 | 000100010100 | 10 |
| 73 | 000100100000 | 13 | 000100010100 | 11 |
| 74 | 000100100000 | 14 | 000100010100 | 12 |
| 75 | 000100100000 | 15 | 000100010100 | 13 |
| 76 | 000100100101 | 0 | 000100010100 | 14 |
| 77 | 000100100101 | 1 | 000100010100 | 15 |
| 78 | 000100100101 | 2 | 000100100001 | 0 |
| 79 | 000100100101 | 3 | 000100100001 | 1 |
| 80 | 000100101001 | 0 | 000100100001 | 2 |
| 81 | 000100101001 | 1 | 000100100001 | 3 |
| 82 | 000100101001 | 2 | 000100100001 | 4 |
| 83 | 000100101001 | 3 | 000100100010 | 0 |
| 84 | 000100101001 | 4 | 000100100010 | 1 |
| 85 | 000100101010 | 0 | 000100100010 | 2 |
| 86 | 000100101010 | 1 | 000100100010 | 3 |
| 87 | 000100101010 | 2 | 000100100010 | 4 |
| 88 | 000100101010 | 3 | 000100100010 | 5 |
| 89 | 000100101010 | 4 | 000100100010 | 6 |
| 90 | 000101000000 | 8 | 000100100010 | 7 |
| 91 | 000101000000 | 9 | 000100100100 | 8 |
| 92 | 000101000000 | 10 | 000100100100 | 9 |
| 93 | 000101000000 | 11 | 000100100100 | 10 |
| 94 | 000101000000 | 12 | 000100100100 | 11 |
| 95 | 000101000000 | 13 | 000100100100 | 12 |

State S01 Part-4: Entries 96-127

| | | | | |
|---|---|---|---|---|
| 96 | 000101000000 | 14 | 000100100100 | 13 |
| 97 | 000101000101 | 0 | 000100100100 | 14 |
| 98 | 000101000101 | 1 | 000100100100 | 15 |
| 99 | 000101000101 | 2 | 000100101000 | 8 |
| 100 | 000101000101 | 3 | 000100101000 | 9 |
| 101 | 000101001001 | 0 | 000100101000 | 10 |
| 102 | 000101001001 | 1 | 000100101000 | 11 |
| 103 | 000101001001 | 2 | 000100101000 | 12 |
| 104 | 000101001001 | 3 | 000100101000 | 13 |
| 105 | 000101001001 | 4 | 000100101000 | 14 |
| 106 | 000101001010 | 0 | 000100101000 | 15 |
| 107 | 000101001010 | 1 | 000101000001 | 0 |
| 108 | 000101001010 | 2 | 000101000001 | 1 |
| 109 | 000101001010 | 3 | 000101000001 | 2 |
| 110 | 000101001010 | 4 | 000101000001 | 3 |
| 111 | 000101001010 | 5 | 000101000001 | 4 |
| 112 | 000101001010 | 6 | 000101000010 | 0 |
| 113 | 000101010001 | 0 | 000101000010 | 1 |
| 114 | 000101010001 | 1 | 000101000010 | 2 |
| 115 | 000101010001 | 2 | 000101000010 | 3 |
| 116 | 000101010001 | 3 | 000101000010 | 4 |
| 117 | 000101010001 | 4 | 000101000010 | 5 |
| 118 | 000101010010 | 0 | 000101000010 | 6 |
| 119 | 000101010010 | 1 | 000101000010 | 7 |
| 120 | 000101010010 | 2 | 000101000100 | 8 |
| 121 | 000101010010 | 3 | 000101000100 | 9 |
| 122 | 000101010010 | 4 | 000101000100 | 10 |
| 123 | 000101010010 | 5 | 000101000100 | 11 |
| 124 | 001000000001 | 0 | 000101000100 | 12 |
| 125 | 001000000001 | 1 | 000101000100 | 13 |
| 126 | 001000000001 | 2 | 000101000100 | 14 |
| 127 | 001000000001 | 3 | 000101000100 | 15 |

State S02 Part-1: Entries 0-31

| | | | | |
|---|---|---|---|---|
| 0 | 001000000010 | 0 | 000101001000 | 8 |
| 1 | 001000000010 | 1 | 000101001000 | 9 |
| 2 | 001000000010 | 2 | 000101001000 | 10 |
| 3 | 001000000010 | 3 | 000101001000 | 11 |
| 4 | 001000000010 | 4 | 000101001000 | 12 |
| 5 | 001000000010 | 5 | 000101001000 | 13 |
| 6 | 001000000010 | 6 | 000101001000 | 14 |
| 7 | 001000000010 | 7 | 000101001000 | 15 |
| 8 | 001000000100 | 8 | 000101010000 | 8 |
| 9 | 001000000100 | 9 | 000101010000 | 9 |
| 10 | 001000000100 | 10 | 000101010000 | 10 |
| 11 | 001000000100 | 11 | 000101010000 | 11 |
| 12 | 001000000100 | 12 | 000101010000 | 12 |
| 13 | 001000000100 | 13 | 000101010000 | 13 |
| 14 | 001000000100 | 14 | 000101010000 | 14 |
| 15 | 001000000100 | 15 | 000101010000 | 15 |
| 16 | 001000001000 | 8 | 001000000000 | 8 |
| 17 | 001000001000 | 9 | 001000000000 | 9 |
| 18 | 001000001000 | 10 | 001000000000 | 10 |
| 19 | 001000001000 | 11 | 001000000000 | 11 |
| 20 | 001000001000 | 12 | 001000000000 | 12 |
| 21 | 001000001000 | 13 | 001000000101 | 0 |
| 22 | 001000001000 | 14 | 001000000101 | 1 |
| 23 | 001000001000 | 15 | 001000000101 | 2 |
| 24 | 001000010000 | 8 | 001000000101 | 3 |
| 25 | 001000010000 | 9 | 001000001001 | 0 |
| 26 | 001000010000 | 10 | 001000001001 | 1 |
| 27 | 001000010000 | 11 | 001000001001 | 2 |
| 28 | 001000010000 | 12 | 001000001001 | 3 |
| 29 | 001000010000 | 13 | 001000001001 | 4 |
| 30 | 001000010000 | 14 | 001000001010 | 0 |
| 31 | 001000010000 | 15 | 001000001010 | 1 |

State S02 Part-2: Entries 32-63

| | | | | |
|---|---|---|---|---|
| 32 | 001000010101 | 0 | 001000001010 | 2 |
| 33 | 001000010101 | 1 | 001000001010 | 3 |
| 34 | 001000010101 | 2 | 001000001010 | 4 |
| 35 | 001000100000 | 8 | 001000001010 | 5 |
| 36 | 001000100000 | 9 | 001000001010 | 6 |
| 37 | 001000100000 | 10 | 001000010001 | 0 |
| 38 | 001000100000 | 11 | 001000010001 | 1 |
| 39 | 001000100000 | 12 | 001000010001 | 2 |
| 40 | 001000100000 | 13 | 001000010001 | 3 |
| 41 | 001000100000 | 14 | 001000010001 | 4 |
| 42 | 001000100000 | 15 | 001000010010 | 0 |
| 43 | 001000100101 | 0 | 001000010010 | 1 |
| 44 | 001000100101 | 1 | 001000010010 | 2 |
| 45 | 001000100101 | 2 | 001000010010 | 3 |
| 46 | 001000100101 | 3 | 001000010010 | 4 |
| 47 | 001000101001 | 0 | 001000010010 | 5 |
| 48 | 001000101001 | 1 | 001000010010 | 6 |
| 49 | 001000101001 | 2 | 001000010010 | 7 |
| 50 | 001000101001 | 3 | 001000010100 | 8 |
| 51 | 001000101001 | 4 | 001000010100 | 9 |
| 52 | 001000101010 | 0 | 001000010100 | 10 |
| 53 | 001000101010 | 1 | 001000010100 | 11 |
| 54 | 001000101010 | 2 | 001000010100 | 12 |
| 55 | 001000101010 | 3 | 001000010100 | 13 |
| 56 | 001000101010 | 4 | 001000010100 | 14 |
| 57 | 001001000000 | 8 | 001000010100 | 15 |
| 58 | 001001000000 | 9 | 001000100001 | 0 |
| 59 | 001001000000 | 10 | 001000100001 | 1 |
| 60 | 001001000000 | 11 | 001000100001 | 2 |
| 61 | 001001000000 | 12 | 001000100001 | 3 |
| 62 | 001001000000 | 13 | 001000100001 | 4 |
| 63 | 001001000000 | 14 | 001000100010 | 0 |

State S02 Part-3: Entries 64-95

| | | | | |
|---|---|---|---|---|
| 64 | 001001000101 | 0 | 001000100010 | 1 |
| 65 | 001001000101 | 1 | 001000100010 | 2 |
| 66 | 001001000101 | 2 | 001000100010 | 3 |
| 67 | 001001000101 | 3 | 001000100010 | 4 |
| 68 | 001001001001 | 0 | 001000100010 | 5 |
| 69 | 001001001001 | 1 | 001000100010 | 6 |
| 70 | 001001001001 | 2 | 001000100010 | 7 |
| 71 | 001001001001 | 3 | 001000100100 | 8 |
| 72 | 001001001001 | 4 | 001000100100 | 9 |
| 73 | 001001001010 | 0 | 001000100100 | 10 |
| 74 | 001001001010 | 1 | 001000100100 | 11 |
| 75 | 001001001010 | 2 | 001000100100 | 12 |
| 76 | 001001001010 | 3 | 001000100100 | 13 |
| 77 | 001001001010 | 4 | 001000100100 | 14 |
| 78 | 001001001010 | 5 | 001000100100 | 15 |
| 79 | 001001001010 | 6 | 001000101000 | 8 |
| 80 | 001001010001 | 0 | 001000101000 | 9 |
| 81 | 001001010001 | 1 | 001000101000 | 10 |
| 82 | 001001010001 | 2 | 001000101000 | 11 |
| 83 | 001001010001 | 3 | 001000101000 | 12 |
| 84 | 001001010001 | 4 | 001000101000 | 13 |
| 85 | 001001010010 | 0 | 001000101000 | 14 |
| 86 | 001001010010 | 1 | 001000101000 | 15 |
| 87 | 001001010010 | 2 | 001001000001 | 0 |
| 88 | 001001010010 | 3 | 001001000001 | 1 |
| 89 | 001001010010 | 4 | 001001000001 | 2 |
| 90 | 001001010010 | 5 | 001001000001 | 3 |
| 91 | 001001010010 | 6 | 001001000001 | 4 |
| 92 | 001001010010 | 7 | 001001000010 | 0 |
| 93 | 001001010100 | 8 | 001001000010 | 1 |
| 94 | 001001010100 | 9 | 001001000010 | 2 |
| 95 | 001001010100 | 10 | 001001000010 | 3 |

State S02 Part-4: Entries 96-127

| | | | | |
|---|---|---|---|---|
| 96 | 001001010100 | 11 | 001001000010 | 4 |
| 97 | 001001010100 | 12 | 001001000010 | 5 |
| 98 | 001001010100 | 13 | 001001000010 | 6 |
| 99 | 001001010100 | 14 | 001001000010 | 7 |
| 100 | 001001010100 | 15 | 001001000100 | 8 |
| 101 | 001010000000 | 8 | 001001000100 | 9 |
| 102 | 001010000000 | 9 | 001001000100 | 10 |
| 103 | 001010000000 | 10 | 001001000100 | 11 |
| 104 | 001010000000 | 11 | 001001000100 | 12 |
| 105 | 001010000000 | 12 | 001001000100 | 13 |
| 106 | 001010000000 | 13 | 001001000100 | 14 |
| 107 | 001010000000 | 14 | 001001000100 | 15 |
| 108 | 001010000101 | 0 | 001001001000 | 8 |
| 109 | 001010000101 | 1 | 001001001000 | 9 |
| 110 | 001010000101 | 2 | 001001001000 | 10 |
| 111 | 001010000101 | 3 | 001001001000 | 11 |
| 112 | 001010001001 | 0 | 001001001000 | 12 |
| 113 | 001010001001 | 1 | 001001001000 | 13 |
| 114 | 001010001001 | 2 | 001001001000 | 14 |
| 115 | 001010001001 | 3 | 001001001000 | 15 |
| 116 | 001010001001 | 4 | 001001010000 | 8 |
| 117 | 001010001010 | 0 | 001001010000 | 9 |
| 118 | 001010001010 | 1 | 001001010000 | 10 |
| 119 | 001010001010 | 2 | 001001010000 | 11 |
| 120 | 001010001010 | 3 | 001001010000 | 12 |
| 121 | 001010001010 | 4 | 001001010000 | 13 |
| 122 | 001010001010 | 5 | 001001010000 | 14 |
| 123 | 001010001010 | 6 | 001001010000 | 15 |
| 124 | 001010010001 | 0 | 001010000001 | 0 |
| 125 | 001010010001 | 1 | 001010000001 | 1 |
| 126 | 001010010001 | 2 | 001010000001 | 2 |
| 127 | 001010010001 | 3 | 001010000001 | 3 |

State S03 Part-1: Entries 0-31

| | | | | |
|---|---|---|---|---|
| 0 | 001010010010 | 0 | 001010000010 | 0 |
| 1 | 001010010010 | 1 | 001010000010 | 1 |
| 2 | 001010010010 | 2 | 001010000010 | 2 |
| 3 | 001010010010 | 3 | 001010000010 | 3 |
| 4 | 001010010010 | 4 | 001010000010 | 4 |
| 5 | 001010010010 | 5 | 001010000010 | 5 |
| 6 | 001010010010 | 6 | 001010000010 | 6 |
| 7 | 001010010010 | 7 | 001010000010 | 7 |
| 8 | 001010010100 | 8 | 001010000100 | 8 |
| 9 | 001010010100 | 9 | 001010000100 | 9 |
| 10 | 001010010100 | 10 | 001010000100 | 10 |
| 11 | 001010010100 | 11 | 001010000100 | 11 |
| 12 | 001010010100 | 12 | 001010000100 | 12 |
| 13 | 001010010100 | 13 | 001010000100 | 13 |
| 14 | 001010010100 | 14 | 001010000100 | 14 |
| 15 | 001010010100 | 15 | 001010000100 | 15 |
| 16 | 001010100001 | 0 | 001010001000 | 8 |
| 17 | 001010100001 | 1 | 001010001000 | 9 |
| 18 | 001010100001 | 2 | 001010001000 | 10 |
| 19 | 001010100001 | 3 | 001010001000 | 11 |
| 20 | 001010100001 | 4 | 001010001000 | 12 |
| 21 | 001010100010 | 0 | 001010001000 | 13 |
| 22 | 001010100010 | 1 | 001010001000 | 14 |
| 23 | 001010100010 | 2 | 001010001000 | 15 |
| 24 | 001010100010 | 3 | 001010010000 | 8 |
| 25 | 001010100010 | 4 | 001010010000 | 9 |
| 26 | 001010100010 | 5 | 001010010000 | 10 |
| 27 | 001010100010 | 6 | 001010010000 | 11 |
| 28 | 001010100010 | 7 | 001010010000 | 12 |
| 29 | 001010100100 | 8 | 001010010000 | 13 |
| 30 | 001010100100 | 9 | 001010010000 | 14 |
| 31 | 001010100100 | 10 | 001010010000 | 15 |

State S03 Part-2: Entries 32-63

| | | | | |
|---|---|---|---|---|
| 32 | 001010100100 | 11 | 001010010101 | 0 |
| 33 | 001010100100 | 12 | 001010010101 | 1 |
| 34 | 001010100100 | 13 | 001010010101 | 2 |
| 35 | 001010100100 | 14 | 001010100000 | 8 |
| 36 | 001010100100 | 15 | 001010100000 | 9 |
| 37 | 010000000001 | 0 | 001010100000 | 10 |
| 38 | 010000000001 | 1 | 001010100000 | 11 |
| 39 | 010000000001 | 2 | 001010100000 | 12 |
| 40 | 010000000001 | 3 | 001010100000 | 13 |
| 41 | 010000000001 | 4 | 001010100000 | 14 |
| 42 | 010000000010 | 0 | 001010100000 | 15 |
| 43 | 010000000010 | 1 | 001010100101 | 0 |
| 44 | 010000000010 | 2 | 001010100101 | 1 |
| 45 | 010000000010 | 3 | 001010100101 | 2 |
| 46 | 010000000010 | 4 | 001010100101 | 3 |
| 47 | 010000000010 | 5 | 010000000000 | 8 |
| 48 | 010000000010 | 6 | 010000000000 | 9 |
| 49 | 010000000010 | 7 | 010000000000 | 10 |
| 50 | 010000000100 | 8 | 010000000101 | 0 |
| 51 | 010000000100 | 9 | 010000000101 | 1 |
| 52 | 010000000100 | 10 | 010000000101 | 2 |
| 53 | 010000000100 | 11 | 010000000101 | 3 |
| 54 | 010000000100 | 12 | 010000001001 | 0 |
| 55 | 010000000100 | 13 | 010000001001 | 1 |
| 56 | 010000000100 | 14 | 010000001001 | 2 |
| 57 | 010000000100 | 15 | 010000001001 | 3 |
| 58 | 010000001000 | 8 | 010000001001 | 4 |
| 59 | 010000001000 | 9 | 010000001010 | 0 |
| 60 | 010000001000 | 10 | 010000001010 | 1 |
| 61 | 010000001000 | 11 | 010000001010 | 2 |
| 62 | 010000001000 | 12 | 010000001010 | 3 |
| 63 | 010000001000 | 13 | 010000001010 | 4 |

State S03 Part-3: Entries 64-95

| | | | | |
|---|---|---|---|---|
| 64 | 010000001000 | 14 | 010000001010 | 5 |
| 65 | 010000001000 | 15 | 010000001010 | 6 |
| 66 | 010000010000 | 8 | 010000010001 | 0 |
| 67 | 010000010000 | 9 | 010000010001 | 1 |
| 68 | 010000010000 | 10 | 010000010001 | 2 |
| 69 | 010000010000 | 11 | 010000010001 | 3 |
| 70 | 010000010000 | 12 | 010000010001 | 4 |
| 71 | 010000010000 | 13 | 010000010010 | 0 |
| 72 | 010000010000 | 14 | 010000010010 | 1 |
| 73 | 010000010000 | 15 | 010000010010 | 2 |
| 74 | 010000010101 | 0 | 010000010010 | 3 |
| 75 | 010000010101 | 1 | 010000010010 | 4 |
| 76 | 010000010101 | 2 | 010000010010 | 5 |
| 77 | 010000100000 | 8 | 010000010010 | 6 |
| 78 | 010000100000 | 9 | 010000010010 | 7 |
| 79 | 010000100000 | 10 | 010000010100 | 8 |
| 80 | 010000100000 | 11 | 010000010100 | 9 |
| 81 | 010000100000 | 12 | 010000010100 | 10 |
| 82 | 010000100000 | 13 | 010000010100 | 11 |
| 83 | 010000100000 | 14 | 010000010100 | 12 |
| 84 | 010000100000 | 15 | 010000010100 | 13 |
| 85 | 010000100101 | 0 | 010000010100 | 14 |
| 86 | 010000100101 | 1 | 010000010100 | 15 |
| 87 | 010000100101 | 2 | 010000100001 | 0 |
| 88 | 010000100101 | 3 | 010000100001 | 1 |
| 89 | 010000101001 | 0 | 010000100001 | 2 |
| 90 | 010000101001 | 1 | 010000100001 | 3 |
| 91 | 010000101001 | 2 | 010000100001 | 4 |
| 92 | 010000101001 | 3 | 010000100010 | 0 |
| 93 | 010000101001 | 4 | 010000100010 | 1 |
| 94 | 010000101010 | 0 | 010000100010 | 2 |
| 95 | 010000101010 | 1 | 010000100010 | 3 |

State S03 Part-4: Entries 96-127

| | | | | |
|---|---|---|---|---|
| 96 | 010000101010 | 2 | 010000100010 | 4 |
| 97 | 010000101010 | 3 | 010000100010 | 5 |
| 98 | 010000101010 | 4 | 010000100010 | 6 |
| 99 | 010001000000 | 8 | 010000100010 | 7 |
| 100 | 010001000000 | 9 | 010000100100 | 8 |
| 101 | 010001000000 | 10 | 010000100100 | 9 |
| 102 | 010001000000 | 11 | 010000100100 | 10 |
| 103 | 010001000000 | 12 | 010000100100 | 11 |
| 104 | 010001000000 | 13 | 010000100100 | 12 |
| 105 | 010001000000 | 14 | 010000100100 | 13 |
| 106 | 010001000101 | 0 | 010000100100 | 14 |
| 107 | 010001000101 | 1 | 010000100100 | 15 |
| 108 | 010001000101 | 2 | 010000101000 | 8 |
| 109 | 010001000101 | 3 | 010000101000 | 9 |
| 110 | 010001001001 | 0 | 010000101000 | 10 |
| 111 | 010001001001 | 1 | 010000101000 | 11 |
| 112 | 010001001001 | 2 | 010000101000 | 12 |
| 113 | 010001001001 | 3 | 010000101000 | 13 |
| 114 | 010001001001 | 4 | 010000101000 | 14 |
| 115 | 010001001010 | 0 | 010000101000 | 15 |
| 116 | 010001001010 | 1 | 010001000001 | 0 |
| 117 | 010001001010 | 2 | 010001000001 | 1 |
| 118 | 010001001010 | 3 | 010001000001 | 2 |
| 119 | 010001001010 | 4 | 010001000001 | 3 |
| 120 | 010001001010 | 5 | 010001000001 | 4 |
| 121 | 010001001010 | 6 | 010001000010 | 0 |
| 122 | 010001010001 | 0 | 010001000010 | 1 |
| 123 | 010001010001 | 1 | 010001000010 | 2 |
| 124 | 010001010001 | 2 | 010001000010 | 3 |
| 125 | 010001010001 | 3 | 010001000010 | 4 |
| 126 | 010001010001 | 4 | 010001000010 | 5 |
| 127 | 010001010010 | 0 | 010001000010 | 6 |

State S04 Part-1: Entries 0-31

| | | | | |
|---|---|---|---|---|
| 0 | 010001010100 | 8 | 010001000100 | 8 |
| 1 | 010001010100 | 9 | 010001000100 | 9 |
| 2 | 010001010100 | 10 | 010001000100 | 10 |
| 3 | 010001010100 | 11 | 010001000100 | 11 |
| 4 | 010001010100 | 12 | 010001000100 | 12 |
| 5 | 010001010100 | 13 | 010001000100 | 13 |
| 6 | 010001010100 | 14 | 010001000100 | 14 |
| 7 | 010001010100 | 15 | 010001000100 | 15 |
| 8 | 010010000000 | 8 | 010001001000 | 8 |
| 9 | 010010000000 | 9 | 010001001000 | 9 |
| 10 | 010010000000 | 10 | 010001001000 | 10 |
| 11 | 010010000000 | 11 | 010001001000 | 11 |
| 12 | 010010000000 | 12 | 010001001000 | 12 |
| 13 | 010010000000 | 13 | 010001001000 | 13 |
| 14 | 010010000000 | 14 | 010001001000 | 14 |
| 15 | 010010000101 | 0 | 010001001000 | 15 |
| 16 | 010010000101 | 1 | 010001010000 | 8 |
| 17 | 010010000101 | 2 | 010001010000 | 9 |
| 18 | 010010000101 | 3 | 010001010000 | 10 |
| 19 | 010010001001 | 0 | 010001010000 | 11 |
| 20 | 010010001001 | 1 | 010001010000 | 12 |
| 21 | 010010001001 | 2 | 010001010000 | 13 |
| 22 | 010010001001 | 3 | 010001010000 | 14 |
| 23 | 010010001001 | 4 | 010001010000 | 15 |
| 24 | 010010001010 | 0 | 010010000001 | 0 |
| 25 | 010010001010 | 1 | 010010000001 | 1 |
| 26 | 010010001010 | 2 | 010010000001 | 2 |
| 27 | 010010001010 | 3 | 010010000001 | 3 |
| 28 | 010010001010 | 4 | 010010000001 | 4 |
| 29 | 010010001010 | 5 | 010010000010 | 0 |
| 30 | 010010001010 | 6 | 010010000010 | 1 |
| 31 | 010010010001 | 0 | 010010000010 | 2 |

State S04 Part-2: Entries 32-63

| | | | | |
|---|---|---|---|---|
| 32 | 010010010001 | 1 | 010010000010 | 3 |
| 33 | 010010010001 | 2 | 010010000010 | 4 |
| 34 | 010010010001 | 3 | 010010000010 | 5 |
| 35 | 010010010001 | 4 | 010010000010 | 6 |
| 36 | 010010010010 | 0 | 010010000010 | 7 |
| 37 | 010010010010 | 1 | 010010000100 | 8 |
| 38 | 010010010010 | 2 | 010010000100 | 9 |
| 39 | 010010010010 | 3 | 010010000100 | 10 |
| 40 | 010010010010 | 4 | 010010000100 | 11 |
| 41 | 010010010010 | 5 | 010010000100 | 12 |
| 42 | 010010010010 | 6 | 010010000100 | 13 |
| 43 | 010010010010 | 7 | 010010000100 | 14 |
| 44 | 010010010100 | 8 | 010010000100 | 15 |
| 45 | 010010010100 | 9 | 010010001000 | 8 |
| 46 | 010010010100 | 10 | 010010001000 | 9 |
| 47 | 010010010100 | 11 | 010010001000 | 10 |
| 48 | 010010010100 | 12 | 010010001000 | 11 |
| 49 | 010010010100 | 13 | 010010001000 | 12 |
| 50 | 010010010100 | 14 | 010010001000 | 13 |
| 51 | 010010010100 | 15 | 010010001000 | 14 |
| 52 | 010010100001 | 0 | 010010001000 | 15 |
| 53 | 010010100001 | 1 | 010010010000 | 8 |
| 54 | 010010100001 | 2 | 010010010000 | 9 |
| 55 | 010010100001 | 3 | 010010010000 | 10 |
| 56 | 010010100001 | 4 | 010010010000 | 11 |
| 57 | 010010100010 | 0 | 010010010000 | 12 |
| 58 | 010010100010 | 1 | 010010010000 | 13 |
| 59 | 010010100010 | 2 | 010010010000 | 14 |
| 60 | 010010100010 | 3 | 010010010000 | 15 |
| 61 | 010010100010 | 4 | 010010010101 | 0 |
| 62 | 010010100010 | 5 | 010010010101 | 1 |
| 63 | 010010100010 | 6 | 010010010101 | 2 |

State S04 Part-3: Entries 64-95

| | | | | |
|---|---|---|---|---|
| 64 | 010010100010 | 7 | 010010100000 | 8 |
| 65 | 010010100100 | 8 | 010010100000 | 9 |
| 66 | 010010100100 | 9 | 010010100000 | 10 |
| 67 | 010010100100 | 10 | 010010100000 | 11 |
| 68 | 010010100100 | 11 | 010010100000 | 12 |
| 69 | 010010100100 | 12 | 010010100000 | 13 |
| 70 | 010010100100 | 13 | 010010100000 | 14 |
| 71 | 010010100100 | 14 | 010010100000 | 15 |
| 72 | 010010100100 | 15 | 010010100101 | 0 |
| 73 | 010010101000 | 8 | 010010100101 | 1 |
| 74 | 010010101000 | 9 | 010010100101 | 2 |
| 75 | 010010101000 | 10 | 010010100101 | 3 |
| 76 | 010010101000 | 11 | 010010101001 | 0 |
| 77 | 010010101000 | 12 | 010010101001 | 1 |
| 78 | 010010101000 | 13 | 010010101001 | 2 |
| 79 | 010010101000 | 14 | 010010101001 | 3 |
| 80 | 010010101000 | 15 | 010010101001 | 4 |
| 81 | 010100000000 | 8 | 010100000001 | 0 |
| 82 | 010100000000 | 9 | 010100000001 | 1 |
| 83 | 010100000000 | 10 | 010100000001 | 2 |
| 84 | 010100000000 | 11 | 010100000001 | 3 |
| 85 | 010100000000 | 12 | 010100000001 | 4 |
| 86 | 010100000000 | 13 | 010100000010 | 0 |
| 87 | 010100000101 | 0 | 010100000010 | 1 |
| 88 | 010100000101 | 1 | 010100000010 | 2 |
| 89 | 010100000101 | 2 | 010100000010 | 3 |
| 90 | 010100000101 | 3 | 010100000010 | 4 |
| 91 | 010100001001 | 0 | 010100000010 | 5 |
| 92 | 010100001001 | 1 | 010100000010 | 6 |
| 93 | 010100001001 | 2 | 010100000010 | 7 |
| 94 | 010100001001 | 3 | 010100000100 | 8 |
| 95 | 010100001001 | 4 | 010100000100 | 9 |

State S04 Part-4: Entries 96-127

| | | | | |
|---|---|---|---|---|
| 96 | 010100001010 | 0 | 010100000100 | 10 |
| 97 | 010100001010 | 1 | 010100000100 | 11 |
| 98 | 010100001010 | 2 | 010100000100 | 12 |
| 99 | 010100001010 | 3 | 010100000100 | 13 |
| 100 | 010100001010 | 4 | 010100000100 | 14 |
| 101 | 010100001010 | 5 | 010100000100 | 15 |
| 102 | 010100001010 | 6 | 010100001000 | 8 |
| 103 | 010100010001 | 0 | 010100001000 | 9 |
| 104 | 010100010001 | 1 | 010100001000 | 10 |
| 105 | 010100010001 | 2 | 010100001000 | 11 |
| 106 | 010100010001 | 3 | 010100001000 | 12 |
| 107 | 010100010001 | 4 | 010100001000 | 13 |
| 108 | 010100010010 | 0 | 010100001000 | 14 |
| 109 | 010100010010 | 1 | 010100001000 | 15 |
| 110 | 010100010010 | 2 | 010100010000 | 8 |
| 111 | 010100010010 | 3 | 010100010000 | 9 |
| 112 | 010100010010 | 4 | 010100010000 | 10 |
| 113 | 010100010010 | 5 | 010100010000 | 11 |
| 114 | 010100010010 | 6 | 010100010000 | 12 |
| 115 | 010100010010 | 7 | 010100010000 | 13 |
| 116 | 010100010100 | 8 | 010100010000 | 14 |
| 117 | 010100010100 | 9 | 010100010000 | 15 |
| 118 | 010100010100 | 10 | 010100010101 | 0 |
| 119 | 010100010100 | 11 | 010100010101 | 1 |
| 120 | 010100010100 | 12 | 010100010101 | 2 |
| 121 | 010100010100 | 13 | 010100100000 | 8 |
| 122 | 010100010100 | 14 | 010100100000 | 9 |
| 123 | 010100010100 | 15 | 010100100000 | 10 |
| 124 | 010100100001 | 0 | 010100100000 | 11 |
| 125 | 010100100001 | 1 | 010100100000 | 12 |
| 126 | 010100100001 | 2 | 010100100000 | 13 |
| 127 | 010100100001 | 3 | 010100100000 | 14 |

State S05 Part-1: Entries 0-31

| | | | | |
|---|---|---|---|---|
| 0 | 010100100010 | 0 | 010100100101 | 0 |
| 1 | 010100100010 | 1 | 010100100101 | 1 |
| 2 | 010100100010 | 2 | 010100100101 | 2 |
| 3 | 010100100010 | 3 | 010100100101 | 3 |
| 4 | 010100100010 | 4 | 010100101001 | 0 |
| 5 | 010100100010 | 5 | 010100101001 | 1 |
| 6 | 010100100010 | 6 | 010100101001 | 2 |
| 7 | 010100100010 | 7 | 010100101001 | 3 |
| 8 | 010100100100 | 8 | 010100101001 | 4 |
| 9 | 010100100100 | 9 | 010100101010 | 0 |
| 10 | 010100100100 | 10 | 010100101010 | 1 |
| 11 | 010100100100 | 11 | 010100101010 | 2 |
| 12 | 010100100100 | 12 | 010100101010 | 3 |
| 13 | 010100100100 | 13 | 010100101010 | 4 |
| 14 | 010100100100 | 14 | 010101000000 | 8 |
| 15 | 010100100100 | 15 | 010101000000 | 9 |
| 16 | 010100101000 | 8 | 010101000000 | 10 |
| 17 | 010100101000 | 9 | 010101000000 | 11 |
| 18 | 010100101000 | 10 | 010101000000 | 12 |
| 19 | 010100101000 | 11 | 010101000000 | 13 |
| 20 | 010100101000 | 12 | 010101000000 | 14 |
| 21 | 010100101000 | 13 | 010101000101 | 0 |
| 22 | 010100101000 | 14 | 010101000101 | 1 |
| 23 | 010100101000 | 15 | 010101000101 | 2 |
| 24 | 010101000001 | 0 | 010101000101 | 3 |
| 25 | 010101000001 | 1 | 010101001001 | 0 |
| 26 | 010101000001 | 2 | 010101001001 | 1 |
| 27 | 010101000001 | 3 | 010101001001 | 2 |
| 28 | 010101000001 | 4 | 010101001001 | 3 |
| 29 | 010101000010 | 0 | 010101001001 | 4 |
| 30 | 010101000010 | 1 | 010101001010 | 0 |
| 31 | 010101000010 | 2 | 010101001010 | 1 |

State S05 Part-2: Entries 32-63

| | | | | |
|---|---|---|---|---|
| 32 | 010101000010 | 3 | 010101001010 | 2 |
| 33 | 010101000010 | 4 | 010101001010 | 3 |
| 34 | 010101000010 | 5 | 010101001010 | 4 |
| 35 | 010101000010 | 6 | 010101001010 | 5 |
| 36 | 010101000010 | 7 | 010101001010 | 6 |
| 37 | 010101000100 | 8 | 100000000101 | 0 |
| 38 | 010101000100 | 9 | 100000000101 | 1 |
| 39 | 010101000100 | 10 | 100000000101 | 2 |
| 40 | 010101000100 | 11 | 100000000101 | 3 |
| 41 | 010101000100 | 12 | 100000001001 | 0 |
| 42 | 010101000100 | 13 | 100000001001 | 1 |
| 43 | 010101000100 | 14 | 100000001001 | 2 |
| 44 | 010101000100 | 15 | 100000001001 | 3 |
| 45 | 010101001000 | 8 | 100000001001 | 4 |
| 46 | 010101001000 | 9 | 100000001010 | 0 |
| 47 | 010101001000 | 10 | 100000001010 | 1 |
| 48 | 010101001000 | 11 | 100000001010 | 2 |
| 49 | 010101001000 | 12 | 100000001010 | 3 |
| 50 | 010101001000 | 13 | 100000001010 | 4 |
| 51 | 010101001000 | 14 | 100000001010 | 5 |
| 52 | 010101001000 | 15 | 100000001010 | 6 |
| 53 | 100000000001 | 0 | 100000010001 | 0 |
| 54 | 100000000001 | 1 | 100000010001 | 1 |
| 55 | 100000000001 | 2 | 100000010001 | 2 |
| 56 | 100000000001 | 3 | 100000010001 | 3 |
| 57 | 100000000001 | 4 | 100000010001 | 4 |
| 58 | 100000000010 | 0 | 100000010010 | 0 |
| 59 | 100000000010 | 1 | 100000010010 | 1 |
| 60 | 100000000010 | 2 | 100000010010 | 2 |
| 61 | 100000000010 | 3 | 100000010010 | 3 |
| 62 | 100000000010 | 4 | 100000010010 | 4 |
| 63 | 100000000010 | 5 | 100000010010 | 5 |

State S05 Part-3: Entries 64-95

| | | | | |
|---|---|---|---|---|
| 64 | 100000000010 | 6 | 100000010010 | 6 |
| 65 | 100000000010 | 7 | 100000010010 | 7 |
| 66 | 100000000100 | 8 | 100000010100 | 8 |
| 67 | 100000000100 | 9 | 100000010100 | 9 |
| 68 | 100000000100 | 10 | 100000010100 | 10 |
| 69 | 100000000100 | 11 | 100000010100 | 11 |
| 70 | 100000000100 | 12 | 100000010100 | 12 |
| 71 | 100000000100 | 13 | 100000010100 | 13 |
| 72 | 100000000100 | 14 | 100000010100 | 14 |
| 73 | 100000000100 | 15 | 100000010100 | 15 |
| 74 | 100000001000 | 8 | 100000100001 | 0 |
| 75 | 100000001000 | 9 | 100000100001 | 1 |
| 76 | 100000001000 | 10 | 100000100001 | 2 |
| 77 | 100000001000 | 11 | 100000100001 | 3 |
| 78 | 100000001000 | 12 | 100000100001 | 4 |
| 79 | 100000001000 | 13 | 100000100010 | 0 |
| 80 | 100000001000 | 14 | 100000100010 | 1 |
| 81 | 100000001000 | 15 | 100000100010 | 2 |
| 82 | 100000010000 | 8 | 100000100010 | 3 |
| 83 | 100000010000 | 9 | 100000100010 | 4 |
| 84 | 100000010000 | 10 | 100000100010 | 5 |
| 85 | 100000010000 | 11 | 100000100010 | 6 |
| 86 | 100000010000 | 12 | 100000100010 | 7 |
| 87 | 100000010000 | 13 | 100000100100 | 8 |
| 88 | 100000010000 | 14 | 100000100100 | 9 |
| 89 | 100000010000 | 15 | 100000100100 | 10 |
| 90 | 100000010101 | 0 | 100000100100 | 11 |
| 91 | 100000010101 | 1 | 100000100100 | 12 |
| 92 | 100000010101 | 2 | 100000100100 | 13 |
| 93 | 100000100000 | 8 | 100000100100 | 14 |
| 94 | 100000100000 | 9 | 100000100100 | 15 |
| 95 | 100000100000 | 10 | 100000101000 | 8 |

State S05 Part-4: Entries 96-127

| | | | | |
|---|---|---|---|---|
| 96 | 100000100000 | 11 | 100000101000 | 9 |
| 97 | 100000100000 | 12 | 100000101000 | 10 |
| 98 | 100000100000 | 13 | 100000101000 | 11 |
| 99 | 100000100000 | 14 | 100000101000 | 12 |
| 100 | 100000100000 | 15 | 100000101000 | 13 |
| 101 | 100000100101 | 0 | 100000101000 | 14 |
| 102 | 100000100101 | 1 | 100000101000 | 15 |
| 103 | 100000100101 | 2 | 100001000001 | 0 |
| 104 | 100000100101 | 3 | 100001000001 | 1 |
| 105 | 100000101001 | 0 | 100001000001 | 2 |
| 106 | 100000101001 | 1 | 100001000001 | 3 |
| 107 | 100000101001 | 2 | 100001000001 | 4 |
| 108 | 100000101001 | 3 | 100001000010 | 0 |
| 109 | 100000101001 | 4 | 100001000010 | 1 |
| 110 | 100000101010 | 0 | 100001000010 | 2 |
| 111 | 100000101010 | 1 | 100001000010 | 3 |
| 112 | 100000101010 | 2 | 100001000010 | 4 |
| 113 | 100000101010 | 3 | 100001000010 | 5 |
| 114 | 100000101010 | 4 | 100001000010 | 6 |
| 115 | 100001000000 | 8 | 100001000010 | 7 |
| 116 | 100001000000 | 9 | 100001000100 | 8 |
| 117 | 100001000000 | 10 | 100001000100 | 9 |
| 118 | 100001000000 | 11 | 100001000100 | 10 |
| 119 | 100001000000 | 12 | 100001000100 | 11 |
| 120 | 100001000000 | 13 | 100001000100 | 12 |
| 121 | 100001000000 | 14 | 100001000100 | 13 |
| 122 | 100001000101 | 0 | 100001000100 | 14 |
| 123 | 100001000101 | 1 | 100001000100 | 15 |
| 124 | 100001000101 | 2 | 100001001000 | 8 |
| 125 | 100001000101 | 3 | 100001001000 | 9 |
| 126 | 100001001001 | 0 | 100001001000 | 10 |
| 127 | 100001001001 | 1 | 100001001000 | 11 |

State S06 Part-1: Entries 0-31

| | | | | |
|---|---|---|---|---|
| 0 | 100001001010 | 0 | 100001010000 | 8 |
| 1 | 100001001010 | 1 | 100001010000 | 9 |
| 2 | 100001001010 | 2 | 100001010000 | 10 |
| 3 | 100001001010 | 3 | 100001010000 | 11 |
| 4 | 100001001010 | 4 | 100001010000 | 12 |
| 5 | 100001001010 | 5 | 100001010000 | 13 |
| 6 | 100001001010 | 6 | 100001010000 | 14 |
| 7 | 100001010001 | 0 | 100001010000 | 15 |
| 8 | 100001010001 | 1 | 100010000001 | 0 |
| 9 | 100001010001 | 2 | 100010000001 | 1 |
| 10 | 100001010001 | 3 | 100010000001 | 2 |
| 11 | 100001010001 | 4 | 100010000001 | 3 |
| 12 | 100001010010 | 0 | 100010000001 | 4 |
| 13 | 100001010010 | 1 | 100010000010 | 0 |
| 14 | 100001010010 | 2 | 100010000010 | 1 |
| 15 | 100001010010 | 3 | 100010000010 | 2 |
| 16 | 100001010010 | 4 | 100010000010 | 3 |
| 17 | 100001010010 | 5 | 100010000010 | 4 |
| 18 | 100001010010 | 6 | 100010000010 | 5 |
| 19 | 100001010010 | 7 | 100010000010 | 6 |
| 20 | 100001010100 | 8 | 100010000010 | 7 |
| 21 | 100001010100 | 9 | 100010000100 | 8 |
| 22 | 100001010100 | 10 | 100010000100 | 9 |
| 23 | 100001010100 | 11 | 100010000100 | 10 |
| 24 | 100001010100 | 12 | 100010000100 | 11 |
| 25 | 100001010100 | 13 | 100010000100 | 12 |
| 26 | 100001010100 | 14 | 100010000100 | 13 |
| 27 | 100001010100 | 15 | 100010000100 | 14 |
| 28 | 100010000000 | 8 | 100010000100 | 15 |
| 29 | 100010000000 | 9 | 100010001000 | 8 |
| 30 | 100010000000 | 10 | 100010001000 | 9 |
| 31 | 100010000000 | 11 | 100010001000 | 10 |

State S06 Part-2: Entries 32-63

| | | | | |
|---|---|---|---|---|
| 32 | 100010000000 | 12 | 100010001000 | 11 |
| 33 | 100010000000 | 13 | 100010001000 | 12 |
| 34 | 100010000000 | 14 | 100010001000 | 13 |
| 35 | 100010000101 | 0 | 100010001000 | 14 |
| 36 | 100010000101 | 1 | 100010001000 | 15 |
| 37 | 100010000101 | 2 | 100010010000 | 8 |
| 38 | 100010000101 | 3 | 100010010000 | 9 |
| 39 | 100010001001 | 0 | 100010010000 | 10 |
| 40 | 100010001001 | 1 | 100010010000 | 11 |
| 41 | 100010001001 | 2 | 100010010000 | 12 |
| 42 | 100010001001 | 3 | 100010010000 | 13 |
| 43 | 100010001001 | 4 | 100010010000 | 14 |
| 44 | 100010001010 | 0 | 100010010000 | 15 |
| 45 | 100010001010 | 1 | 100010010101 | 0 |
| 46 | 100010001010 | 2 | 100010010101 | 1 |
| 47 | 100010001010 | 3 | 100010010101 | 2 |
| 48 | 100010001010 | 4 | 100010100000 | 8 |
| 49 | 100010001010 | 5 | 100010100000 | 9 |
| 50 | 100010001010 | 6 | 100010100000 | 10 |
| 51 | 100010010001 | 0 | 100010100000 | 11 |
| 52 | 100010010001 | 1 | 100010100000 | 12 |
| 53 | 100010010001 | 2 | 100010100000 | 13 |
| 54 | 100010010001 | 3 | 100010100000 | 14 |
| 55 | 100010010001 | 4 | 100010100000 | 15 |
| 56 | 100010010010 | 0 | 100010100101 | 0 |
| 57 | 100010010010 | 1 | 100010100101 | 1 |
| 58 | 100010010010 | 2 | 100010100101 | 2 |
| 59 | 100010010010 | 3 | 100010100101 | 3 |
| 60 | 100010010010 | 4 | 100010101001 | 0 |
| 61 | 100010010010 | 5 | 100010101001 | 1 |
| 62 | 100010010010 | 6 | 100010101001 | 2 |
| 63 | 100010010010 | 7 | 100010101001 | 3 |

State S06 Part-3: Entries 64-95

| | | | | |
|---|---|---|---|---|
| 64 | 100010010100 | 8 | 100010101001 | 4 |
| 65 | 100010010100 | 9 | 100100000001 | 0 |
| 66 | 100010010100 | 10 | 100100000001 | 1 |
| 67 | 100010010100 | 11 | 100100000001 | 2 |
| 68 | 100010010100 | 12 | 100100000001 | 3 |
| 69 | 100010010100 | 13 | 100100000001 | 4 |
| 70 | 100010010100 | 14 | 100100000010 | 0 |
| 71 | 100010010100 | 15 | 100100000010 | 1 |
| 72 | 100010100001 | 0 | 100100000010 | 2 |
| 73 | 100010100001 | 1 | 100100000010 | 3 |
| 74 | 100010100001 | 2 | 100100000010 | 4 |
| 75 | 100010100001 | 3 | 100100000010 | 5 |
| 76 | 100010100001 | 4 | 100100000010 | 6 |
| 77 | 100010100010 | 0 | 100100000010 | 7 |
| 78 | 100010100010 | 1 | 100100000100 | 8 |
| 79 | 100010100010 | 2 | 100100000100 | 9 |
| 80 | 100010100010 | 3 | 100100000100 | 10 |
| 81 | 100010100010 | 4 | 100100000100 | 11 |
| 82 | 100010100010 | 5 | 100100000100 | 12 |
| 83 | 100010100010 | 6 | 100100000100 | 13 |
| 84 | 100010100010 | 7 | 100100000100 | 14 |
| 85 | 100010100100 | 8 | 100100000100 | 15 |
| 86 | 100010100100 | 9 | 100100001000 | 8 |
| 87 | 100010100100 | 10 | 100100001000 | 9 |
| 88 | 100010100100 | 11 | 100100001000 | 10 |
| 89 | 100010100100 | 12 | 100100001000 | 11 |
| 90 | 100010100100 | 13 | 100100001000 | 12 |
| 91 | 100010100100 | 14 | 100100001000 | 13 |
| 92 | 100010100100 | 15 | 100100001000 | 14 |
| 93 | 100010101000 | 8 | 100100001000 | 15 |
| 94 | 100010101000 | 9 | 100100010000 | 8 |
| 95 | 100010101000 | 10 | 100100010000 | 9 |

State S06 Part-4: Entries 96-127

| | | | | |
|---|---|---|---|---|
| 96 | 100010101000 | 11 | 100100010000 | 10 |
| 97 | 100010101000 | 12 | 100100010000 | 11 |
| 98 | 100010101000 | 13 | 100100010000 | 12 |
| 99 | 100010101000 | 14 | 100100010000 | 13 |
| 100 | 100010101000 | 15 | 100100010000 | 14 |
| 101 | 100100000000 | 8 | 100100010000 | 15 |
| 102 | 100100000000 | 9 | 100100010101 | 0 |
| 103 | 100100000000 | 10 | 100100010101 | 1 |
| 104 | 100100000000 | 11 | 100100010101 | 2 |
| 105 | 100100000000 | 12 | 100100100000 | 8 |
| 106 | 100100000000 | 13 | 100100100000 | 9 |
| 107 | 100100000101 | 0 | 100100100000 | 10 |
| 108 | 100100000101 | 1 | 100100100000 | 11 |
| 109 | 100100000101 | 2 | 100100100000 | 12 |
| 110 | 100100000101 | 3 | 100100100000 | 13 |
| 111 | 100100001001 | 0 | 100100100000 | 14 |
| 112 | 100100001001 | 1 | 100100100000 | 15 |
| 113 | 100100001001 | 2 | 100100100101 | 0 |
| 114 | 100100001001 | 3 | 100100100101 | 1 |
| 115 | 100100001001 | 4 | 100100100101 | 2 |
| 116 | 100100001010 | 0 | 100100100101 | 3 |
| 117 | 100100001010 | 1 | 100100101001 | 0 |
| 118 | 100100001010 | 2 | 100100101001 | 1 |
| 119 | 100100001010 | 3 | 100100101001 | 2 |
| 120 | 100100001010 | 4 | 100100101001 | 3 |
| 121 | 100100001010 | 5 | 100100101001 | 4 |
| 122 | 100100001010 | 6 | 100100101010 | 0 |
| 123 | 100100010001 | 0 | 100100101010 | 1 |
| 124 | 100100010001 | 1 | 100100101010 | 2 |
| 125 | 100100010001 | 2 | 100100101010 | 3 |
| 126 | 100100010001 | 3 | 100100101010 | 4 |
| 127 | 100100010001 | 4 | 100101000000 | 8 |

State S07 Part-1: Entries 0-31

| | | | | |
|---|---|---|---|---|
| 0 | 100100010010 | 0 | 100101000101 | 0 |
| 1 | 100100010010 | 1 | 100101000101 | 1 |
| 2 | 100100010010 | 2 | 100101000101 | 2 |
| 3 | 100100010010 | 3 | 100101000101 | 3 |
| 4 | 100100010010 | 4 | 100101001001 | 0 |
| 5 | 100100010010 | 5 | 100101001001 | 1 |
| 6 | 100100010010 | 6 | 100101001001 | 2 |
| 7 | 100100010010 | 7 | 100101001001 | 3 |
| 8 | 100100010100 | 8 | 100101001001 | 4 |
| 9 | 100100010100 | 9 | 100101001010 | 0 |
| 10 | 100100010100 | 10 | 100101001010 | 1 |
| 11 | 100100010100 | 11 | 100101001010 | 2 |
| 12 | 100100010100 | 12 | 100101001010 | 3 |
| 13 | 100100010100 | 13 | 100101001010 | 4 |
| 14 | 100100010100 | 14 | 100101001010 | 5 |
| 15 | 100100010100 | 15 | 100101001010 | 6 |
| 16 | 100100100001 | 0 | 100101010001 | 0 |
| 17 | 100100100001 | 1 | 100101010001 | 1 |
| 18 | 100100100001 | 2 | 100101010001 | 2 |
| 19 | 100100100001 | 3 | 100101010001 | 3 |
| 20 | 100100100001 | 4 | 100101010001 | 4 |
| 21 | 100100100010 | 0 | 100101010010 | 0 |
| 22 | 100100100010 | 1 | 100101010010 | 1 |
| 23 | 100100100010 | 2 | 100101010010 | 2 |
| 24 | 100100100010 | 3 | 100101010010 | 3 |
| 25 | 100100100010 | 4 | 100101010010 | 4 |
| 26 | 100100100010 | 5 | 100101010010 | 5 |
| 27 | 100100100010 | 6 | 100101010010 | 6 |
| 28 | 100100100010 | 7 | 100101010010 | 7 |
| 29 | 100100100100 | 8 | 101000000001 | 0 |
| 30 | 100100100100 | 9 | 101000000001 | 1 |
| 31 | 100100100100 | 10 | 101000000001 | 2 |

State S07 Part-2: Entries 32-63

| | | | | |
|---|---|---|---|---|
| 32 | 100100100100 | 11 | 101000000001 | 3 |
| 33 | 100100100100 | 12 | 101000000001 | 4 |
| 34 | 100100100100 | 13 | 101000000010 | 0 |
| 35 | 100100100100 | 14 | 101000000010 | 1 |
| 36 | 100100100100 | 15 | 101000000010 | 2 |
| 37 | 100100101000 | 8 | 101000000010 | 3 |
| 38 | 100100101000 | 9 | 101000000010 | 4 |
| 39 | 100100101000 | 10 | 101000000010 | 5 |
| 40 | 100100101000 | 11 | 101000000010 | 6 |
| 41 | 100100101000 | 12 | 101000000010 | 7 |
| 42 | 100100101000 | 13 | 101000000100 | 8 |
| 43 | 100100101000 | 14 | 101000000100 | 9 |
| 44 | 100100101000 | 15 | 101000000100 | 10 |
| 45 | 100101000001 | 0 | 101000000100 | 11 |
| 46 | 100101000001 | 1 | 101000000100 | 12 |
| 47 | 100101000001 | 2 | 101000000100 | 13 |
| 48 | 100101000001 | 3 | 101000000100 | 14 |
| 49 | 100101000001 | 4 | 101000000100 | 15 |
| 50 | 100101000010 | 0 | 101000001000 | 8 |
| 51 | 100101000010 | 1 | 101000001000 | 9 |
| 52 | 100101000010 | 2 | 101000001000 | 10 |
| 53 | 100101000010 | 3 | 101000001000 | 11 |
| 54 | 100101000010 | 4 | 101000001000 | 12 |
| 55 | 100101000010 | 5 | 101000001000 | 13 |
| 56 | 100101000010 | 6 | 101000001000 | 14 |
| 57 | 100101000010 | 7 | 101000001000 | 15 |
| 58 | 100101000100 | 8 | 101000010000 | 8 |
| 59 | 100101000100 | 9 | 101000010000 | 9 |
| 60 | 100101000100 | 10 | 101000010000 | 10 |
| 61 | 100101000100 | 11 | 101000010000 | 11 |
| 62 | 100101000100 | 12 | 101000010000 | 12 |
| 63 | 100101000100 | 13 | 101000010000 | 13 |

State S07 Part-3: Entries 64-95

| | | | | |
|---|---|---|---|---|
| 64 | 100101000100 | 14 | 101000010000 | 14 |
| 65 | 100101000100 | 15 | 101000010000 | 15 |
| 66 | 100101001000 | 8 | 101000010101 | 0 |
| 67 | 100101001000 | 9 | 101000010101 | 1 |
| 68 | 100101001000 | 10 | 101000010101 | 2 |
| 69 | 100101001000 | 11 | 101000100000 | 8 |
| 70 | 100101001000 | 12 | 101000100000 | 9 |
| 71 | 100101001000 | 13 | 101000100000 | 10 |
| 72 | 100101001000 | 14 | 101000100000 | 11 |
| 73 | 100101001000 | 15 | 101000100000 | 12 |
| 74 | 100101010000 | 8 | 101000100000 | 13 |
| 75 | 100101010000 | 9 | 101000100000 | 14 |
| 76 | 100101010000 | 10 | 101000100000 | 15 |
| 77 | 100101010090 | 11 | 101000100101 | 0 |
| 78 | 100101010000 | 12 | 101000100101 | 1 |
| 79 | 100101010000 | 13 | 101000100101 | 2 |
| 80 | 100101010000 | 14 | 101000100101 | 3 |
| 81 | 100101010000 | 15 | 101000101001 | 0 |
| 82 | 101000000000 | 8 | 101000101001 | 1 |
| 83 | 101000000000 | 9 | 101000101001 | 2 |
| 84 | 101000000000 | 10 | 101000101001 | 3 |
| 85 | 101000000000 | 11 | 101000101001 | 4 |
| 86 | 101000000000 | 12 | 101000101010 | 0 |
| 87 | 101000000101 | 0 | 101000101010 | 1 |
| 88 | 101000000101 | 1 | 101000101010 | 2 |
| 89 | 101000000101 | 2 | 101000101010 | 3 |
| 90 | 101000000101 | 3 | 101000101010 | 4 |
| 91 | 101000001001 | 0 | 101001000000 | 8 |
| 92 | 101000001001 | 1 | 101001000000 | 9 |
| 93 | 101000001001 | 2 | 101001000000 | 10 |
| 94 | 101000001001 | 3 | 101001000000 | 11 |
| 95 | 101000001001 | 4 | 101001000000 | 12 |

State S07 Part-4: Entries 96-127

| | | | | |
|---|---|---|---|---|
| 96 | 101000001010 | 0 | 101001000000 | 13 |
| 97 | 101000001010 | 1 | 101001000000 | 14 |
| 98 | 101000001010 | 2 | 101001000101 | 0 |
| 99 | 101000001010 | 3 | 101001000101 | 1 |
| 100 | 101000001010 | 4 | 101001000101 | 2 |
| 101 | 101000001010 | 5 | 101001000101 | 3 |
| 102 | 101000001010 | 6 | 101001001001 | 0 |
| 103 | 101000010001 | 0 | 101001001001 | 1 |
| 104 | 101000010001 | 1 | 101001001001 | 2 |
| 105 | 101000010001 | 2 | 101001001001 | 3 |
| 106 | 101000010001 | 3 | 101001001001 | 4 |
| 107 | 101000010001 | 4 | 101001001010 | 0 |
| 108 | 101000010010 | 0 | 101001001010 | 1 |
| 109 | 101000010010 | 1 | 101001001010 | 2 |
| 110 | 101000010010 | 2 | 101001001010 | 3 |
| 111 | 101000010010 | 3 | 101001001010 | 4 |
| 112 | 101000010010 | 4 | 101001001010 | 5 |
| 113 | 101000010010 | 5 | 101001001010 | 6 |
| 114 | 101000010010 | 6 | 101001010001 | 0 |
| 115 | 101000010010 | 7 | 101001010001 | 1 |
| 116 | 101000010100 | 8 | 101001010001 | 2 |
| 117 | 101000010100 | 9 | 101001010001 | 3 |
| 118 | 101000010100 | 10 | 101001010001 | 4 |
| 119 | 101000010100 | 11 | 101001010010 | 0 |
| 120 | 101000010100 | 12 | 101001010010 | 1 |
| 121 | 101000010100 | 13 | 101001010010 | 2 |
| 122 | 101000010100 | 14 | 101001010010 | 3 |
| 123 | 101000010100 | 15 | 101001010010 | 4 |
| 124 | 101000100001 | 0 | 101001010010 | 5 |
| 125 | 101000100001 | 1 | 101001010010 | 6 |
| 126 | 101000100001 | 2 | 101001010010 | 7 |
| 127 | 101000100001 | 3 | 101001010100 | 8 |

State S08 Part-1: Entries 0-31

| | | | | |
|---|---|---|---|---|
| 0 | 100001001010 | 0 | 100001010000 | 8 |
| 1 | 100001001010 | 1 | 100001010000 | 9 |
| 2 | 100001001010 | 2 | 100001010000 | 10 |
| 3 | 100001001010 | 3 | 100001010000 | 11 |
| 4 | 100001001010 | 4 | 100001010000 | 12 |
| 5 | 100001001010 | 5 | 100001010000 | 13 |
| 6 | 100001001010 | 6 | 100001010000 | 14 |
| 7 | 100001010001 | 0 | 100001010000 | 15 |
| 8 | 100001010001 | 1 | 100010000001 | 0 |
| 9 | 100001010001 | 2 | 100010000001 | 1 |
| 10 | 100001010001 | 3 | 100010000001 | 2 |
| 11 | 100001010001 | 4 | 100010000001 | 3 |
| 12 | 100001010010 | 0 | 100010000001 | 4 |
| 13 | 100001010010 | 1 | 100010000010 | 0 |
| 14 | 100001010010 | 2 | 100010000010 | 1 |
| 15 | 100001010010 | 3 | 100010000010 | 2 |
| 16 | 100001010010 | 4 | 100010000010 | 3 |
| 17 | 100001010010 | 5 | 100010000010 | 4 |
| 18 | 100001010010 | 6 | 100010000010 | 5 |
| 19 | 100001010010 | 7 | 100010000010 | 6 |
| 20 | 100001010100 | 8 | 100010000010 | 7 |
| 21 | 100001010100 | 9 | 100010000100 | 8 |
| 22 | 100001010100 | 10 | 100010000100 | 9 |
| 23 | 100001010100 | 11 | 100010000100 | 10 |
| 24 | 100001010100 | 12 | 100010000100 | 11 |
| 25 | 100001010100 | 13 | 100010000100 | 12 |
| 26 | 100001010100 | 14 | 100010000100 | 13 |
| 27 | 100001010100 | 15 | 100010000100 | 14 |
| 28 | 100010000000 | 8 | 100010000100 | 15 |
| 29 | 100010000000 | 9 | 100010001000 | 8 |
| 30 | 100010000000 | 10 | 100010001000 | 9 |
| 31 | 100010000000 | 11 | 100010001000 | 10 |

State S08 Part-2: Entries 32-63

| | | | | |
|---|---|---|---|---|
| 32 | 100010000000 | 12 | 100010001000 | 11 |
| 33 | 100010000000 | 13 | 100001001000 | 13 |
| 34 | 100010000000 | 14 | 100001001000 | 14 |
| 35 | 100010000101 | 0 | 100001001000 | 15 |
| 36 | 100010000101 | 1 | 100001001000 | 12 |
| 37 | 100010000101 | 2 | 100000000101 | 0 |
| 38 | 100010000101 | 3 | 100000000101 | 1 |
| 39 | 100010001001 | 0 | 100000000101 | 2 |
| 40 | 100010001001 | 1 | 100000000101 | 3 |
| 41 | 100010001001 | 2 | 100000001001 | 0 |
| 42 | 100010001001 | 3 | 100000001001 | 1 |
| 43 | 100010001001 | 4 | 100000001001 | 2 |
| 44 | 100010001010 | 0 | 100000001001 | 3 |
| 45 | 100010001010 | 1 | 100000001001 | 4 |
| 46 | 100010001010 | 2 | 100000001010 | 0 |
| 47 | 100010001010 | 3 | 100000001010 | 1 |
| 48 | 100010001010 | 4 | 100000001010 | 2 |
| 49 | 100010001010 | 5 | 100000001010 | 3 |
| 50 | 100001001001 | 4 | 100000001010 | 4 |
| 51 | 100001001001 | 2 | 100000001010 | 5 |
| 52 | 100001001001 | 3 | 100000001010 | 6 |
| 53 | 100000000001 | 0 | 100000010001 | 0 |
| 54 | 100000000001 | 1 | 100000010001 | 1 |
| 55 | 100000000001 | 2 | 100000010001 | 2 |
| 56 | 100000000001 | 3 | 100000010001 | 3 |
| 57 | 100000000001 | 4 | 100000010001 | 4 |
| 58 | 100000000010 | 0 | 100000010010 | 0 |
| 59 | 100000000010 | 1 | 100000010010 | 1 |
| 60 | 100000000010 | 2 | 100000010010 | 2 |
| 61 | 100000000010 | 3 | 100000010010 | 3 |
| 62 | 100000000010 | 4 | 100000010010 | 4 |
| 63 | 100000000010 | 5 | 100000010010 | 5 |

State S08 Part-3: Entries 64-95

| | | | | |
|---|---|---|---|---|
| 64 | 100000000010 | 6 | 100000010010 | 6 |
| 65 | 100000000010 | 7 | 100000010010 | 7 |
| 66 | 100000000100 | 8 | 100000010100 | 8 |
| 67 | 100000000100 | 9 | 100000010100 | 9 |
| 68 | 100000000100 | 10 | 100000010100 | 10 |
| 69 | 100000000100 | 11 | 100000010100 | 11 |
| 70 | 100000000100 | 12 | 100000010100 | 12 |
| 71 | 100000000100 | 13 | 100000010100 | 13 |
| 72 | 100000000100 | 14 | 100000010100 | 14 |
| 73 | 100000000100 | 15 | 100000010100 | 15 |
| 74 | 100000001000 | 8 | 100000100001 | 0 |
| 75 | 100000001000 | 9 | 100000100001 | 1 |
| 76 | 100000001000 | 10 | 100000100001 | 2 |
| 77 | 100000001000 | 11 | 100000100001 | 3 |
| 78 | 100000001000 | 12 | 100000100001 | 4 |
| 79 | 100000001000 | 13 | 100000100010 | 0 |
| 80 | 100000001000 | 14 | 100000100010 | 1 |
| 81 | 100000001000 | 15 | 100000100010 | 2 |
| 82 | 100000010000 | 8 | 100000100010 | 3 |
| 83 | 100000010000 | 9 | 100000100010 | 4 |
| 84 | 100000010000 | 10 | 100000100010 | 5 |
| 85 | 100000010000 | 11 | 100000100010 | 6 |
| 86 | 100000010000 | 12 | 100000100010 | 7 |
| 87 | 100000010000 | 13 | 100000100100 | 8 |
| 88 | 100000010000 | 14 | 100000100100 | 9 |
| 89 | 100000010000 | 15 | 100000100100 | 10 |
| 90 | 100000010101 | 0 | 100000100100 | 11 |
| 91 | 100000010101 | 1 | 100000100100 | 12 |
| 92 | 100000010101 | 2 | 100000100100 | 13 |
| 93 | 100000100000 | 8 | 100000100100 | 14 |
| 94 | 100000100000 | 9 | 100000100100 | 15 |
| 95 | 100000100000 | 10 | 100000101000 | 8 |

State S08 Part-4: Entries 96-127

| | | | | |
|---|---|---|---|---|
| 96 | 100000100000 | 11 | 100000101000 | 9 |
| 97 | 100000100000 | 12 | 100000101000 | 10 |
| 98 | 100000100000 | 13 | 100000101000 | 11 |
| 99 | 100000100000 | 14 | 100000101000 | 12 |
| 100 | 100000100000 | 15 | 100000101000 | 13 |
| 101 | 100000100101 | 0 | 100000101000 | 14 |
| 102 | 100000100101 | 1 | 100000101000 | 15 |
| 103 | 100000100101 | 2 | 100001000001 | 0 |
| 104 | 100000100101 | 3 | 100001000001 | 1 |
| 105 | 100000101001 | 0 | 100001000001 | 2 |
| 106 | 100000101001 | 1 | 100001000001 | 3 |
| 107 | 100000101001 | 2 | 100001000001 | 4 |
| 108 | 100000101001 | 3 | 100001000010 | 0 |
| 109 | 100000101001 | 4 | 100001000010 | 1 |
| 110 | 100000101010 | 0 | 100001000010 | 2 |
| 111 | 100000101010 | 1 | 100001000010 | 3 |
| 112 | 100000101010 | 2 | 100001000010 | 4 |
| 113 | 100000101010 | 3 | 100001000010 | 5 |
| 114 | 100000101010 | 4 | 100001000010 | 6 |
| 115 | 100001000000 | 8 | 100001000010 | 7 |
| 116 | 100001000000 | 9 | 100001000100 | 8 |
| 117 | 100001000000 | 10 | 100001000100 | 9 |
| 118 | 100001000000 | 11 | 100001000100 | 10 |
| 119 | 100001000000 | 12 | 100001000100 | 11 |
| 120 | 100001000000 | 13 | 100001000100 | 12 |
| 121 | 100001000000 | 14 | 100001000100 | 13 |
| 122 | 100001000101 | 0 | 100001000100 | 14 |
| 123 | 100001000101 | 1 | 100001000100 | 15 |
| 124 | 100001000101 | 2 | 100001001000 | 8 |
| 125 | 100001000101 | 3 | 100001001000 | 9 |
| 126 | 100001001001 | 0 | 100001001000 | 10 |
| 127 | 100001001001 | 1 | 100001001000 | 11 |

State S09 Part-1: Entries 0-31

| | | | | |
|---|---|---|---|---|
| 0 | 100100010010 | 0 | 100101000101 | 0 |
| 1 | 100100010010 | 1 | 100101000101 | 1 |
| 2 | 100100010010 | 2 | 100101000101 | 2 |
| 3 | 100100010010 | 3 | 100101000101 | 3 |
| 4 | 100100010010 | 4 | 100101001001 | 0 |
| 5 | 100100010010 | 5 | 100101001001 | 1 |
| 6 | 100100010010 | 6 | 100101001001 | 2 |
| 7 | 100100010010 | 7 | 100101001001 | 3 |
| 8 | 100100010100 | 8 | 100101001001 | 4 |
| 9 | 100100010100 | 9 | 100101001010 | 0 |
| 10 | 100100010100 | 10 | 100101001010 | 1 |
| 11 | 100100010100 | 11 | 100101001010 | 2 |
| 12 | 100100010100 | 12 | 100101001010 | 3 |
| 13 | 100100010100 | 13 | 100101001010 | 4 |
| 14 | 100100010100 | 14 | 100101001010 | 5 |
| 15 | 100100010100 | 15 | 100101001010 | 6 |
| 16 | 100100100001 | 0 | 100101010001 | 0 |
| 17 | 100100100001 | 1 | 100101010001 | 1 |
| 18 | 100100100001 | 2 | 100101010001 | 2 |
| 19 | 100100100001 | 3 | 100101010001 | 3 |
| 20 | 100100100001 | 4 | 100101010001 | 4 |
| 21 | 100100100010 | 0 | 100101010010 | 0 |
| 22 | 100100100010 | 1 | 100101010010 | 1 |
| 23 | 100100100010 | 2 | 100101010010 | 2 |
| 24 | 100100100010 | 3 | 100101010010 | 3 |
| 25 | 100100100010 | 4 | 100101010010 | 4 |
| 26 | 100100100010 | 5 | 100101010010 | 5 |
| 27 | 100100100010 | 6 | 100101010010 | 6 |
| 28 | 100100100010 | 7 | 100101010010 | 7 |
| 29 | 100100100100 | 8 | 101000000001 | 0 |
| 30 | 100100100100 | 9 | 101000000001 | 1 |
| 31 | 100100100100 | 10 | 100101000000 | 14 |

State S09 Part-2: Entries 32-63

| | | | | |
|---|---|---|---|---|
| 32 | 100100100100 | 11 | 100101000000 | 11 |
| 33 | 100100100100 | 12 | 100101000000 | 12 |
| 34 | 100100100100 | 13 | 100101000000 | 13 |
| 35 | 100100100100 | 14 | 100101000000 | 9 |
| 36 | 100100100100 | 15 | 100101000000 | 10 |
| 37 | 100100101000 | 8 | 100010010000 | 8 |
| 38 | 100100101000 | 9 | 100010010000 | 9 |
| 39 | 100100101000 | 10 | 100010010000 | 10 |
| 40 | 100100101000 | 11 | 100010010000 | 11 |
| 41 | 100100101000 | 12 | 100010010000 | 12 |
| 42 | 100100101000 | 13 | 100010010000 | 13 |
| 43 | 100100101000 | 14 | 100010010000 | 14 |
| 44 | 100100101000 | 15 | 100010010000 | 15 |
| 45 | 100101000001 | 0 | 100010010101 | 0 |
| 46 | 100101000001 | 1 | 100010010101 | 1 |
| 47 | 100101000001 | 2 | 100010010101 | 2 |
| 48 | 100101000001 | 3 | 100010100000 | 8 |
| 49 | 100101000001 | 4 | 100010100000 | 9 |
| 50 | 100101000010 | 0 | 100010100000 | 10 |
| 51 | 100010010001 | 0 | 100010100000 | 11 |
| 52 | 100010010001 | 1 | 100010100000 | 12 |
| 53 | 100010010001 | 2 | 100010100000 | 13 |
| 54 | 100010010001 | 3 | 100010100000 | 14 |
| 55 | 100010010001 | 4 | 100010100000 | 15 |
| 56 | 100010010010 | 0 | 100010100101 | 0 |
| 57 | 100010010010 | 1 | 100010100101 | 1 |
| 58 | 100010010010 | 2 | 100010100101 | 2 |
| 59 | 100010010010 | 3 | 100010100101 | 3 |
| 60 | 100010010010 | 4 | 100010101001 | 0 |
| 61 | 100010010010 | 5 | 100010101001 | 1 |
| 62 | 100010010010 | 6 | 100010101001 | 2 |
| 63 | 100010010010 | 7 | 100010101001 | 3 |

State S09 Part-3: Entries 64-95

| | | | | |
|---|---|---|---|---|
| 64 | 100010010100 | 8 | 100010101001 | 4 |
| 65 | 100010010100 | 9 | 100100000001 | 0 |
| 66 | 100010010100 | 10 | 100100000001 | 1 |
| 67 | 100010010100 | 11 | 100100000001 | 2 |
| 68 | 100010010100 | 12 | 100100000001 | 3 |
| 69 | 100010010100 | 13 | 100100000001 | 4 |
| 70 | 100010010100 | 14 | 100100000010 | 0 |
| 71 | 100010010100 | 15 | 100100000010 | 1 |
| 72 | 100010100001 | 0 | 100100000010 | 2 |
| 73 | 100010100001 | 1 | 100100000010 | 3 |
| 74 | 100010100001 | 2 | 100100000010 | 4 |
| 75 | 100010100001 | 3 | 100100000010 | 5 |
| 76 | 100010100001 | 4 | 100100000010 | 6 |
| 77 | 100010100010 | 0 | 100100000010 | 7 |
| 78 | 100010100010 | 1 | 100100000100 | 8 |
| 79 | 100010100010 | 2 | 100100000100 | 9 |
| 80 | 100010100010 | 3 | 100100000100 | 10 |
| 81 | 100010100010 | 4 | 100100000100 | 11 |
| 82 | 100010100010 | 5 | 100100000100 | 12 |
| 83 | 100010100010 | 6 | 100100000100 | 13 |
| 84 | 100010100010 | 7 | 100100000100 | 14 |
| 85 | 100010100100 | 8 | 100100000100 | 15 |
| 86 | 100010100100 | 9 | 100100001000 | 8 |
| 87 | 100010100100 | 10 | 100100001000 | 9 |
| 88 | 100010100100 | 11 | 100100001000 | 10 |
| 89 | 100010100100 | 12 | 100100001000 | 11 |
| 90 | 100010100100 | 13 | 100100001000 | 12 |
| 91 | 100010100100 | 14 | 100100001000 | 13 |
| 92 | 100010100100 | 15 | 100100001000 | 14 |
| 93 | 100010101000 | 8 | 100100001000 | 15 |
| 94 | 100010101000 | 9 | 100100010000 | 8 |
| 95 | 100010101000 | 10 | 100100010000 | 9 |

State S09 Part-4: Entries 96-127

| | | | | |
|---|---|---|---|---|
| 96 | 100010101000 | 11 | 100100010000 | 10 |
| 97 | 100010101000 | 12 | 100100010000 | 11 |
| 98 | 100010101000 | 13 | 100100010000 | 12 |
| 99 | 100010101000 | 14 | 100100010000 | 13 |
| 100 | 100010101000 | 15 | 100100010000 | 14 |
| 101 | 100100000000 | 8 | 100100010000 | 15 |
| 102 | 100100000000 | 9 | 100100010101 | 0 |
| 103 | 100100000000 | 10 | 100100010101 | 1 |
| 104 | 100100000000 | 11 | 100100010101 | 2 |
| 105 | 100100000000 | 12 | 100100100000 | 8 |
| 106 | 100100000000 | 13 | 100100100000 | 9 |
| 107 | 100100000101 | 0 | 100100100000 | 10 |
| 108 | 100100000101 | 1 | 100100100000 | 11 |
| 109 | 100100000101 | 2 | 100100100000 | 12 |
| 110 | 100100000101 | 3 | 100100100000 | 13 |
| 111 | 100100001001 | 0 | 100100100000 | 14 |
| 112 | 100100001001 | 1 | 100100100000 | 15 |
| 113 | 100100001001 | 2 | 100100100101 | 0 |
| 114 | 100100001001 | 3 | 100100100101 | 1 |
| 115 | 100100001001 | 4 | 100100100101 | 2 |
| 116 | 100100001010 | 0 | 100100100101 | 3 |
| 117 | 100100001010 | 1 | 100100101001 | 0 |
| 118 | 100100001010 | 2 | 100100101001 | 1 |
| 119 | 100100001010 | 3 | 100100101001 | 2 |
| 120 | 100100001010 | 4 | 100100101001 | 3 |
| 121 | 100100001010 | 5 | 100100101001 | 4 |
| 122 | 100100001010 | 6 | 100100101010 | 0 |
| 123 | 100100010001 | 0 | 100100101010 | 1 |
| 124 | 100100010001 | 1 | 100100101010 | 2 |
| 125 | 100100010001 | 2 | 100100101010 | 3 |
| 126 | 100100010001 | 3 | 100100101010 | 4 |
| 127 | 100100010001 | 4 | 100101000000 | 8 |

State S10 Part-1: Entries 0-31

| | | | | |
|---|---|---|---|---|
| 0 | 101001001000 | 8 | 101010000000 | 9 |
| 1 | 101001001000 | 9 | 101010000000 | 10 |
| 2 | 101001001000 | 10 | 101010000000 | 11 |
| 3 | 101001001000 | 11 | 101010000000 | 12 |
| 4 | 101001001000 | 12 | 101010000000 | 13 |
| 5 | 101001001000 | 13 | 101010000000 | 14 |
| 6 | 101001001000 | 14 | 101010000101 | 0 |
| 7 | 101001001000 | 15 | 101010000101 | 1 |
| 8 | 101001010000 | 8 | 101010000101 | 2 |
| 9 | 101001010000 | 9 | 101010000101 | 3 |
| 10 | 101001010000 | 10 | 101010001001 | 0 |
| 11 | 101001010000 | 11 | 101010001001 | 1 |
| 12 | 101000100001 | 4 | 101010001001 | 2 |
| 13 | 101000100010 | 0 | 101010001001 | 3 |
| 14 | 101000100010 | 1 | 101010001001 | 4 |
| 15 | 101000100010 | 2 | 101010001010 | 0 |
| 16 | 101000100010 | 3 | 101010001010 | 1 |
| 17 | 101000100010 | 4 | 101010001010 | 2 |
| 18 | 101000100010 | 5 | 101010001010 | 3 |
| 19 | 101000100010 | 6 | 101010001010 | 4 |
| 20 | 101000100010 | 7 | 101010001010 | 5 |
| 21 | 101000100100 | 8 | 101010001010 | 6 |
| 22 | 101000100100 | 9 | 101010010001 | 0 |
| 23 | 101000100100 | 10 | 101010010001 | 1 |
| 24 | 101000100100 | 11 | 101010010001 | 2 |
| 25 | 101000100100 | 12 | 101010010001 | 3 |
| 26 | 101000100100 | 13 | 101001010100 | 9 |
| 27 | 101000100100 | 14 | 101001010100 | 10 |
| 28 | 101000100100 | 15 | 101001010100 | 11 |
| 29 | 101000101000 | 8 | 101001010100 | 12 |
| 30 | 101000101000 | 9 | 101001010100 | 13 |
| 31 | 101000101000 | 10 | 101001010100 | 14 |

State S10 Part-2: Entries 32-63

| | | | | |
|---|---|---|---|---|
| 32 | 101000101000 | 11 | 101001010100 | 15 |
| 33 | 101000101000 | 12 | 101010000000 | 8 |
| 34 | 101000101000 | 13 | 101000000010 | 0 |
| 35 | 101000101000 | 14 | 101000000010 | 1 |
| 36 | 101000101000 | 15 | 101000000010 | 2 |
| 37 | 101001000001 | 0 | 101000000010 | 3 |
| 38 | 101001000001 | 1 | 101000000010 | 4 |
| 39 | 101001000001 | 2 | 101000000010 | 5 |
| 40 | 101001000001 | 3 | 101000000010 | 6 |
| 41 | 101001000001 | 4 | 101000000010 | 7 |
| 42 | 101001000010 | 0 | 101000000100 | 8 |
| 43 | 101001000010 | 1 | 101000000100 | 9 |
| 44 | 101001000010 | 2 | 101000000100 | 10 |
| 45 | 101001000010 | 3 | 101000000100 | 11 |
| 46 | 101001000010 | 4 | 101000000100 | 12 |
| 47 | 101001000010 | 5 | 101000000100 | 13 |
| 48 | 101001000010 | 6 | 101000000100 | 14 |
| 49 | 101001000010 | 7 | 101000000100 | 15 |
| 50 | 101001000100 | 8 | 101000001000 | 8 |
| 51 | 101001000100 | 9 | 101000001000 | 9 |
| 52 | 101001000100 | 10 | 101000001000 | 10 |
| 53 | 101001000100 | 11 | 101000001000 | 11 |
| 54 | 101001000100 | 12 | 101000001000 | 12 |
| 55 | 101001000100 | 13 | 101000001000 | 13 |
| 56 | 101001000100 | 14 | 101000001000 | 14 |
| 57 | 101001000100 | 15 | 101000001000 | 15 |
| 58 | 100101000100 | 8 | 101000010000 | 8 |
| 59 | 100101000100 | 9 | 101000010000 | 9 |
| 60 | 100101000100 | 10 | 101000010000 | 10 |
| 61 | 100101000100 | 11 | 101000010000 | 11 |
| 62 | 100101000100 | 12 | 101000010000 | 12 |
| 63 | 100101000100 | 13 | 101000010000 | 13 |

State S10 Part-3: Entries 64-95

| | | | | |
|---|---|---|---|---|
| 64 | 100101000100 | 14 | 101000010000 | 14 |
| 65 | 100101000100 | 15 | 101000010000 | 15 |
| 66 | 100101001000 | 8 | 101000010101 | 0 |
| 67 | 100101001000 | 9 | 101000010101 | 1 |
| 68 | 100101001000 | 10 | 101000010101 | 2 |
| 69 | 100101001000 | 11 | 101000100000 | 8 |
| 70 | 100101001000 | 12 | 101000100000 | 9 |
| 71 | 100101001000 | 13 | 101000100000 | 10 |
| 72 | 100101001000 | 14 | 101000100000 | 11 |
| 73 | 100101001000 | 15 | 101000100000 | 12 |
| 74 | 100101010000 | 8 | 101000100000 | 13 |
| 75 | 100101010000 | 9 | 101000100000 | 14 |
| 76 | 100101010000 | 10 | 101000100000 | 15 |
| 77 | 100101010000 | 11 | 101000100101 | 0 |
| 78 | 100101010000 | 12 | 101000100101 | 1 |
| 79 | 100101010000 | 13 | 101000100101 | 2 |
| 80 | 100101010000 | 14 | 101000100101 | 3 |
| 81 | 100101010000 | 15 | 101000101001 | 0 |
| 82 | 101000000000 | 8 | 101000101001 | 1 |
| 83 | 101000000000 | 9 | 101000101001 | 2 |
| 84 | 101000000000 | 10 | 101000101001 | 3 |
| 85 | 101000000000 | 11 | 101000101001 | 4 |
| 86 | 101000000000 | 12 | 101000101010 | 0 |
| 87 | 101000000101 | 0 | 101000101010 | 1 |
| 88 | 101000000101 | 1 | 101000101010 | 2 |
| 89 | 101000000101 | 2 | 101000101010 | 3 |
| 90 | 101000000101 | 3 | 101000101010 | 4 |
| 91 | 101000001001 | 0 | 101001000000 | 8 |
| 92 | 101000001001 | 1 | 101001000000 | 9 |
| 93 | 101000001001 | 2 | 101001000000 | 10 |
| 94 | 101000001001 | 3 | 101001000000 | 11 |
| 95 | 101000001001 | 4 | 101001000000 | 12 |

State S10 Part-4: Entries 96-127

| | | | | |
|---|---|---|---|---|
| 96 | 101000001010 | 0 | 101001000000 | 13 |
| 97 | 101000001010 | 1 | 101001000000 | 14 |
| 98 | 101000001010 | 2 | 101001000101 | 0 |
| 99 | 101000001010 | 3 | 101001000101 | 1 |
| 100 | 101000001010 | 4 | 101001000101 | 2 |
| 101 | 101000001010 | 5 | 101001000101 | 3 |
| 102 | 101000001010 | 6 | 101001001001 | 0 |
| 103 | 101000010001 | 0 | 101001001001 | 1 |
| 104 | 101000010001 | 1 | 101001001001 | 2 |
| 105 | 101000010001 | 2 | 101001001001 | 3 |
| 106 | 101000010001 | 3 | 101001001001 | 4 |
| 107 | 101000010001 | 4 | 101001001010 | 0 |
| 108 | 101000010010 | 0 | 101001001010 | 1 |
| 109 | 101000010010 | 1 | 101001001010 | 2 |
| 110 | 101000010010 | 2 | 101001001010 | 3 |
| 111 | 101000010010 | 3 | 101001001010 | 4 |
| 112 | 101000010010 | 4 | 101001001010 | 5 |
| 113 | 101000010010 | 5 | 101001001010 | 6 |
| 114 | 101000010010 | 6 | 101001010001 | 0 |
| 115 | 101000010010 | 7 | 101001010001 | 1 |
| 116 | 101000010100 | 8 | 101001010001 | 2 |
| 117 | 101000010100 | 9 | 101001010001 | 3 |
| 118 | 101000010100 | 10 | 101001010001 | 4 |
| 119 | 101000010100 | 11 | 101001010010 | 0 |
| 120 | 101000010100 | 12 | 101001010010 | 1 |
| 121 | 101000010100 | 13 | 101001010010 | 2 |
| 122 | 101000010100 | 14 | 101001010010 | 3 |
| 123 | 101000010100 | 15 | 101001010010 | 4 |
| 124 | 101000100001 | 0 | 101001010010 | 5 |
| 125 | 101000100001 | 1 | 101001010010 | 6 |
| 126 | 101000100001 | 2 | 101001010010 | 7 |
| 127 | 101000100001 | 3 | 101001010100 | 8 |

State S11 Part-1: Entries 0-31

| | | | | |
|---|---|---|---|---|
| 0 | 010001010100 | 8 | 010001000100 | 8 |
| 1 | 010001010100 | 9 | 010001000100 | 9 |
| 2 | 010001010100 | 10 | 010001000100 | 10 |
| 3 | 010001010100 | 11 | 010001000100 | 11 |
| 4 | 010001010100 | 12 | 010001000100 | 12 |
| 5 | 010001010100 | 13 | 010001000100 | 13 |
| 6 | 010001010100 | 14 | 010001000100 | 14 |
| 7 | 010001010100 | 15 | 010001000100 | 15 |
| 8 | 010010000000 | 8 | 010001001000 | 8 |
| 9 | 010010000000 | 9 | 010001001000 | 9 |
| 10 | 010010000000 | 10 | 010001001000 | 10 |
| 11 | 010010000000 | 11 | 010001001000 | 11 |
| 12 | 010010000000 | 12 | 010001001000 | 12 |
| 13 | 010010000000 | 13 | 010001001000 | 13 |
| 14 | 010010000000 | 14 | 010001001000 | 14 |
| 15 | 010010000101 | 0 | 010001001000 | 15 |
| 16 | 010010000101 | 1 | 010001010000 | 8 |
| 17 | 010010000101 | 2 | 010001010000 | 9 |
| 18 | 010010000101 | 3 | 010001010000 | 10 |
| 19 | 010010001001 | 0 | 010001010000 | 11 |
| 20 | 010010001001 | 1 | 010001010000 | 12 |
| 21 | 010010001001 | 2 | 010001010000 | 13 |
| 22 | 010010001001 | 3 | 010001010000 | 14 |
| 23 | 010010001001 | 4 | 010001010000 | 15 |
| 24 | 010010001010 | 0 | 010010000001 | 0 |
| 25 | 010010001010 | 1 | 010010000001 | 1 |
| 26 | 010010001010 | 2 | 010010000001 | 2 |
| 27 | 010010001010 | 3 | 010010000001 | 3 |
| 28 | 010010001010 | 4 | 010010000001 | 4 |
| 29 | 010010001010 | 5 | 010010000010 | 0 |
| 30 | 010001010010 | 3 | 010010000010 | 1 |
| 31 | 010001010010 | 4 | 010010000010 | 2 |

State S11 Part-2: Entries 32-63

| | | | | |
|---|---|---|---|---|
| 32 | 010001010010 | 5 | 010010000010 | 3 |
| 33 | 010001010010 | 6 | 010010000010 | 4 |
| 34 | 010001010010 | 7 | 010010000010 | 5 |
| 35 | 010001010010 | 1 | 010010000010 | 6 |
| 36 | 010001010010 | 2 | 010010000010 | 7 |
| 37 | 010000000001 | 0 | 010010000100 | 8 |
| 38 | 010000000001 | 1 | 010010000100 | 9 |
| 39 | 010000000001 | 2 | 010010000100 | 10 |
| 40 | 010000000001 | 3 | 010010000100 | 11 |
| 41 | 010000000001 | 4 | 010010000100 | 12 |
| 42 | 010000000010 | 0 | 010010000100 | 13 |
| 43 | 010000000010 | 1 | 010010000100 | 14 |
| 44 | 010000000010 | 2 | 010010000100 | 15 |
| 45 | 010000000010 | 3 | 010010001000 | 8 |
| 46 | 010000000010 | 4 | 010001000010 | 7 |
| 47 | 010000000010 | 5 | 010000000000 | 8 |
| 48 | 010000000010 | 6 | 010000000000 | 9 |
| 49 | 010000000010 | 7 | 010000000000 | 10 |
| 50 | 010000000100 | 8 | 010000000101 | 0 |
| 51 | 010000000100 | 9 | 010000000101 | 1 |
| 52 | 010000000100 | 10 | 010000000101 | 2 |
| 53 | 010000000100 | 11 | 010000000101 | 3 |
| 54 | 010000000100 | 12 | 010000001001 | 0 |
| 55 | 010000000100 | 13 | 010000001001 | 1 |
| 56 | 010000000100 | 14 | 010000001001 | 2 |
| 57 | 010000000100 | 15 | 010000001001 | 3 |
| 58 | 010000001000 | 8 | 010000001001 | 4 |
| 59 | 010000001000 | 9 | 010000001010 | 0 |
| 60 | 010000001000 | 10 | 010000001010 | 1 |
| 61 | 010000001000 | 11 | 010000001010 | 2 |
| 62 | 010000001000 | 12 | 010000001010 | 3 |
| 63 | 010000001000 | 13 | 010000001010 | 4 |

State S11 Part-3: Entries 64-95

| | | | | |
|---|---|---|---|---|
| 64 | 010000001000 | 14 | 010000001010 | 5 |
| 65 | 010000001000 | 15 | 010000001010 | 6 |
| 66 | 010000010000 | 8 | 010000010001 | 0 |
| 67 | 010000010000 | 9 | 010000010001 | 1 |
| 68 | 010000010000 | 10 | 010000010001 | 2 |
| 69 | 010000010000 | 11 | 010000010001 | 3 |
| 70 | 010000010000 | 12 | 010000010001 | 4 |
| 71 | 010000010000 | 13 | 010000010010 | 0 |
| 72 | 010000010000 | 14 | 010000010010 | 1 |
| 73 | 010000010000 | 15 | 010000010010 | 2 |
| 74 | 010000010101 | 0 | 010000010010 | 3 |
| 75 | 010000010101 | 1 | 010000010010 | 4 |
| 76 | 010000010101 | 2 | 010000010010 | 5 |
| 77 | 010000100000 | 8 | 010000010010 | 6 |
| 78 | 010000100000 | 9 | 010000010010 | 7 |
| 79 | 010000100000 | 10 | 010000010100 | 8 |
| 80 | 010000100000 | 11 | 010000010100 | 9 |
| 81 | 010000100000 | 12 | 010000010100 | 10 |
| 82 | 010000100000 | 13 | 010000010100 | 11 |
| 83 | 010000100000 | 14 | 010000010100 | 12 |
| 84 | 010000100000 | 15 | 010000010100 | 13 |
| 85 | 010000100101 | 0 | 010000010100 | 14 |
| 86 | 010000100101 | 1 | 010000010100 | 15 |
| 87 | 010000100101 | 2 | 010000100001 | 0 |
| 88 | 010000100101 | 3 | 010000100001 | 1 |
| 89 | 010000101001 | 0 | 010000100001 | 2 |
| 90 | 010000101001 | 1 | 010000100001 | 3 |
| 91 | 010000101001 | 2 | 010000100001 | 4 |
| 92 | 010000101001 | 3 | 010000100010 | 0 |
| 93 | 010000101001 | 4 | 010000100010 | 1 |
| 94 | 010000101010 | 0 | 010000100010 | 2 |
| 95 | 010000101010 | 1 | 010000100010 | 3 |

State S11 Part-4: Entries 96-127

| | | | | |
|---|---|---|---|---|
| 96 | 010000101010 | 2 | 010000100010 | 4 |
| 97 | 010000101010 | 3 | 010000100010 | 5 |
| 98 | 010000101010 | 4 | 010000100010 | 6 |
| 99 | 010001000000 | 8 | 010000100010 | 7 |
| 100 | 010001000000 | 9 | 010000100100 | 8 |
| 101 | 010001000000 | 10 | 010000100100 | 9 |
| 102 | 010001000000 | 11 | 010000100100 | 10 |
| 103 | 010001000000 | 12 | 010000100100 | 11 |
| 104 | 010001000000 | 13 | 010000100100 | 12 |
| 105 | 010001000000 | 14 | 010000100100 | 13 |
| 106 | 010001000101 | 0 | 010000100100 | 14 |
| 107 | 010001000101 | 1 | 010000100100 | 15 |
| 108 | 010001000101 | 2 | 010000101000 | 8 |
| 109 | 010001000101 | 3 | 010000101000 | 9 |
| 110 | 010001001001 | 0 | 010000101000 | 10 |
| 111 | 010001001001 | 1 | 010000101000 | 11 |
| 112 | 010001001001 | 2 | 010000101000 | 12 |
| 113 | 010001001001 | 3 | 010000101000 | 13 |
| 114 | 010001001001 | 4 | 010000101000 | 14 |
| 115 | 010001001010 | 0 | 010000101000 | 15 |
| 116 | 010001001010 | 1 | 010001000001 | 0 |
| 117 | 010001001010 | 2 | 010001000001 | 1 |
| 118 | 010001001010 | 3 | 010001000001 | 2 |
| 119 | 010001001010 | 4 | 010001000001 | 3 |
| 120 | 010001001010 | 5 | 010001000001 | 4 |
| 121 | 010001001010 | 6 | 010001000010 | 0 |
| 122 | 010001010001 | 0 | 010001000010 | 1 |
| 123 | 010001010001 | 1 | 010001000010 | 2 |
| 124 | 010001010001 | 2 | 010001000010 | 3 |
| 125 | 010001010001 | 3 | 010001000010 | 4 |
| 126 | 010001010001 | 4 | 010001000010 | 5 |
| 127 | 010001010010 | 0 | 010001000010 | 6 |

State S12 Part-1: Entries 0-31

| | | | | |
|---|---|---|---|---|
| 0 | 010100100010 | 0 | 010100100101 | 0 |
| 1 | 010100100010 | 1 | 010100100101 | 1 |
| 2 | 010100100010 | 2 | 010100100101 | 2 |
| 3 | 010100100010 | 3 | 010100100101 | 3 |
| 4 | 010100100010 | 4 | 010100101001 | 0 |
| 5 | 010100100010 | 5 | 010100101001 | 1 |
| 6 | 010100100010 | 6 | 010100101001 | 2 |
| 7 | 010100100010 | 7 | 010100101001 | 3 |
| 8 | 010100100100 | 8 | 010100101001 | 4 |
| 9 | 010100100100 | 9 | 010100101010 | 0 |
| 10 | 010100100100 | 10 | 010100101010 | 1 |
| 11 | 010100100100 | 11 | 010100101010 | 2 |
| 12 | 010100100100 | 12 | 010100101010 | 3 |
| 13 | 010100100100 | 13 | 010100101010 | 4 |
| 14 | 010100100100 | 14 | 010101000000 | 8 |
| 15 | 010100100100 | 15 | 010101000000 | 9 |
| 16 | 010100101000 | 8 | 010101000000 | 10 |
| 17 | 010100101000 | 9 | 010101000000 | 11 |
| 18 | 010100101000 | 10 | 010101000000 | 12 |
| 19 | 010100101000 | 11 | 010101000000 | 13 |
| 20 | 010100101000 | 12 | 010101000000 | 14 |
| 21 | 010100101000 | 13 | 010101000101 | 0 |
| 22 | 010100101000 | 14 | 010101000101 | 1 |
| 23 | 010100101000 | 15 | 010101000101 | 2 |
| 24 | 010101000001 | 0 | 010101000101 | 3 |
| 25 | 010101000001 | 1 | 010101001001 | 0 |
| 26 | 010101000001 | 2 | 010101001001 | 1 |
| 27 | 010101000001 | 3 | 010101001001 | 2 |
| 28 | 010101000001 | 4 | 010101001001 | 3 |
| 29 | 010101000010 | 0 | 010101001001 | 4 |
| 30 | 010100100001 | 4 | 010101001010 | 0 |
| 31 | 010010010001 | 0 | 010101001010 | 1 |

State S12 Part-2: Entries 32-63

| | | | | |
|---|---|---|---|---|
| 32 | 010010010001 | 1 | 010101001010 | 2 |
| 33 | 010010010001 | 2 | 010101001010 | 3 |
| 34 | 010010010001 | 3 | 010101001010 | 4 |
| 35 | 010010010001 | 4 | 010101001010 | 5 |
| 36 | 010010010010 | 0 | 010101001010 | 6 |
| 37 | 010010010010 | 1 | 101010010010 | 7 |
| 38 | 010010010010 | 2 | 101010010100 | 8 |
| 39 | 010010010010 | 3 | 101010010100 | 9 |
| 40 | 010010010010 | 4 | 101010010100 | 10 |
| 41 | 010010010010 | 5 | 101010010100 | 11 |
| 42 | 010010010010 | 6 | 101010010100 | 12 |
| 43 | 010010010010 | 7 | 101010010100 | 13 |
| 44 | 010010010100 | 8 | 101010010100 | 14 |
| 45 | 010010010100 | 9 | 010100100000 | 15 |
| 46 | 010010010100 | 10 | 101010010010 | 0 |
| 47 | 010010010100 | 11 | 101010010010 | 1 |
| 48 | 010010010100 | 12 | 101010010010 | 2 |
| 49 | 010010010100 | 13 | 101010010010 | 3 |
| 50 | 010010010100 | 14 | 101010010010 | 4 |
| 51 | 010010010100 | 15 | 101010010010 | 5 |
| 52 | 010010100001 | 0 | 101010010010 | 6 |
| 53 | 010010100001 | 1 | 010010010000 | 8 |
| 54 | 010010100001 | 2 | 010010010000 | 9 |
| 55 | 010010100001 | 3 | 010010010000 | 10 |
| 56 | 010010100001 | 4 | 010010010000 | 11 |
| 57 | 010010100010 | 0 | 010010010000 | 12 |
| 58 | 010010100010 | 1 | 010010010000 | 13 |
| 59 | 010010100010 | 2 | 010010010000 | 14 |
| 60 | 010010100010 | 3 | 010010010000 | 15 |
| 61 | 010010100010 | 4 | 010010010101 | 0 |
| 62 | 010010100010 | 5 | 010010010101 | 1 |
| 63 | 010010100010 | 6 | 010010010101 | 2 |

State S12 Part-3: Entries 64-95

| | | | | |
|---|---|---|---|---|
| 64 | 010010100010 | 7 | 010010100000 | 8 |
| 65 | 010010100100 | 8 | 010010100000 | 9 |
| 66 | 010010100100 | 9 | 010010100000 | 10 |
| 67 | 010010100100 | 10 | 010010100000 | 11 |
| 68 | 010010100100 | 11 | 010010100000 | 12 |
| 69 | 010010100100 | 12 | 010010100000 | 13 |
| 70 | 010010100100 | 13 | 010010100000 | 14 |
| 71 | 010010100100 | 14 | 010010100000 | 15 |
| 72 | 010010100100 | 15 | 010010100101 | 0 |
| 73 | 010010101000 | 8 | 010010100101 | 1 |
| 74 | 010010101000 | 9 | 010010100101 | 2 |
| 75 | 010010101000 | 10 | 010010100101 | 3 |
| 76 | 010010101000 | 11 | 010010101001 | 0 |
| 77 | 010010101000 | 12 | 010010101001 | 1 |
| 78 | 010010101000 | 13 | 010010101001 | 2 |
| 79 | 010010101000 | 14 | 010010101001 | 3 |
| 80 | 010010101000 | 15 | 010010101001 | 4 |
| 81 | 010100000000 | 8 | 010100000001 | 0 |
| 82 | 010100000000 | 9 | 010100000001 | 1 |
| 83 | 010100000000 | 10 | 010100000001 | 2 |
| 84 | 010100000000 | 11 | 010100000001 | 3 |
| 85 | 010100000000 | 12 | 010100000001 | 4 |
| 86 | 010100000000 | 13 | 010100000010 | 0 |
| 87 | 010100000101 | 0 | 010100000010 | 1 |
| 88 | 010100000101 | 1 | 010100000010 | 2 |
| 89 | 010100000101 | 2 | 010100000010 | 3 |
| 90 | 010100000101 | 3 | 010100000010 | 4 |
| 91 | 010100001001 | 0 | 010100000010 | 5 |
| 92 | 010100001001 | 1 | 010100000010 | 6 |
| 93 | 010100001001 | 2 | 010100000010 | 7 |
| 94 | 010100001001 | 3 | 010100000100 | 8 |
| 95 | 010100001001 | 4 | 010100000100 | 9 |

State S12 Part-4: Entries 96-127

| | | | | |
|---|---|---|---|---|
| 96 | 010100001010 | 0 | 010100000100 | 10 |
| 97 | 010100001010 | 1 | 010100000100 | 11 |
| 98 | 010100001010 | 2 | 010100000100 | 12 |
| 99 | 010100001010 | 3 | 010100000100 | 13 |
| 100 | 010100001010 | 4 | 010100000100 | 14 |
| 101 | 010100001010 | 5 | 010100000100 | 15 |
| 102 | 010100001010 | 6 | 010100001000 | 8 |
| 103 | 010100010001 | 0 | 010100001000 | 9 |
| 104 | 010100010001 | 1 | 010100001000 | 10 |
| 105 | 010100010001 | 2 | 010100001000 | 11 |
| 106 | 010100010001 | 3 | 010100001000 | 12 |
| 107 | 010100010001 | 4 | 010100001000 | 13 |
| 108 | 010100010010 | 0 | 010100001000 | 14 |
| 109 | 010100010010 | 1 | 010100001000 | 15 |
| 110 | 010100010010 | 2 | 010100010000 | 8 |
| 111 | 010100010010 | 3 | 010100010000 | 9 |
| 112 | 010100010010 | 4 | 010100010000 | 10 |
| 113 | 010100010010 | 5 | 010100010000 | 11 |
| 114 | 010100010010 | 6 | 010100010000 | 12 |
| 115 | 010100010010 | 7 | 010100010000 | 13 |
| 116 | 010100010100 | 8 | 010100010000 | 14 |
| 117 | 010100010100 | 9 | 010100010000 | 15 |
| 118 | 010100010100 | 10 | 010100010101 | 0 |
| 119 | 010100010100 | 11 | 010100010101 | 1 |
| 120 | 010100010100 | 12 | 010100010101 | 2 |
| 121 | 010100010100 | 13 | 010100100000 | 8 |
| 122 | 010100010100 | 14 | 010100100000 | 9 |
| 123 | 010100010100 | 15 | 010100100000 | 10 |
| 124 | 010100100001 | 0 | 010100100000 | 11 |
| 125 | 010100100001 | 1 | 010100100000 | 12 |
| 126 | 010100100001 | 2 | 010100100000 | 13 |
| 127 | 010100100001 | 3 | 010100100000 | 14 |

State S13 Part-1: Entries 0-31

| | | | | |
|---|---|---|---|---|
| 0 | 001000000010 | 0 | 001010000010 | 0 |
| 1 | 001000000010 | 1 | 001010000010 | 1 |
| 2 | 001000000010 | 2 | 001010000010 | 2 |
| 3 | 001000000010 | 3 | 001010000010 | 3 |
| 4 | 001000000010 | 4 | 001010000010 | 4 |
| 5 | 001000000010 | 5 | 001010000010 | 5 |
| 6 | 001000000010 | 6 | 001010000010 | 6 |
| 7 | 001000000010 | 7 | 001010000010 | 7 |
| 8 | 001000000100 | 8 | 001010000100 | 8 |
| 9 | 001000000100 | 9 | 001010000100 | 9 |
| 10 | 001000000100 | 10 | 001010000100 | 10 |
| 11 | 001000000100 | 11 | 001010000100 | 11 |
| 12 | 001000000100 | 12 | 001010000100 | 12 |
| 13 | 001000000100 | 13 | 001010000100 | 13 |
| 14 | 001000000100 | 14 | 001010000100 | 14 |
| 15 | 001000000100 | 15 | 001010000001 | 4 |
| 16 | 001000001000 | 8 | 001000000000 | 8 |
| 17 | 001000001000 | 9 | 001000000000 | 9 |
| 18 | 001000001000 | 10 | 010000000000 | 10 |
| 19 | 001000001000 | 11 | 001000000000 | 11 |
| 20 | 001000001000 | 12 | 001000000000 | 12 |
| 21 | 001000001000 | 13 | 001000000101 | 0 |
| 22 | 001000001000 | 14 | 001000000101 | 1 |
| 23 | 001000001000 | 15 | 001000000101 | 2 |
| 24 | 001000010000 | 8 | 001000000101 | 3 |
| 25 | 001000010000 | 9 | 001000001001 | 0 |
| 26 | 001000010000 | 10 | 001000001001 | 1 |
| 27 | 001000010000 | 11 | 001000001001 | 2 |
| 28 | 001000010000 | 12 | 001000001001 | 3 |
| 29 | 001000010000 | 13 | 001000001001 | 4 |
| 30 | 001000010000 | 14 | 001000001010 | 0 |
| 31 | 001000010000 | 15 | 001000001010 | 1 |

State S13 Part-2: Entries 32-63

| | | | | |
|---|---|---|---|---|
| 32 | 001000010101 | 0 | 001000001010 | 2 |
| 33 | 001000010101 | 1 | 001000001010 | 3 |
| 34 | 001000010101 | 2 | 001000001010 | 4 |
| 35 | 001000100000 | 8 | 001000001010 | 5 |
| 36 | 001000100000 | 9 | 001000001010 | 6 |
| 37 | 001000100000 | 10 | 001000010001 | 0 |
| 38 | 001000100000 | 11 | 001000010001 | 1 |
| 39 | 001000100000 | 12 | 001000010001 | 2 |
| 40 | 001000100000 | 13 | 001000010001 | 3 |
| 41 | 001000100000 | 14 | 001000010001 | 4 |
| 42 | 001000100000 | 15 | 001000010010 | 0 |
| 43 | 001000100101 | 0 | 001000010010 | 1 |
| 44 | 001000100101 | 1 | 001000010010 | 2 |
| 45 | 001000100101 | 2 | 001000010010 | 3 |
| 46 | 001000100101 | 3 | 001000010010 | 4 |
| 47 | 001000101001 | 0 | 001000010010 | 5 |
| 48 | 001000101001 | 1 | 001000010010 | 6 |
| 49 | 001000101001 | 2 | 001000010010 | 7 |
| 50 | 001000101001 | 3 | 001000010100 | 8 |
| 51 | 001000101001 | 4 | 001000010100 | 9 |
| 52 | 001000101010 | 0 | 001000010100 | 10 |
| 53 | 001000101010 | 1 | 001000010100 | 11 |
| 54 | 001000101010 | 2 | 001000010100 | 12 |
| 55 | 001000101010 | 3 | 001000010100 | 13 |
| 56 | 001000101010 | 4 | 001000010100 | 14 |
| 57 | 001001000000 | 8 | 001000010100 | 15 |
| 58 | 001001000000 | 9 | 001000100001 | 0 |
| 59 | 001001000000 | 10 | 001000100001 | 1 |
| 60 | 001001000000 | 11 | 001000100001 | 2 |
| 61 | 001001000000 | 12 | 001000100001 | 3 |
| 62 | 001001000000 | 13 | 001000100001 | 4 |
| 63 | 001001000000 | 14 | 001000100010 | 0 |

State S13 Part-3: Entries 64-95

| | | | | |
|---|---|---|---|---|
| 64 | 001001000101 | 0 | 001000100010 | 1 |
| 65 | 001001000101 | 1 | 001000100010 | 2 |
| 66 | 001001000101 | 2 | 001000100010 | 3 |
| 67 | 001001000101 | 3 | 001000100010 | 4 |
| 68 | 001001001001 | 0 | 001000100010 | 5 |
| 69 | 001001001001 | 1 | 001000100010 | 6 |
| 70 | 001001001001 | 2 | 001000100010 | 7 |
| 71 | 001001001001 | 3 | 001000100100 | 8 |
| 72 | 001001001001 | 4 | 001000100100 | 9 |
| 73 | 001001001010 | 0 | 001000100100 | 10 |
| 74 | 001001001010 | 1 | 001000100100 | 11 |
| 75 | 001001001010 | 2 | 001000100100 | 12 |
| 76 | 001001001010 | 3 | 001000100100 | 13 |
| 77 | 001001001010 | 4 | 001000100100 | 14 |
| 78 | 001001001010 | 5 | 001000100100 | 15 |
| 79 | 001001001010 | 6 | 001000101000 | 8 |
| 80 | 001001010001 | 0 | 001000101000 | 9 |
| 81 | 001001010001 | 1 | 001000101000 | 10 |
| 82 | 001001010001 | 2 | 001000101000 | 11 |
| 83 | 001001010001 | 3 | 001000101000 | 12 |
| 84 | 001001010001 | 4 | 001000101000 | 13 |
| 85 | 001001010010 | 0 | 001000101000 | 14 |
| 86 | 001001010010 | 1 | 001000101000 | 15 |
| 87 | 001001010010 | 2 | 001001000001 | 0 |
| 88 | 001001010010 | 3 | 001001000001 | 1 |
| 89 | 001001010010 | 4 | 001001000001 | 2 |
| 90 | 001001010010 | 5 | 001001000001 | 3 |
| 91 | 001001010010 | 6 | 001001000001 | 4 |
| 92 | 001001010010 | 7 | 001001000010 | 0 |
| 93 | 001001010100 | 8 | 001001000010 | 1 |
| 94 | 001001010100 | 9 | 001001000010 | 2 |
| 95 | 001001010100 | 10 | 001001000010 | 3 |

State S13 Part-4: Entries 96-127

| | | | | |
|---|---|---|---|---|
| 96 | 001001010100 | 11 | 001001000010 | 4 |
| 97 | 001001010100 | 12 | 001001000010 | 5 |
| 98 | 001001010100 | 13 | 001001000010 | 6 |
| 99 | 001001010100 | 14 | 001001000010 | 7 |
| 100 | 001001010100 | 15 | 001001000100 | 8 |
| 101 | 001010000000 | 8 | 001001000100 | 9 |
| 102 | 001010000000 | 9 | 001001000100 | 10 |
| 103 | 001010000000 | 10 | 001001000100 | 11 |
| 104 | 001010000000 | 11 | 001001000100 | 12 |
| 105 | 001010000000 | 12 | 001001000100 | 13 |
| 106 | 001010000000 | 13 | 001001000100 | 14 |
| 107 | 001010000000 | 14 | 001001000100 | 15 |
| 108 | 001010000101 | 0 | 001001001000 | 8 |
| 109 | 001010000101 | 1 | 001001001000 | 9 |
| 110 | 001010000101 | 2 | 001001001000 | 10 |
| 111 | 001010000101 | 3 | 001001001000 | 11 |
| 112 | 001010001001 | 0 | 001001001000 | 12 |
| 113 | 001010001001 | 1 | 001001001000 | 13 |
| 114 | 001010001001 | 2 | 001001001000 | 14 |
| 115 | 001010001001 | 3 | 001001001000 | 15 |
| 116 | 001010001001 | 4 | 001001010000 | 8 |
| 117 | 001010001010 | 0 | 001001010000 | 9 |
| 118 | 001010001010 | 1 | 001001010000 | 10 |
| 119 | 001010001010 | 2 | 001001010000 | 11 |
| 120 | 001010001010 | 3 | 001001010000 | 12 |
| 121 | 001010001010 | 4 | 001001010000 | 13 |
| 122 | 001010001010 | 5 | 001001010000 | 14 |
| 123 | 001000000001 | 4 | 001001010000 | 15 |
| 124 | 001000000001 | 0 | 001010000001 | 0 |
| 125 | 001000000001 | 1 | 001010000001 | 1 |
| 126 | 001000000001 | 2 | 001010000001 | 2 |
| 127 | 001000000001 | 3 | 001010000001 | 3 |

State S14 Part-1: Entries 0-31

| | | | | |
|---|---|---|---|---|
| 0 | 001010010010 | 0 | 000101001000 | 8 |
| 1 | 001010010010 | 1 | 000101001000 | 9 |
| 2 | 001010010010 | 2 | 000101001000 | 10 |
| 3 | 001010010010 | 3 | 000101001000 | 11 |
| 4 | 001010010010 | 4 | 000101001000 | 12 |
| 5 | 001010010010 | 5 | 000101001000 | 13 |
| 6 | 001010010010 | 6 | 000101001000 | 14 |
| 7 | 001010010010 | 7 | 000101001000 | 15 |
| 8 | 001010010100 | 8 | 000101010000 | 8 |
| 9 | 001010010100 | 9 | 000101010000 | 9 |
| 10 | 001010010100 | 10 | 000101010000 | 10 |
| 11 | 001010010100 | 11 | 000101010000 | 11 |
| 12 | 001010010100 | 12 | 000101010000 | 12 |
| 13 | 001010010100 | 13 | 000101010000 | 13 |
| 14 | 001010010100 | 14 | 000101010000 | 14 |
| 15 | 001010010100 | 15 | 000101010000 | 15 |
| 16 | 001010100001 | 0 | 001010001000 | 8 |
| 17 | 001010100001 | 1 | 001010001000 | 9 |
| 18 | 001010100001 | 2 | 001010001000 | 10 |
| 19 | 001010100001 | 3 | 001010001000 | 11 |
| 20 | 001010100001 | 4 | 001010001000 | 12 |
| 21 | 001010100010 | 0 | 001010001000 | 13 |
| 22 | 001010100010 | 1 | 001010001000 | 14 |
| 23 | 001010100010 | 2 | 001010001000 | 15 |
| 24 | 001010100010 | 3 | 001010010000 | 8 |
| 25 | 000101010010 | 6 | 001010010000 | 9 |
| 26 | 000101010010 | 7 | 001010010000 | 10 |
| 27 | 001010010001 | 4 | 001010010000 | 11 |
| 28 | 000100000001 | 0 | 001010010000 | 12 |
| 29 | 000100000001 | 1 | 001010010000 | 13 |
| 30 | 000100000001 | 2 | 001010010000 | 14 |
| 31 | 000100000001 | 3 | 001010010000 | 15 |

State S14 Part-2: Entries 32-63

| | | | | |
|---|---|---|---|---|
| 32 | 000100000001 | 4 | 001010010101 | 0 |
| 33 | 000100000010 | 0 | 001010010101 | 1 |
| 34 | 000100000010 | 1 | 001010010101 | 2 |
| 35 | 000100000010 | 2 | 000100000000 | 8 |
| 36 | 000100000010 | 3 | 000100000000 | 9 |
| 37 | 000100000010 | 4 | 000100000000 | 10 |
| 38 | 000100000010 | 5 | 000100000000 | 11 |
| 39 | 000100000010 | 6 | 000100000000 | 12 |
| 40 | 000100000010 | 7 | 000100000000 | 13 |
| 41 | 000100000100 | 8 | 000100000101 | 0 |
| 42 | 000100000100 | 9 | 000100000101 | 1 |
| 43 | 000100000100 | 10 | 000100000101 | 2 |
| 44 | 000100000100 | 11 | 000100000101 | 3 |
| 45 | 000100000100 | 12 | 000100001001 | 0 |
| 46 | 000100000100 | 13 | 000100001001 | 1 |
| 47 | 000100000100 | 14 | 000100001001 | 2 |
| 48 | 000100000100 | 15 | 000100001001 | 3 |
| 49 | 000100001000 | 8 | 000100001001 | 4 |
| 50 | 000100001000 | 9 | 000100001010 | 0 |
| 51 | 000100001000 | 10 | 000100001010 | 1 |
| 52 | 000100001000 | 11 | 000100001010 | 2 |
| 53 | 000100001000 | 12 | 000100001010 | 3 |
| 54 | 000100001000 | 13 | 000100001010 | 4 |
| 55 | 000100001000 | 14 | 000100001010 | 5 |
| 56 | 000100001000 | 15 | 000100001010 | 6 |
| 57 | 000100010000 | 8 | 000100010001 | 0 |
| 58 | 000100010000 | 9 | 000100010001 | 1 |
| 59 | 000100010000 | 10 | 000100010001 | 2 |
| 60 | 000100010000 | 11 | 000100010001 | 3 |
| 61 | 000100010000 | 12 | 000100010001 | 4 |
| 62 | 000100010000 | 13 | 000100010010 | 0 |
| 63 | 000100010000 | 14 | 000100010010 | 1 |

State S14 Part-3: Entries 64-95

| | | | | |
|---|---|---|---|---|
| 64 | 000100010000 | 15 | 000100010010 | 2 |
| 65 | 000100010101 | 0 | 000100010010 | 3 |
| 66 | 000100010101 | 1 | 000100010010 | 4 |
| 67 | 000100010101 | 2 | 000100010010 | 5 |
| 68 | 000100100000 | 8 | 000100010010 | 6 |
| 69 | 000100100000 | 9 | 000100010010 | 7 |
| 70 | 000100100000 | 10 | 000100010100 | 8 |
| 71 | 000100100000 | 11 | 000100010100 | 9 |
| 72 | 000100100000 | 12 | 000100010100 | 10 |
| 73 | 000100100000 | 13 | 000100010100 | 11 |
| 74 | 000100100000 | 14 | 000100010100 | 12 |
| 75 | 000100100000 | 15 | 000100010100 | 13 |
| 76 | 000100100101 | 0 | 000100010100 | 14 |
| 77 | 000100100101 | 1 | 000100010100 | 15 |
| 78 | 000100100101 | 2 | 000100100001 | 0 |
| 79 | 000100100101 | 3 | 000100100001 | 1 |
| 80 | 000100101001 | 0 | 000100100001 | 2 |
| 81 | 000100101001 | 1 | 000100100001 | 3 |
| 82 | 000100101001 | 2 | 000100100001 | 4 |
| 83 | 000100101001 | 3 | 000100100010 | 0 |
| 84 | 000100101001 | 4 | 000100100010 | 1 |
| 85 | 000100101010 | 0 | 000100100010 | 2 |
| 86 | 000100101010 | 1 | 000100100010 | 3 |
| 87 | 000100101010 | 2 | 000100100010 | 4 |
| 88 | 000100101010 | 3 | 000100100010 | 5 |
| 89 | 000100101010 | 4 | 000100100010 | 6 |
| 90 | 000101000000 | 8 | 000100100010 | 7 |
| 91 | 000101000000 | 9 | 000100100100 | 8 |
| 92 | 000101000000 | 10 | 000100100100 | 9 |
| 93 | 000101000000 | 11 | 000100100100 | 10 |
| 94 | 000101000000 | 12 | 000100100100 | 11 |
| 95 | 000101000000 | 13 | 000100100100 | 12 |

State S14 Part-4: Entries 96-127

| | | | | |
|---|---|---|---|---|
| 96 | 000101000000 | 14 | 000100100100 | 13 |
| 97 | 000101000101 | 0 | 000100100100 | 14 |
| 98 | 000101000101 | 1 | 000100100100 | 15 |
| 99 | 000101000101 | 2 | 000100101000 | 8 |
| 100 | 000101000101 | 3 | 000100101000 | 9 |
| 101 | 000101001001 | 0 | 000100101000 | 10 |
| 102 | 000101001001 | 1 | 000100101000 | 11 |
| 103 | 000101001001 | 2 | 000100101000 | 12 |
| 104 | 000101001001 | 3 | 000100101000 | 13 |
| 105 | 000101001001 | 4 | 000100101000 | 14 |
| 106 | 000101001010 | 0 | 000100101000 | 15 |
| 107 | 000101001010 | 1 | 000101000001 | 0 |
| 108 | 000101001010 | 2 | 000101000001 | 1 |
| 109 | 000101001010 | 3 | 000101000001 | 2 |
| 110 | 000101001010 | 4 | 000101000001 | 3 |
| 111 | 000101001010 | 5 | 000101000001 | 4 |
| 112 | 000101001010 | 6 | 000101000010 | 0 |
| 113 | 000101010001 | 0 | 000101000010 | 1 |
| 114 | 000101010001 | 1 | 000101000010 | 2 |
| 115 | 000101010001 | 2 | 000101000010 | 3 |
| 116 | 000101010001 | 3 | 000101000010 | 4 |
| 117 | 000101010001 | 4 | 000101000010 | 5 |
| 118 | 000101010010 | 0 | 000101000010 | 6 |
| 119 | 000101010010 | 1 | 000101000010 | 7 |
| 120 | 000101010010 | 2 | 000101000100 | 8 |
| 121 | 000101010010 | 3 | 000101000100 | 9 |
| 122 | 000101010010 | 4 | 000101000100 | 10 |
| 123 | 000101010010 | 5 | 000101000100 | 11 |
| 124 | 001010010001 | 0 | 000101000100 | 12 |
| 125 | 001010010001 | 1 | 000101000100 | 13 |
| 126 | 001010010001 | 2 | 000101000100 | 14 |
| 127 | 001010010001 | 3 | 000101000100 | 15 |

State S15 Part-1: Entries 0-31

| | | | | |
|---|---|---|---|---|
| 0 | 000010010000 | 8 | 000010010100 | 8 |
| 1 | 000010010000 | 9 | 000010010100 | 9 |
| 2 | 000010010000 | 10 | 000010010100 | 10 |
| 3 | 000010010000 | 11 | 000010010100 | 11 |
| 4 | 000010010000 | 12 | 000010010100 | 12 |
| 5 | 000010010000 | 13 | 000010010100 | 13 |
| 6 | 000010010000 | 14 | 000010010100 | 14 |
| 7 | 000010010000 | 15 | 000010010100 | 15 |
| 8 | 000010010101 | 0 | 000010100001 | 0 |
| 9 | 000010010101 | 1 | 000010100001 | 1 |
| 10 | 000010010101 | 2 | 000010100001 | 2 |
| 11 | 000010100000 | 8 | 000010100001 | 3 |
| 12 | 000010100000 | 9 | 000010100001 | 4 |
| 13 | 000010100000 | 10 | 000010100010 | 0 |
| 14 | 000010100000 | 11 | 000010100010 | 1 |
| 15 | 000010100000 | 12 | 000010100010 | 2 |
| 16 | 000010100000 | 13 | 000010100010 | 3 |
| 17 | 000010100000 | 14 | 000010100010 | 4 |
| 18 | 000010100000 | 15 | 000010100010 | 5 |
| 19 | 000010100101 | 0 | 000010100010 | 6 |
| 20 | 000010100101 | 1 | 000010100010 | 7 |
| 21 | 000010100101 | 2 | 000010100100 | 8 |
| 22 | 000010100101 | 3 | 000010100100 | 9 |
| 23 | 000010101001 | 0 | 000010100100 | 10 |
| 24 | 000010101001 | 1 | 000010100100 | 11 |
| 25 | 000010101001 | 2 | 000010100100 | 12 |
| 26 | 000010101001 | 3 | 000010100100 | 13 |
| 27 | 000010101001 | 4 | 000010100100 | 14 |
| 28 | 101010000001 | 0 | 000010100100 | 15 |
| 29 | 001010100100 | 8 | 000010101000 | 8 |
| 30 | 001010100100 | 9 | 000010101000 | 9 |
| 31 | 001010100100 | 10 | 000010101000 | 10 |

State S15 Part-2: Entries 32-63

| | | | | |
|---|---|---|---|---|
| 32 | 001010100100 | 11 | 000010101000 | 11 |
| 33 | 001010100100 | 12 | 000010101000 | 12 |
| 34 | 001010100100 | 13 | 000010101000 | 13 |
| 35 | 001010100100 | 14 | 001010100000 | 8 |
| 36 | 001010100100 | 15 | 001010100000 | 9 |
| 37 | 010101000100 | 8 | 001010100000 | 10 |
| 38 | 010101000100 | 9 | 001010100000 | 11 |
| 39 | 010101000100 | 10 | 001010100000 | 12 |
| 40 | 010101000100 | 11 | 001010100000 | 13 |
| 41 | 010101000100 | 12 | 001010100000 | 14 |
| 42 | 010101000100 | 13 | 001010100000 | 15 |
| 43 | 010101000100 | 14 | 001010100101 | 0 |
| 44 | 010101000100 | 15 | 001010100101 | 1 |
| 45 | 010101001000 | 8 | 001010100101 | 2 |
| 46 | 010101001000 | 9 | 000010101000 | 15 |
| 47 | 010101001000 | 10 | 000010010010 | 7 |
| 48 | 010101001000 | 11 | 000010101000 | 14 |
| 49 | 010101001000 | 12 | 000001000000 | 8 |
| 50 | 010101001000 | 13 | 000001000000 | 9 |
| 51 | 010101001000 | 14 | 000001000000 | 10 |
| 52 | 010101001000 | 15 | 000001000000 | 11 |
| 53 | 101010000001 | 1 | 000001000000 | 12 |
| 54 | 101010000001 | 2 | 000001000000 | 13 |
| 55 | 101010000001 | 3 | 000001000000 | 14 |
| 56 | 101010000001 | 4 | 000001000101 | 0 |
| 57 | 101010000010 | 0 | 000001000101 | 1 |
| 58 | 101010000010 | 1 | 000001000101 | 2 |
| 59 | 101010000010 | 2 | 000001000101 | 3 |
| 60 | 101010000010 | 3 | 000001001001 | 0 |
| 61 | 101010000010 | 4 | 000001001001 | 1 |
| 62 | 000010001000 | 12 | 000001001001 | 2 |
| 63 | 000010001000 | 13 | 000001001001 | 3 |

State S15 Part-3: Entries 64-95

| | | | | |
|---|---|---|---|---|
| 64 | 000010001000 | 14 | 000001001001 | 4 |
| 65 | 000010001000 | 15 | 000001001010 | 0 |
| 66 | 000001000001 | 0 | 000001001010 | 1 |
| 67 | 000001000001 | 1 | 000001001010 | 2 |
| 68 | 000001000001 | 2 | 000001001010 | 3 |
| 69 | 000001000001 | 3 | 000001001010 | 4 |
| 70 | 000001000001 | 4 | 000001001010 | 5 |
| 71 | 000001000010 | 0 | 000001001010 | 6 |
| 72 | 000001000010 | 1 | 000001010001 | 0 |
| 73 | 000001000010 | 2 | 000001010001 | 1 |
| 74 | 000001000010 | 3 | 000001010001 | 2 |
| 75 | 000001000010 | 4 | 000001010001 | 3 |
| 76 | 000001000010 | 5 | 000001010001 | 4 |
| 77 | 000001000010 | 6 | 000001010010 | 0 |
| 78 | 000001000010 | 7 | 000001010010 | 1 |
| 79 | 000001000100 | 8 | 000001010010 | 2 |
| 80 | 000001000100 | 9 | 000001010010 | 3 |
| 81 | 000001000100 | 10 | 000001010010 | 4 |
| 82 | 000001000100 | 11 | 000001010010 | 5 |
| 83 | 000001000100 | 12 | 000001010010 | 6 |
| 84 | 000001000100 | 13 | 000001010010 | 7 |
| 85 | 000001000100 | 14 | 000001010100 | 8 |
| 86 | 000001000100 | 15 | 000001010100 | 9 |
| 87 | 000001001000 | 8 | 000001010100 | 10 |
| 88 | 000001001000 | 9 | 000001010100 | 11 |
| 89 | 000001001000 | 10 | 000001010100 | 12 |
| 90 | 000001001000 | 11 | 000001010100 | 13 |
| 91 | 000001001000 | 12 | 000001010100 | 14 |
| 92 | 000001001000 | 13 | 000001010100 | 15 |
| 93 | 000001001000 | 14 | 000010000000 | 8 |
| 94 | 000001001000 | 15 | 000010000000 | 9 |
| 95 | 000001010000 | 8 | 000010000000 | 10 |

State S15 Part-4: Entries 96-127

| | | | | |
|---|---|---|---|---|
| 96 | 000001010000 | 9 | 000010000000 | 11 |
| 97 | 000001010000 | 10 | 000010000000 | 12 |
| 98 | 000001010000 | 11 | 000010000000 | 13 |
| 99 | 000001010000 | 12 | 000010000000 | 14 |
| 100 | 000001010000 | 13 | 000010000101 | 0 |
| 101 | 000001010000 | 14 | 000010000101 | 1 |
| 102 | 000001010000 | 15 | 000010000101 | 2 |
| 103 | 000010000001 | 0 | 000010000101 | 3 |
| 104 | 000010000001 | 1 | 000010001001 | 0 |
| 105 | 000010000001 | 2 | 000010001001 | 1 |
| 106 | 000010000001 | 3 | 000010001001 | 2 |
| 107 | 000010000001 | 4 | 000010001001 | 3 |
| 108 | 000010000010 | 0 | 000010001001 | 4 |
| 109 | 000010000010 | 1 | 000010001010 | 0 |
| 110 | 000010000010 | 2 | 000010001010 | 1 |
| 111 | 000010000010 | 3 | 000010001010 | 2 |
| 112 | 000010000010 | 4 | 000010001010 | 3 |
| 113 | 000010000010 | 5 | 000010001010 | 4 |
| 114 | 000010000010 | 6 | 000010001010 | 5 |
| 115 | 000010000010 | 7 | 000010001010 | 6 |
| 116 | 000010000100 | 8 | 000010010001 | 0 |
| 117 | 000010000100 | 9 | 000010010001 | 1 |
| 118 | 000010000100 | 10 | 000010010001 | 2 |
| 119 | 000010000100 | 11 | 000010010001 | 3 |
| 120 | 000010000100 | 12 | 000010010001 | 4 |
| 121 | 000010000100 | 13 | 000010010010 | 0 |
| 122 | 000010000100 | 14 | 000010010010 | 1 |
| 123 | 000010000100 | 15 | 000010010010 | 2 |
| 124 | 000010001000 | 8 | 000010010010 | 3 |
| 125 | 000010001000 | 9 | 000010010010 | 4 |
| 126 | 000010001000 | 10 | 000010010010 | 5 |
| 127 | 000010001000 | 11 | 000010010010 | 6 |

1. A method of converting a user bitstream into a coded bitstream by means of a channel code where the channel code has a constraint of d=1, characterized in that the channel code has an additional constraint of r=2.

2. A method as claimed in claim 1, characterized in that said channel code is parity-preserving channel code, thus preserving a parity between user words and corresponding channel words of the channel code.

3. A method as claimed in claim 2, characterized in that the channel code is a sliding-block decodable channel code obtainable via an approximate eigenvector that satisfies two inequalities at the same time, a first inequality for even-parity channel words, and a second inequality for odd-parity channel words.

4. A method as claimed in claim 3, characterized in that the code has an additional k-constraint of k=12.

5. A method as claimed in claim 3, characterized in that the code has an additional k-constraint of k=10.

6. A method as claimed in claim 4, characterized in that the code has an 8-to-12 mapping.

7. A coder for converting a user bitstream into a coded bitstream by means of a channel code where the coder comprises processing device for applying a channel code with the constraint of d=1, characterized in that the coder is arranged to apply an additional constraint of r=2 when converting the user bitstream into the coded bitstream.

8. A coder as claimed in claim 7, characterized in that said channel code is a parity-preserving channel code, thus preserving a parity between user words and corresponding channel words of the channel code.

9. A coder as claimed in claim 8, characterized in that the channel code is a sliding-block decodable channel code obtainable via an approximate eigenvector that satisfies two inequalities at the same time, a first inequality for even-parity channel words, and a second inequality for the odd-parity channel words.

10. A coder as claimed in claim 9, characterized in that the code has an additional k-constraint of k=12.

11. A coder as claimed in claim 9, characterized in that the code has an additional k-constraint of k=10.

12. A coder as claimed in claim 10, characterized in that the code has an 8-to-12 mapping.

13. A recording device comprising a coder as claimed in claim 7, an input device for receiving the user bitstream and providing the user bit stream to the coder and recording means for recording the coded bitstream on a record carrier as provided by the coder to the recording means.

14. A bit detector for performing bit detection on a code bitstream comprising a user bitstream coded in a coded bitstream by means of a channel code where the channel code has the constraint of d=1, characterized in that the channel code has an additional constraint of r=2.

15. A bit detector as claimed in claim 14, characterized in that said channel code is a parity-preserving channel code, thus preserving a parity between user words and corresponding channel words of the channel code.

16. A bit detector as claimed in claim 15, characterized in that the channel code is a sliding-block decodable channel code obtainable via an approximate eigenvector that satisfies two inequalities at the same time, a first inequality for the even-parity channel words, and a second inequality for the odd-parity channel words.

17. A bit detector as claimed in claim 16, characterized in that the code has an additional k-constraint of k=12.

18. A bit detector as claimed in claim 16, characterized in that the code has an additional k-constraint of k=10.

19. A bit detector as claimed in claim 17, characterized in that the code has an 8-to-12 mapping.

20. A playback device comprising a bit detector as claimed in claim 14.

21. A signal comprising a user bitstream coded in a coded bitstream by means of a channel code where the channel code has the constraints of d=1 characterized in that the channel code has an additional constraint of r=2.

22. A record carrier comprising a track comprising a signal comprising a user bitstream coded in a coded bitstream by means of a channel code where the channel code has the constraint of d=1, characterized in that the channel code has an additional constraint of r=2.

23. A record carrier comprising a signal as claimed in claim 22, characterized in that said channel code is a parity-preserving channel code, thus preserving a parity between user words and corresponding channel words of the channel code.

24. A record carrier as claimed in claim 23, characterized in that the channel code is a sliding-block decodable channel code obtainable via an approximate eigenvector that satisfies two inequalities at the same time, a first inequality for the even-parity channel words, and a second inequality for the odd-parity channel words.

25. A record carrier as claimed in claim 24, characterized in that the code has an additional k-constraint of k=12.

26. A record carrier as claimed in claim 24, characterized in that the code has an additional k-constraint of k=10.

27. A record carrier as claimed in claim 25, characterized in that the code has an 8-to-12 mapping.
